(19) United States
(12) Patent Application Publication
(10) Pub. No.: US 2008/0233761 A1
(43) Pub. Date: Sep. 25, 2008

(54) Fabrication method of semiconductor integrated circuit device

(76) Inventors: Takeshi Ozawa, Kofu (JP); Yasuyuki Sato, Ryuou (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/071,974

(22) Filed: Feb. 28, 2008

Related U.S. Application Data
(63) Continuation of application No. 10/864,638, filed on Jun. 10, 2004, now abandoned.

(30) Foreign Application Priority Data
Jun. 16, 2003 (JP) 2003-170968
Mar. 19, 2004 (JP) 2004-079952

(51) Int. Cl. H01L 21/283

(52) U.S. Cl. 438/758; 257/E21.159

(57) ABSTRACT

An object of the present invention is to provide a fabrication method of a semiconductor integrated circuit device capable of improving the throughput, reducing the cost of a cleaning gas and prolonging the life of a process kit by automatically detecting the end point of cleaning in a chamber. A cleaning gas converted into plasma in a plasma gas generator is introduced into a chamber to remove an unnecessary film deposited over the interior wall of the chamber or electrode. By an RF power source adjusted to low output from the film formation time, a high frequency voltage is applied to a lower electrode and an upper electrode. This voltage is detected by an RF sensor and amplified by an electronic module. The voltage thus amplified by the electronic module is input to a termination controller. The termination controller automatically judges the termination of cleaning when the voltage thus input becomes substantially constant at a predetermined voltage or greater.

### CROSS-REFERENCE TO RELATED APPLICATION

The present application claims priority from Japanese Patent application JP 2004-079952 filed on Mar. 19, 2004 and JP 2003-170968 filed on Jun. 16, 2003, the content of which is hereby incorporated by reference into this application. This application is a Continuation application of application Ser. No. 10/864,638, filed Jun. 10, 2004, the contents of which is incorporated herein by reference in their entirety.

### BACKGROUND OF THE INVENTION

The present invention relates to a fabrication technique of a semiconductor integrated circuit device, particularly to a technique effective when applied to a cleaning step of a semiconductor manufacturing apparatus for forming a film over a semiconductor wafer (which will hereinafter be called “wafer” simply).

In Japanese Unexamined Patent Publication No. Hei 9 (1997)-082645 (Patent Document 1), disclosed is a technique of detecting a cleaning end-point of a CDV apparatus based on an emission intensity ratio of a plasma species participating in cleaning to a plasma species not participating in cleaning, a change in pressure during cleaning or a change in plasma potential.

In Japanese Unexamined Patent Publication No. Hei 10 (1998)-022280 (Patent Document 2), disclosed is a technique of disposing an impedance detection means between a cathode electrode and an anode electrode for detecting a change in impedance therebetween and terminating cleaning when an increasing ratio or decreasing ratio of the impedance detected by the impedance detection means falls below a predetermined value.

In U.S. Pat. No. 6,534,007 (International Patent Publication No. 2001-527151) (Patent Document 3), disclosed is a technique of monitoring the intensity of emission lines of a cleaning gas and that of at least one background gas in a chamber to determine a ratio of the intensity of the cleaning gas emission line to the intensity of the background gas emission line, comparing the determined intensity ratio to a preset threshold value, and detecting an end point of cleaning based on the comparison results.

In Japanese Unexamined Patent Publication No. Hei 11 (1999)-162957 (Patent Document 4), disclosed is a following technique. Described specifically, a movable intermediate mesh electrode is disposed between a pair of electrodes. For the cleaning of an interior wall of a chamber on one electrode side, it is etched by generating plasma of an etching gas between the one electrode and the intermediate mesh electrode. For the cleaning of an interior wall of the chamber on the other electrode side, the intermediate mesh electrode is transferred to a position between the intermediate mesh electrode and the other electrode at which generation of glow discharge can be generated and then, etching is performed by generating plasma of an etching gas between the intermediate mesh electrode and the other electrode.

[Patent Document 1] Japanese Unexamined Patent Publication No. Hei 9 (1997)-082645 (page 3, FIG. 4)
[Patent Document 2] Japanese Unexamined Patent Publication No. Hei 10 (1998)-022280 (pages 2 to 3, FIGS. 2 to 3)
[Patent Document 3] U.S. Pat. No. 6,534,007
[Patent Document 4] Japanese Unexamined Patent Publication No. Hei 11 (1999)-162957 (pages 4 to 7, FIG. 1, FIG. 3)

### SUMMARY OF THE INVENTION

A film is formed over a wafer, for example, by CVD (Chemical Vapor Deposition) method. In the CVD method, a necessary raw material, depending on the kind of a film to be formed, is fed in the gas form; a chemical reaction is caused by applying energy to the gas; and a film is deposited over the wafer while making use of a catalytic reaction on the surface of the underlying film. There are many kinds of this CVD method. When they are classified by energy to be applied, thermal CVD and plasma CVD methods can be given as examples.

The plasma CVD method is a technique of introducing a raw material gas in a pressure-reduced chamber, converting the introduced gas into plasma by high-frequency electric field and depositing a film by the chemical reaction. An apparatus for actualizing this plasma CVD method is a plasma CVD apparatus.

In the plasma CVD apparatus, a film is formed over a wafer in a chamber. Upon formation of a film over a wafer, however, films are formed over places other than the wafer. These films formed in the chamber may be a cause for generation of foreign matters. The fabrication procedure of a semiconductor integrated circuit device therefore includes cleaning of the chamber in the plasma CVD apparatus.

First method for cleaning the interior of the chamber is a method of RF (Radio Frequency) direct application. In this method, a cleaning gas is introduced between a pair of electrodes in a chamber and then converted into plasma by applying a voltage to the pair of electrodes by an RF oscillator. A film deposited in the chamber is removed by the chemical reaction between the cleaning gas in plasma form and the film deposited in the chamber.

The amount of fluorine radicals differs with the progress stage of the chemical reaction, while transition of fluorine radicals generated in the chamber causes light emission. In this method, therefore, termination time of cleaning can be automatically detected by detecting, through a light emission monitor, a change in the intensity of light emitted by fluorine radicals.

In addition, the impedance of the chamber and that of the power source are matched in order to keep constant the discharge in the chamber. When the cleaning is finished, the impedance of the chamber changes, and also a change in discharge occurs. By detecting a change in the impedance of the chamber, the end point of the cleaning can be detected automatically.

The above-described RF direct application method is however accompanied with the problem that generation of a cleaning gas in plasma form requires high output, which tends to damage parts (process kit) such as electrodes.

A second method for cleaning the interior of the chamber is a cleaning method using remote plasma, which has been prevalent recently. In this method, an NF₃ gas (mixed with an argon gas which is an inert gas) is used as the cleaning gas and this cleaning gas is converted into plasma by introducing it into a plasma gas generator disposed outside the chamber. Drying etching is carried out by introducing the plasma cleaning gas into the chamber and an unnecessary film formed in the chamber is removed.

Different from the above-described RF direct application method, the second cleaning method using remote plasma does not require the operation of the RF oscillator in the chamber for cleaning. The end point of the cleaning therefore cannot be detected by the above-described method.

The below-described method is a possible solution which enables automatic detection of the finish time of the cleaning.

For example, a gas analyzer is disposed in a gas exhaust line of the chamber and the finish time of the cleaning is detected by a change in the fluorine amount passing through the gas exhaust line. This method however involves such a problem that the sensor of the gas analyzer is corroded by fluorine, which disturbs stable detection of the finish time of the cleaning. In addition, the gas analyzer costs high.

In the cleaning method using remote plasma, the finish time of the cleaning cannot be automatically detected stably. At present, for example, 1.2 times as much as that of the cleaning time starting from the initiation time to the expected finish time is spent whenever film formation is conducted. The cleaning time is set longer in consideration of a change in the state of the chamber. The finish time of the cleaning can be expected using, for example, the above-described gas analyzer. In other words, the cleaning time in the chamber is measured using the gas analyzer on an experimental basis. In the actual fabrication line, the gas analyzer is not used and cleaning is conducted for a time of about 1.2 times as much as that of the cleaning time determined by measurement.

The above-described method is however accompanied with such drawbacks as lowering in the throughput owing to the cleaning time about 1.2 times as much as the actual cleaning time and deterioration of parts due to over-etching. In addition, foreign matters may be generated by the over-etching of the part. Moreover, over-etching increases the consumption amount of the cleaning gas, leading to a cost rise.

An object of the present invention disclosed by the present application is to provide a fabrication technique of a semiconductor integrated circuit device capable of automatically detecting the correct finish time of cleaning of the interior of a chamber.

Another object of the present invention disclosed by the present application is to provide a fabrication method of a semiconductor integrated circuit device capable of reducing the treatment time of each batch.

A further object of the present invention disclosed by the present application is to provide a CVD technique capable of reducing the treatment time of each batch.

A still further object of the present invention disclosed by the present application is to provide an efficient cleaning technique in CVD.

A still further object of the present invention disclosed by the present application is to provide a process controlling technique suited for the cleaning in CVD.

A still further object of the present invention disclosed by the present application is to provide a fabrication method of a semiconductor integrated circuit device suited for small batch treatment.

A still further object of the present invention disclosed by the present application is to provide an efficient technique for detecting the end point of cleaning which technique is suited for plasma CVD.

A still further object of the present invention disclosed by the present application is to provide an efficient technique for detecting the end point of cleaning which technique is suited for CVD.

A still further object of the present invention disclosed by the present application is to provide an efficient technique for detecting the end point of cleaning which technique is suited for plasma CVD making use of a remote plasma cleaning mechanism.

A still further object of the present invention disclosed by the present application is to provide a CVD technique requiring less treatment time.

A still further object of the present invention disclosed by the present application is to provide a cleaning technique in CVD with a small consumption amount of a cleaning gas.

A still further object of the present invention disclosed by the present application is to provide a cleaning technique in CVD with less apparatus damage.

A still further object of the present invention disclosed by the present application is to provide a cleaning technique in CVD with less contamination.

A still further object of the present invention disclosed by the present application is to provide a CVD technique suited for wafer-by-wafer processing.

A still further object of the present invention disclosed by the present application is to provide a CVD technique suited for the processing of a wafer 300 Φ or greater.

The above and other objects and novel features of the invention will become apparent from the description of the specification and the appended drawings.

Of the inventions disclosed by the present application, representative ones will next be described briefly.

1. A semiconductor manufacturing apparatus which comprises: (a) a chamber to be cleaned by a cleaning gas in plasma form; (b) a pair of electrodes disposed in the chamber; (c) an oscillator for supplying the pair of electrodes with electricity upon cleaning of the chamber; (d) a sensor for detecting a voltage applied to the pair of electrode by the electricity supplied by the oscillator; and (e) a termination controller for terminating, based on the voltage detected by the sensor, cleaning of the interior of the chamber with the plasma cleaning gas.

2. A semiconductor manufacturing apparatus comprising: (a) a plasma gas generator for generating a cleaning gas in plasma form; (b) a chamber to be cleaned by the plasma cleaning gas and spaced from the plasma gas generator; (c) a pair of electrodes disposed in the chamber; (d) an oscillator for supplying the pair of electrodes with electricity upon cleaning of the chamber; (e) a sensor for detecting a voltage applied to the pair of electrodes by the electricity supplied by the oscillator; and (f) a termination controller for terminating, based on the voltage detected by the sensor, cleaning of the interior of the chamber with the plasma cleaning gas.

3. A semiconductor manufacturing apparatus equipped with (a) a plasma gas generator for generating a plasma cleaning gas; (b) a chamber to be cleaned by introducing the plasma cleaning gas and spaced from the plasma gas generator; (c) a pair of electrodes disposed in the chamber; (d) an oscillator for supplying the pair of electrodes with electricity upon cleaning of the chamber; (e) a sensor for detecting a voltage applied between the pair of electrodes by the electricity supplied by the oscillator; and (f) a termination controller for terminating cleaning of the interior of the chamber with the plasma cleaning gas based on the voltage detected by the sensor, wherein the termination controller stops feeding of the plasma cleaning gas into the chamber and supply of the electricity by the oscillator when the voltage detected by the sensor becomes substantially constant at a predetermined voltage or greater.

4. A semiconductor manufacturing apparatus for introducing a raw material gas in plasma form to a wafer to form a film thereover, which comprises (a) a plasma gas generator for generating a cleaning gas in plasma form; (b) a chamber to be cleaned by introducing the plasma cleaning gas and spaced from the plasma gas generator; (c) a pair of electrodes disposed in the chamber; (d) an oscillator for feeding the pair of electrodes with electricity upon cleaning of the chamber; (e) a sensor for detecting a voltage applied between the pair of electrodes by the electricity supplied by the oscillator; and (f) a termination controller for terminating cleaning of the interior of the chamber with the plasma cleaning gas based on the voltage detected by the sensor.

5. A semiconductor manufacturing apparatus which is equipped with (a) a chamber into which a raw material gas is introduced, (b) a pair of electrodes disposed in the chamber, and (c) an oscillator; and converts the raw material gas into plasma by applying a first voltage between the pair of electrodes by the electricity supplied by the oscillator and forming a film over a wafer disposed in the chamber by using the plasma raw material gas, which comprises (d) a plasma gas generator for forming a plasma cleaning gas and spaced from the chamber; (e) a sensor for detecting a second voltage applied to the pair of electrodes by operating the oscillator at a lower output than that applied upon formation of the film over the wafer, upon cleaning of the chamber by introducing therein the plasma cleaning gas, and (f) a termination controller for terminating cleaning of the interior of the chamber with the plasma cleaning gas, based on the second voltage detected by the sensor; wherein the termination controller stops feeding of the plasma cleaning gas into the chamber and application of the second voltage by the oscillator when the second voltage detected by the sensor becomes constant at a predetermined voltage or greater.

The other inventions disclosed by the present application will next be described under items.

1. A fabrication method of a semiconductor integrated circuit device comprises the steps of (a) forming a film over a wafer in a chamber, (b) unloading the wafer from the chamber, (c) converting a cleaning gas into plasma in a plasma gas generator disposed at a place other than the chamber, (d) after the step (b), feeding the plasma cleaning gas in the chamber to clean the interior of the chamber, (e) supplying electricity to a pair of electrodes disposed in the chamber from an oscillator during cleaning of the interior of the chamber, (f) detecting, by a sensor connected to the electrodes, a voltage generated between the pair of electrodes by feeding of the electricity, and (g) terminating the cleaning of the interior of the chamber with the plasma cleaning gas, based on the voltage detected by the sensor.

2. In a fabrication method of a semiconductor integrated circuit device as described in Item 1, in the step (g), feeding of the plasma cleaning gas to the chamber is terminated when the voltage detected by the sensor is substantially constant at a predetermined voltage or greater.

3. In a fabrication method of a semiconductor integrated circuit device as described in Item 2, wherein when the voltage detected by the sensor does not become substantially constant at a predetermined voltage or greater, feeding of the plasma cleaning gas in the chamber is stopped and abnormal conditions at the plasma gas generator are reported.

4. In a fabrication method of a semiconductor integrated circuit device as described in Item 1, wherein the step (a) further comprises (a-1) disposing the wafer on one of the pair of electrodes, (a2) feeding a raw material of a film over the wafer, and (a3) feeding first electricity to the pair of electrodes by using the oscillator to convert the raw material between the pair of electrodes into plasma and forming a film over the wafer by making use of a chemical reaction of the raw material plasma; and in the step (e), second electricity smaller than the first electricity is fed to the pair of electrodes.

5. In a fabrication method of a semiconductor integrated circuit device as described in Item 4, wherein in the step (e), the minimum electricity necessary for maintaining the plasma form of the plasma cleaning gas to be fed into the chamber from the plasma generator is supplied to the pair of electrodes.

6. In a fabrication method of a semiconductor integrated circuit device as described in Item 4, wherein the second electricity falls within a range of from 1% to 10% of the first electricity.

7. In a fabrication method of a semiconductor integrated circuit device as described in Item 4, wherein the second electricity falls within a range of from 1% to 50% of the first electricity.

8. In a fabrication method of a semiconductor integrated circuit device as described in Item 4, wherein the second electricity falls within a range of from 50% to 80% of the first electricity.

9. In a fabrication method of a semiconductor integrated circuit device as described in Item 1, wherein in the step (a), a silicon oxide film is formed over the wafer.

10. In a fabrication method of a semiconductor integrated circuit device as described in Item 9, wherein the silicon oxide film is formed using TEOS as a raw material.

11. In a fabrication method of a semiconductor integrated circuit device as described in Item 9, wherein the silicon oxide film is an interlayer dielectric film.

12. In a fabrication method of a semiconductor integrated circuit device as described in Item 1, wherein in the step (a), a silicon nitride film is formed over the wafer.

13. In a fabrication method of a semiconductor integrated circuit device as described in Item 12, wherein the silicon nitride film is a passivation film.

14. A fabrication method of a semiconductor integrated circuit device, which comprises the steps of: (a) forming a film over a first wafer in a chamber, (b) unloading the first wafer from the chamber, (c) after the step (b), loading a second wafer in the chamber, (d) forming a film over the second wafer in the chamber, (e) unloading the second wafer from the chamber, (f) converting a cleaning gas into plasma in a plasma gas generator disposed at a place other than the chamber, (g) after the step (e), feeding the plasma cleaning gas into the chamber to clean the interior of the chamber, (h) supplying electricity from an oscillator to a pair of electrodes disposed in the chamber during cleaning the interior of the chamber, (i) detecting, by a sensor connected to the electrodes, a voltage generated between the pair of electrodes by supplying the electricity thereto, and (j) terminating the feeding of the plasma cleaning gas into the chamber when the voltage detected by the sensor becomes substantially constant at a predetermined voltage or greater.

15. A fabrication method of a semiconductor integrated circuit device, which comprises the steps of: (a) repeating, for n pieces of wafers, a step of loading a wafer in a chamber, forming a film over the wafer, and unloading the wafer from the chamber, (b) converting a cleaning gas into plasma in a plasma generator disposed at a place other than the chamber, (c) after the step (a), feeding the plasma cleaning gas into the chamber to clean interior of the chamber, (d) supplying electricity from an oscillator to a pair of electrodes disposed in the chamber during cleaning the interior of the chamber, (e) detecting, by a sensor connected to the electrodes, a voltage generated between the pair of electrodes by supplying the electricity thereto, and (f) terminating the feeding of the plasma cleaning gas into the chamber when the voltage detected by the sensor becomes substantially constant at a predetermined voltage or greater.

16. A fabrication method of a semiconductor integrated circuit device, which comprises the steps of: (a) forming a film over a wafer in a chamber, (b) unloading the wafer from the chamber, (c) converting a cleaning gas into plasma in a plasma gas generator disposed at a place other than the chamber, (d) after the step (b), feeding the plasma cleaning gas into the chamber to clean the interior of the chamber, (e) supplying electricity from an oscillator to a pair of electrodes disposed in the chamber during cleaning the interior of the chamber, and thereby maintaining the plasma form of the cleaning gas existing between the pair of electrodes, (f) detecting, by a photoelectric sensor, light emission of the plasma cleaning gas, and (g) terminating the cleaning in the chamber by the plasma cleaning gas when the output voltage of the photoelectric sensor becomes substantially constant at a predetermined voltage or greater.

17. A fabrication method of a semiconductor integrated circuit device, which comprises the steps of: (a) forming a film over a first wafer in a chamber, (b) unloading the first wafer from the chamber, (c) after the step (b), loading a second wafer into the chamber, (d) forming a film over the second wafer in the chamber, (e) unloading the second wafer from the chamber, (f) converting a cleaning gas into plasma in a plasma gas generator disposed at a place other than the chamber, (g) after the step (e), feeding the plasma cleaning gas into the chamber to clean the interior of the chamber, (h) supplying electricity from an oscillator to a pair of electrodes disposed in the chamber during cleaning the interior of the chamber, and thereby maintaining the plasma form of the cleaning gas existing between the pair of electrodes, (i) detecting, by a photoelectric sensor, light emission of the plasma cleaning gas, and (j) terminating the cleaning in the chamber by the plasma cleaning gas when the output voltage of the photoelectric sensor becomes substantially constant at a predetermined voltage or greater.

18. A fabrication method of a semiconductor integrated circuit device, which comprises the steps of: (a) repeating, for n pieces of wafers, a step of loading a wafer in a chamber, forming a film over the wafer, and unloading the wafer from the chamber, (b) converting a cleaning gas into plasma in a plasma gas generator disposed at a place other than the chamber, (c) after the step (a), feeding the plasma cleaning gas into the chamber to clean the interior of the chamber,

(d) supplying electricity from an oscillator to a pair of electrodes disposed in the chamber during cleaning of the interior of the chamber, and thereby maintaining the plasma form of the cleaning gas existing between the pair of electrodes, (e) detecting light emission of the plasma cleaning gas by a photoelectric sensor, and (f) terminating the cleaning in the chamber with the plasma cleaning gas when the output voltage of the piezoelectric sensor becomes substantially constant at a predetermined voltage or greater.

The other inventions disclosed by the present application will hereinafter be described under items.

1. A fabrication method of a semiconductor integrated circuit device which comprises the steps of: (a) etching and removing an undesired film member (dielectric film or the like) deposited on the interior of a first film forming chamber of a plasma CVD apparatus not containing therein a wafer to be treated, while introducing, in the first film forming chamber, a first-radical-containing first gas generated outside the film forming chamber; (b) during the step (a), subjecting the first gas in the first film formation chamber to plasma excitation at a first radio frequency power of a first intensity and detecting an end point of the etching by observing physical or chemical properties of the excited plasma (in Examples, a radio frequency power for film formation is supplied to a plasma excitation electrode for film formation in a plasma CVD to facilitate detection of the cleaning end-point, but additional disposal of an excitation electrode, excitation coil, excitation antenna, excitation waveguide or excited power injecting mechanism in the film formation chamber or in the exhaust gas system is also possible for observation. In this case, this method is advantageous because it can be applied to thermal CVD free of a plasma excitation electrode for film formation. Even in plasma CVD, damage to the film forming chamber by cleaning can be reduced and introduction of contamination by undesired etching can be reduced. Particularly, disposal in the exhaust system is effective. When a conventional electrode is used, on the other hand, introduction of a new electrode or radio frequency supply system is not necessary. As described below, it is not always necessary to observe the end point of etching in all the cleaning steps. A value expected in advance in a given manner based on the end point measuring results of the same chamber may ordinarily be used and once in C times, the end point may be detected actually. The C generally stands for 1 to 10, preferably from 1 to 5. It is however effective to measure the end point every cleaning time in order to eliminate the waste. The value C may be made variable, depending on the treating amount after periodical cleaning of the whole apparatus. This makes it possible to minimize undesired etching of the interior of the film forming chamber by radio frequency application upon unessential cleaning. This will equally apply to the following Items 8, 12, 15 and 16); (c) based on the results of the step (b), terminating the etching and removing; (d) discharging the first gas from the first film forming chamber (this step is not always essential and the order of this step is not limited to this order as is always the case); (e) after the steps (c) and (d), storing, in the first film forming chamber, a first wafer to be treated; (f) subjecting a second gas, while being introduced into the first film forming chamber containing the first wafer, to plasma excitation by second radio frequency power of a second intensity greater than the first intensity and thereby forming a first film member on or over a first main surface of the first wafer; and (g) after the step (f), taking out the first wafer from the first film forming chamber.

2. A fabrication method of a semiconductor integrated circuit device according to Item 1, wherein the physical or chemical properties of plasma are electrical properties relating to the impedance of the plasma.

3. A fabrication method of a semiconductor integrated circuit device according to Item 1, wherein the physical or chemical properties of plasma are optical properties of the plasma.

4. A fabrication method of a semiconductor integrated circuit device according to any one of Items 1 to 3, wherein the first intensity is from 0.05% to 40% of the second intensity.

5. A fabrication method of a semiconductor integrated circuit device according to any one of Items 1 to 3, wherein the first intensity is from 0.1% to 30% of the second intensity.

6. A fabrication method of a semiconductor integrated circuit device according to any one of Items 1 to 3, wherein the first intensity is 0.5% to 20% of the second intensity.

7. A fabrication method of a semiconductor integrated circuit device according to any one of Items 1 to 3, wherein the first intensity is from 1% to 10% of the second intensity.

8. A fabrication method of a semiconductor integrated circuit device which comprises the following steps of: (a) etching an undesired film member (dielectric film or the like) deposited on the interior of a first film forming chamber of a CVD apparatus not containing therein a wafer to be treated, while introducing, in the first film forming chamber, a first-radical-containing first gas formed outside the first film forming chamber; (b) during the step (a), subjecting the first gas, which is in the first film forming chamber, to plasma excitation by a first radio frequency power of a first intensity and detecting an end point of the etching by observing physical or chemical properties of the excited plasma; (c) terminating the etching based on the results of the step (b); (d) discharging the first gas from the first film forming chamber (this step is not always essential, and the order of this step is not limited to this order as is always the case); (e) after the steps (c) and (d), placing a first wafer to be treated in the first film forming chamber, (f) forming a first film member on or over the first main surface of the first wafer without causing plasma excitation by radio frequency power higher than the first radio frequency power, while introducing a second gas in the first film forming chamber containing therein the first wafer; and (g) after the step (f), taking out the first wafer from the first film forming chamber.

9. A fabrication method of a semiconductor integrated circuit device according to Item 8, wherein the physical or chemical properties of the plasma are electrical properties relating to the impedance of the plasma.

10. A fabrication method of a semiconductor integrated circuit device according to Item 8, wherein the physical or chemical properties of the plasma are optical properties of the plasma.

11. A fabrication method of a semiconductor integrated circuit device according to any one of Items 8 to 10, wherein the first film member is formed by thermal CVD.

12. A fabrication method of a semiconductor integrated circuit device, which comprises the following steps of: (a) etching an undesired film member (dielectric film or the like) deposited on the interior of a first film forming chamber of a plasma CVD apparatus not containing a wafer to be treated (the wafer may be contained in a wafer waiting portion of the apparatus), while introducing, in the first film forming chamber, a first-radical-containing first gas formed outside the first film forming chamber; (b) during the step (a), detecting an end point of the etching; (c) based on the results of the step (b), terminating the etching; (d) discharging the first gas from the first film forming chamber (this step is not always essential, and the order of this step is not limited to this order as is always the case); (e) after the steps (c) and (d), storing a first wafer to be treated in the first film forming chamber, (f) forming a first film member on or over the first main surface of the first wafer by, while introducing a second gas in the first film forming chamber containing the first wafer, subjecting the second gas to plasma excitation; (g) after the step (f), taking out the first wafer from the first film forming chamber; (h) after the step (g), storing a second wafer to be treated in the first film forming chamber without etching an undesired film member deposited in the first film forming chamber during the step (f); (i) forming the first film member on or over the first main surface of the second wafer by, while introducing the second gas in the first film forming chamber containing the second wafer, subjecting the second gas to plasma excitation; and (j) after the step (i), taking out the second wafer from the first film forming chamber.

13. A fabrication method of a semiconductor integrated circuit device according to Item 12, wherein the end point of etching is detected by measuring electrical properties relating to the impedance of the first gas plasma-excited in the first film forming chamber.

14. A fabrication method of a semiconductor integrated circuit device according to Item 12, wherein the end point of etching is detected by measuring optical properties of the first gas plasma-excited in the first film forming chamber.

15. A fabrication method of a semiconductor integrated circuit device, which comprises, upon subjecting a plurality of wafers to CVD by using a CVD apparatus having (a) a plurality of CVD chambers, (b) a waiting portion in which a plurality of wafers can wait, (c) a wafer transfer container installation site capable of having a plurality of wafer transfer containers installed therein; and (d) a wafer transfer mechanism capable of transferring the wafers between them; carrying out cleaning of the plurality of CVD chambers during replacement of a first waiting group of wafers (a wafer group stored in the waiting portion in the first time) with a second waiting group of wafers (a wafer group placed in the waiting portion in the second time).

16. A fabrication method of a semiconductor integrated circuit device, which comprises, upon subjecting a plurality of wafers to CVD by using a CVD apparatus having (a) a plurality of CVD chambers, (b) a wafer transfer container installation site capable of having a plurality of wafer transfer containers installed therein; and (c) a wafer transfer mechanism capable of transferring the wafers between them, carrying out cleaning of the plurality of CVD chambers during the replacement of a first wafer group (a wafer group stored in the CVD chamber in the first time) with a second wafer group (a second wafer group placed in the CVD chamber in the second time), without substantially keeping the wafers waiting in a waiting portion for cleaning.

An advantage available by the representative inventions, of the inventions disclosed by the present application, will next be described.

Film formation time can be reduced because a proper finish time of cleaning in a chamber can be detected automatically.

### BRIEF DESCRIPTION OF THE DRAWINGS

FIG. 1 illustrates the constitution of a plasma CVD apparatus according to Embodiment 1 of the present invention;

FIG. 2 is a graph showing a relationship between a voltage input in a termination controller and time;

FIG. 3 is a flow chart explaining the operation of the plasma CVD in Embodiment 1;

FIG. 4 is a flow chart explaining the operation of the plasma CVD in Embodiment 1;

FIG. 5 illustrates the appearance of a plasma CVD apparatus used in Embodiment 2;

FIG. 6 illustrates a sequence for film formation and cleaning in the plasma CVD apparatus used in Embodiment 2;

FIG. 7 illustrates more specifically a sequence for film formation and cleaning in the plasma CVD apparatus used in Embodiment 2;

FIG. 8 illustrates the constitution of the plasma CVD apparatus to be used in Embodiment 2;

FIG. 9 illustrates the relationship between a voltage input to a termination controller and time from the initiation of the cleaning;

FIG. 10 illustrates, in the cleaning after formation of a 200-nm thick film, the relationship between a voltage input to a termination controller and time from the initiation of the cleaning;

FIG. 11 illustrates, in the cleaning after formation of a 300-nm thick film, the relationship between a voltage input to a termination controller and time from the initiation of the cleaning;

FIG. 12 illustrates, in the cleaning after formation of a 400-nm thick film, the relationship between a voltage input to a termination controller and time from the initiation of the cleaning;

FIG. 13 illustrates, in the cleaning after formation of a 600-nm thick film, the relationship between a voltage input to a termination controller and time from the initiation of the cleaning;

FIG. 14 illustrates, in the cleaning after formation of a 800-nm thick film, the relationship between a voltage input to a termination controller and time from the initiation of the cleaning;

FIG. 15 illustrates, in the cleaning after formation of a 1100-nm thick film, the relationship between a voltage input to a termination controller and time from the initiation of the cleaning;

FIG. 16 illustrates the difference in the thickness of a film formed over a wafer;

FIG. 17 illustrates the difference in the uniformity of a film formed over a wafer;

FIG. 18 illustrates the number of foreign matters deposited over the wafer;

FIG. 19 illustrates the difference in the stress of a film formed over a wafer;

FIG. 20 is a cross-sectional view illustrating a fabrication step of a semiconductor integrated circuit device according to Embodiment 2 of the present invention;

FIG. 21 is a cross-sectional view illustrating a fabrication step of the semiconductor integrated circuit device following that of FIG. 20;

FIG. 22 is a cross-sectional view illustrating a fabrication step of the semiconductor integrated circuit device following that of FIG. 21;

FIG. 23 is a cross-sectional view illustrating a fabrication step of the semiconductor integrated circuit device following that of FIG. 22;

FIG. 24 is a cross-sectional view illustrating a fabrication step of the semiconductor integrated circuit device following that of FIG. 23;

FIG. 25 is a cross-sectional view illustrating a fabrication step of the semiconductor integrated circuit device following that of FIG. 24;

FIG. 26 is a cross-sectional view illustrating a fabrication step of the semiconductor integrated circuit device following that of FIG. 25;

FIG. 27 is a cross-sectional view illustrating a fabrication step of the semiconductor integrated circuit device following that of FIG. 26;

FIG. 28 is a cross-sectional view illustrating a fabrication step of the semiconductor integrated circuit device following that of FIG. 27;

FIG. 29 illustrates the relationship between pressure in a process chamber and time;

FIG. 30 illustrates the relationship between RF output and time;

FIG. 31 illustrates the relationship between heater temperature and time, and heater position and time;

FIG. 32 illustrates the relationship between flow rate of TEOS to be introduced into a process chamber and time;

FIG. 33 illustrates the relationship between flow rate of a helium gas to be introduced into a process chamber and time;

FIG. 34 illustrates the relationship between flow rate of an oxygen gas to be introduced into a process chamber and time;

FIG. 35 illustrates the relationship between flow rate of an NF₃ gas to be introduced into a process chamber and time;

FIG. 36 illustrates the relationship between flow rate of an argon gas to be introduced into a process chamber and time;

FIG. 37 illustrates the relationship between voltage input to a termination controller and time;

FIG. 38 illustrates the relationship between pressure in a process chamber and time;

FIG. 39 illustrates the relationship between RF output and time;

FIG. 40 illustrates the relationship between heater temperature and time, and heater position and time;

FIG. 41 illustrates the relationship between flow rate of a silane gas introduced into a process chamber and time;

FIG. 42 illustrates the relationship between flow rate of an ammonia gas introduced into a process chamber and time;

FIG. 43 illustrates the relationship between flow rate of a nitrogen gas introduced into a process chamber and time;

FIG. 44 illustrates the relationship between flow rate of an NF₃ gas introduced into a process chamber and time;

FIG. 45 illustrates the relationship between flow rate of an argon gas introduced into a process chamber and time;

FIG. 46 illustrates the relationship between voltage input to a termination controller and time;

FIG. 47 illustrates the relationship between pressure in a process chamber and time;

FIG. 48 illustrates the relationship between RF output and time;

FIG. 49 illustrates the relationship between heater temperature and time, and heater position and time;

FIG. 50 illustrates the relationship between flow rate of a silane gas introduced into a process chamber and time;

FIG. 51 illustrates the relationship between flow rate of an N₂O gas introduced into a process chamber and time;

FIG. 52 illustrates the relationship between flow rate of a helium gas introduced into a process chamber and time;

FIG. 53 illustrates the relationship between flow rate of an NF₃ gas introduced into a process chamber and time;

FIG. 54 illustrates the relationship between flow rate of an argon gas introduced into a process chamber and time;

FIG. 55 illustrates the relationship between voltage input to a termination controller and time;

FIG. 56 is a cross-sectional view illustrating a manufacturing step of a semiconductor integrated circuit device according to Embodiment 3 of the present invention;

FIG. 57 is a cross-sectional view illustrating a manufacturing step of the semiconductor integrated circuit device following the step of FIG. 56;

FIG. 58 is a cross-sectional view illustrating a manufacturing step of the semiconductor integrated circuit device following the step of FIG. 57;

FIG. 59 is a cross-sectional view illustrating a manufacturing step of the semiconductor integrated circuit device following the step of FIG. 58;

FIG. 60 is a cross-sectional view illustrating a manufacturing step of the semiconductor integrated circuit device following the step of FIG. 59;

FIG. 61 is a cross-sectional view illustrating a manufacturing step of the semiconductor integrated circuit device following the step of FIG. 60;

FIG. 62 is a cross-sectional view illustrating a manufacturing step of the semiconductor integrated circuit device following the step of FIG. 61;

FIG. 63 explains a sequence for film formation and cleaning in a plasma CVD apparatus to be used in Embodiment 4;

FIG. 64 specifically explains a sequence for film formation and cleaning in the plasma CVD apparatus to be used in Embodiment 4;

FIG. 65 illustrates a sequence for film formation and cleaning in a plasma CVD apparatus to be used in Embodiment 5;

FIG. 66 illustrates the relationship between cumulative film thickness and the number of foreign maters deposited over the wafer; and

FIG. 67 illustrates the constitution of a plasma CVD apparatus to be used in Embodiment 6.

### DETAILED DESCRIPTION OF THE INVENTION

Embodiments of the present invention will hereinafter be described specifically based on accompanying drawings. In all the drawings for describing the below-described embodiments, elements having like function will be identified by like reference numerals and overlapping descriptions will be omitted.

Prior to detailed description of the present invention, the meanings of terms used herein will next be explained.

The term “semiconductor wafer” means a single crystal silicon substrate (generally in a disk form), sapphire substrate, glass substrate, other insulating, semi-insulating or semiconductor substrates or a composite substrate thereof, each used in the manufacture of an integrated circuit. In the present invention, the term “semiconductor integrated circuit device” means not only those fabricated over a semiconductor or insulator substrate such as silicon wafer or sapphire substrate but also, unless otherwise specifically indicated, the other insulating substrates, for example, glass such as TFT (Thin Film Transistor) and STN (Super-Twisted-Nematic) liquid crystals.

The term “conversion into plasma (or plasma excitation)” includes not only conversion of atoms or molecules into corresponding ions but also conversion into radicals (plasma in the technical field of a semiconductor integrated circuit device does not contain so much ion component, but in the present invention, a gas containing a radical formed by plasma excitation is also called “plasma”).

The term “remote plasma method” means a method of generating plasma at a position away from a wafer to be treated or apparatus in order to avoid damage thereto and transferring a necessary active species from a plasma generator to a wafer container. This remote plasma method was introduced into an etching apparatus or the like in an early stage, but recently, it has been applied to film formation in a CVD apparatus or cleaning recently. Upon cleaning, it is the common practice to cause plasma excitation of the active species for cleaning in a chamber other than a wafer film forming chamber.

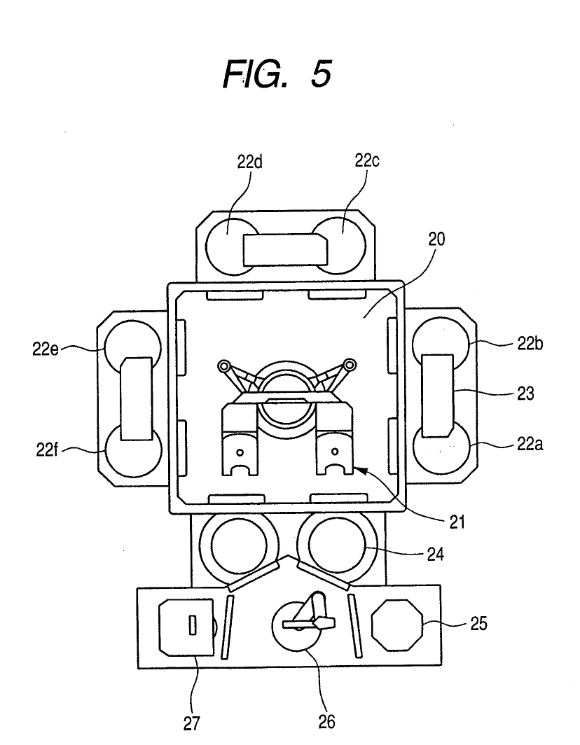

The term “wafer-by-wafer processing” as used herein means processing of only one wafer in one processing chamber at one time. In the case of a plasma CVD apparatus as illustrated in FIG. 5, two adjacent electrode pairs seem to exist in one processing chamber (or two sub-chambers seem to exist in one chamber). In general, however, one electrode pair exists for processing of one wafer. Processing of one specific wafer is sometimes called “single wafer processing”. A thermal CVD apparatus, which looks like the apparatus of FIG. 5, does not have any excitation electrode or antenna so that storing of two wafers in reaction chambers (processing chambers) spatially linked each other is sometimes called “two wafer processing”. Processing in a unit of one wafer and that in a unit of two wafers are collectively called “wafer base processing” in contrast with batch processing (processing of at least three wafers simultaneously in one chamber).

In the below-described examples, a dielectric film (kind of dielectric film and necessary properties) to which the present invention can be applied will be described. Classification of dielectric films which can be applied to interlayer dielectric film, intralayer dielectric film (interlayer dielectric film and intralayer dielectric film are sometimes collectively called “interlayer dielectric film”. This interlayer and intralayer dielectric films are abbreviated as “ILD”), final passivation film, insulating diffusion barrier film and antireflection film, each of a semiconductor integrated circuit device. Conventionally used non Low-k silicon-containing dielectric films can be classified roughly into silicon oxide based dielectric films such as SiO₂ (including those substantially free of carbon, SiON containing a relatively small amount of nitrogen and used mainly as an antireflection film, and silica glass such as PSG and BPSG) and non-oxide based silicon-containing dielectric films typified by silicon nitride (including silicon nitride films such as SiN and SiNH and silicon carbide films such as SiC and SiCN).

Low-k silicon-containing dielectric films (non-organic polymer based ones), on the other hand, include fluorine-containing silica glass based dielectric films such as SiOF, carbon-doped silica glass based (or organosilica glass based, organosiloxane based silica glass) dielectric films such as SiOC (carbon-doped oxide, organosilicate glass, silicon oxicarbide) and porous dielectric films thereof. These dielectric films can be classified by the deposition method. They are coating types such as SOG, CVD types such as plasma TEOS (TEOS or the like is used as an organic precursor) and HDP-CVD (High Density Plasma CVD) types. In particular, ILD by HDP-CVD has been used widely because of its covering planarity. Systems called ECR (Electron Cyclotron Resonance), TCP (Transformer Coupled Plasma) and ICP (Inductively Coupled Plasma) generally correspond to it. In the present application, parallel plate type CVD technique will be described as an example, but it is needless to say that the present invention is not limited thereto.

Raw material gases or organic precursor gases used for these processes are, for example, silane compounds such as monosilane, TEOS, TMS (trimethylsilane), 4MS (tetramethyl silane), TOMCATS (tetramethylcyclotetrasiloxane), OMCTS (octamethylcyclotetrasiloxane) and DMDSO (dimethyldimethoxysilane).

In the below-described embodiments, a description will be made after divided in plural sections or in plural embodiments if necessary for convenience's sake. These plural sections or embodiments are not independent each other, but in a relation such that one is a modification example, details or complementary description of a part or whole of the other one unless otherwise specifically indicated.

In the below-described embodiments, when a reference is made to the number of elements (including the number, value, amount and range), the number of elements is not limited to a specific number but can be greater than or less than the specific number unless otherwise specifically indicated or in the case it is principally apparent that the number is limited to the specific number.

Moreover in the below-described embodiments, it is needless to say that the constituting elements (including element steps) are not always essential unless otherwise specifically indicated or in the case where it is principally apparent that they are essential.

Similarly, in the below-described embodiments, when a reference is made to the shape or positional relationship of the constituting elements, that substantially analogous or similar to it is also embraced unless otherwise specifically indicated or in the case where it is utterly different in principle. This also applies to the above-described value and range.

In all the drawings for describing the below-described embodiments, elements having like function will be identified by like reference numerals and overlapping descriptions will be omitted.

Embodiments of the present invention will hereinafter be described in detail based on accompanying drawings.

### EMBODIMENT 1

In Embodiment 1, the present invention is applied, for example, to a plasma CVD apparatus.

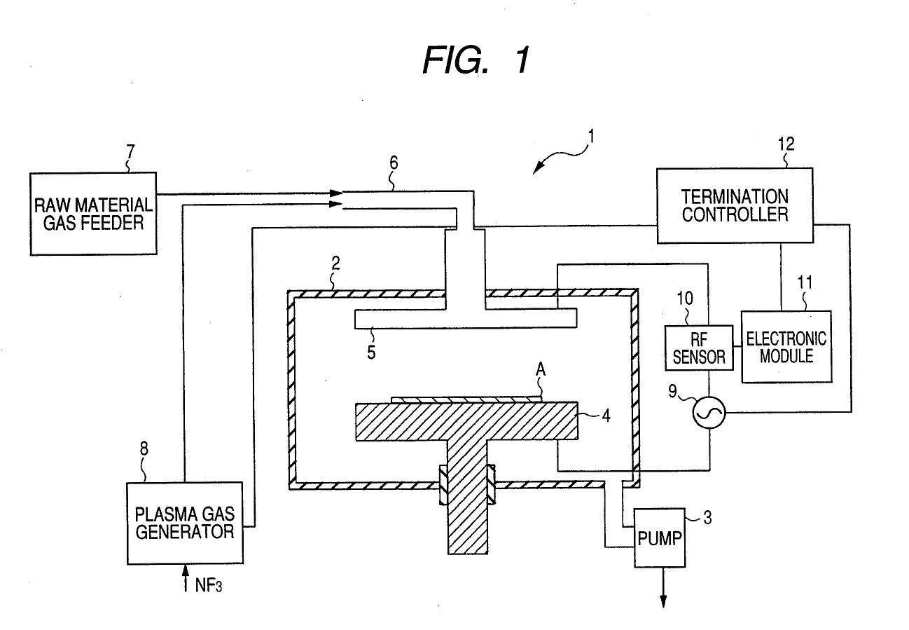

FIG. 1 illustrates the constitution of a plasma CVD apparatus 1 according to Embodiment 1. In FIG. 1, the plasma CVD apparatus 1 of Embodiment 1 has a chamber 2, a pump 3, a lower electrode 4, an upper electrode 5, a pipe 6, a raw material gas feeder 7, a plasma gas generator 8, a radio frequency power source 9, RF (radio frequency) sensor 10, an electronic module 11 and termination controller 12.

In the chamber 2, a film is formed over a wafer A. By the pump 3, the chamber 2 is always kept under vacuum condition. In the chamber 2, a pair of electrodes made of a lower electrode 4 and an upper electrode 5 are disposed with a certain distance therebetween.

The lower electrode 4 is formed to function as a stage for disposing thereon a wafer A on which a film is formed. This lower electrode 4 is vertically movable through the bottom surface of the chamber 2 by an unillustrated driving mechanism so that a position of the wafer A to be disposed on the upper surface of the lower electrode 4 can be adjusted. Between the bottom surface of the chamber 2 and the lower electrode 4, a sealing member is disposed in order to keep the vacuum degree in the chamber 2.

The upper electrode 5 is connected to the raw material gas feeder 7 or plasma gas generator 8 via the pipe 6 and is formed to introduce, into the chamber 2, a raw material gas fed from the raw material gas feeder 7 or a plasma gas generated in the plasma gas generator 8.

The raw material gas feeder 7 is constituted to feed a raw material gas for the formation of a film onto the wafer A disposed on the lower electrode 4. When a silicon oxide film is formed for example, raw material gases such as monosilane (SiH₄), N₂O, N₂, O₂ and Ar are fed from the raw material gas feeder 7 into the chamber 2. When a silicon nitride film is formed, on the other hand, raw material gases such as monosilane (SiH₄), NH₃, N₂, O₂ and Ar are fed. Raw material gases are not limited to the above-described ones, and disilane (Si₂H₆), TEOS (tetraethoxysilane; Si(OC₂H₅)₄) and the like may be fed, depending on the kind of a film to be formed.

The plasma gas generator 8 is disposed in order to feed, in plasma form, a cleaning gas to be used for the removal of an unnecessary film deposited over the interior wall, lower electrode 4 and upper electrode 5 in the chamber 2. As the cleaning gas, NF₃ is, for example, employed. The plasma gas generator 8 has a constitution permitting formation of ions or radicals (fluorine radicals) by using an RF applicator such as RF applicator coil for conversion of an NF₃ gas into plasma.

There is a method of applying a high frequency voltage between the lower electrode 4 and upper electrode 5 in the chamber 2 to convert the cleaning gas into plasma, but this method is apt to damage the parts such as electrodes in the chamber 2. So-called remote plasma method, that is, introduction of a cleaning gas in plasma form, which has been formed in a place away from the chamber 2 (plasma gas generator 8), into the chamber 2, is now employed.

The radio frequency power source (oscillator) 9 is electrically connected to the lower electrode 4 and upper electrode 5 so that electricity can be supplied to a pair of electrodes made of the lower electrode 4 and the upper electrode 5. In other words, a voltage can be applied at high frequency (about 13.56 MHz) between the lower electrode 4 and the upper electrode 5. Owing to high frequency electric field generated by the voltage (first voltage) applied between the lower electrode 4 and the upper electrode 5, a raw material gas fed from the raw material gas feeder 7 is converted into plasma and decomposed into ions or radicals. By the chemical reaction of thus decomposed ions or radicals, a thin film is formed over the wafer A. The output of the radio frequency power source 9 used upon film formation is, for example, about 700 W. The frequency generated by the radio frequency power source 9 is not limited to the above-described value, about 13.56 MHz. The term “first voltage” as used herein means a voltage applied between the lower electrode 4 and the upper electrode 5 when a film is formed over the wafer A.

Upon film formation, the radio frequency power source 9 is in operation, but in the remote plasma method, the radio frequency power source 9 is not used upon cleaning. Described specifically, an unnecessary film formed in the chamber 2 was removed without using the radio frequency power source 9 but by introducing a plasma cleaning gas generated in the plasma gas generator 8 into the chamber 2 by the pipe 6. In this Embodiment 1, on the other hand, the radio frequency power source 9 is operated even upon cleaning. The output of the radio frequency power source 9 upon cleaning is lower than that upon film formation, for example, falls within a range of from about 10 W to about 50 W. The output is adjusted to be lower in order to avoid electrode damage which will be caused when the output is high.

The RF sensor 10 is able to detect a voltage (second voltage) applied between the lower electrode 4 and the upper electrode 5 by the radio frequency power source 9 during cleaning in the chamber 2 and to output the voltage thus detected to an electronic module 11 which will be described later. The “second voltage” as used herein means a voltage applied between the lower electrode 4 and the upper electrode 5 upon cleaning in the chamber 2.

The electronic module (amplification portion) 11 is able to input the voltage detected by the RF sensor 10, amplify the voltage thus input and regulate the voltage to be output to a termination controller 12 which will be described later. For example, an electronic circuit made of an operation amplifier is used for amplifying the voltage detected by the RF sensor 10.

The termination controller 12 is able to input from the electronic module 11 the voltage, which has been detected by the RF sensor 10 and then amplified by the electronic module 11, and based on a change in the voltage thus input, terminate the cleaning in the chamber 2. Described specifically, this termination controller 12 is connected to the plasma gas generator 8 and radio frequency power source 9. When a change in the voltage input by the 11 becomes constant at a predetermined voltage or greater, it judges that the cleaning in the chamber 2 is completed. It is then able to stop generation of the cleaning gas in plasma form by the plasma gas generator 8 and supply of electricity to the lower electrode 4 and the upper electrode 5 from the radio frequency power source 9. This predetermined voltage is determined, for example, by past results.

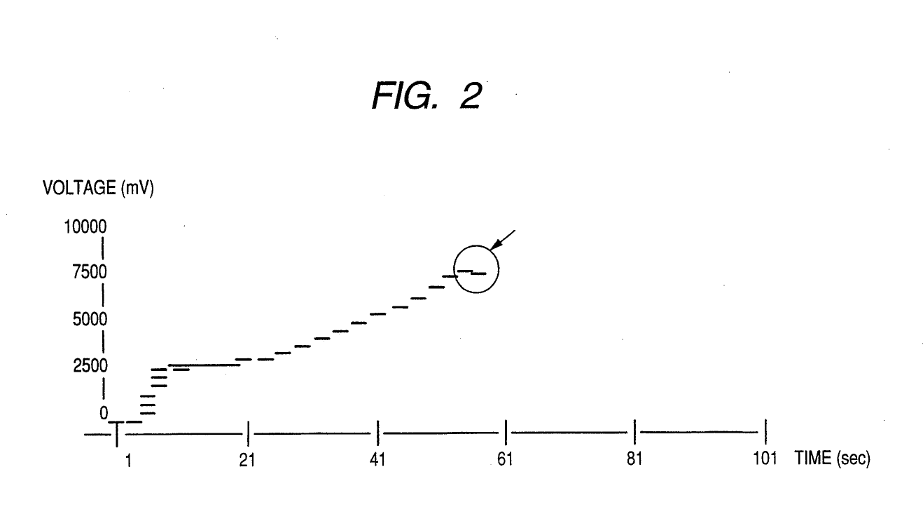

A relationship between the voltage input in the termination controller 12 and time is shown in FIG. 2. In FIG. 2, a voltage detected by the RF sensor 10 and input into the termination controller 12 via the electronic module 11 is plotted along the ordinate and its unit is mV. Along the abscissa, on the other hand, time starting from the initiation of cleaning in the chamber 2 is plotted and its unit is second (s).

As is apparent from FIG. 2, a voltage drastically increases for about 10 seconds just after the initiation of the cleaning in the chamber 2 and becomes about 2500 (mV). For about 20 seconds thereafter, the voltage becomes substantially constant at about 2500 (mV) and for a period from 20 to 55 seconds, a voltage rises. At about 55 seconds, the voltage becomes substantially constant at about 7500 (mV). The voltage is substantially constant in an encircled portion in FIG. 2. It has been revealed by the experience of the present inventors that a substantially constant voltage means removal of an unnecessary film in the chamber 2. The end point of the cleaning in the chamber 2 therefore exists at about 55 seconds. Here, a predetermined voltage is set at about 2500 (mV) or greater but not greater than about 7500 (mV).

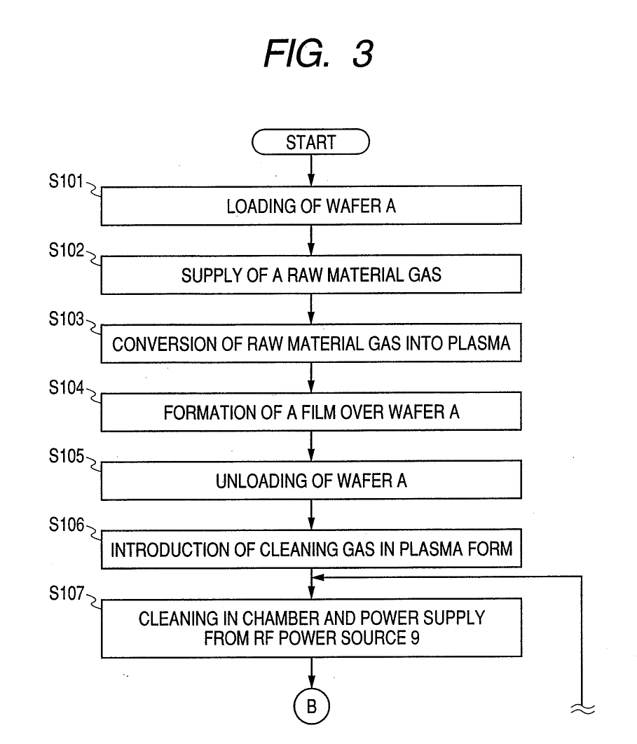

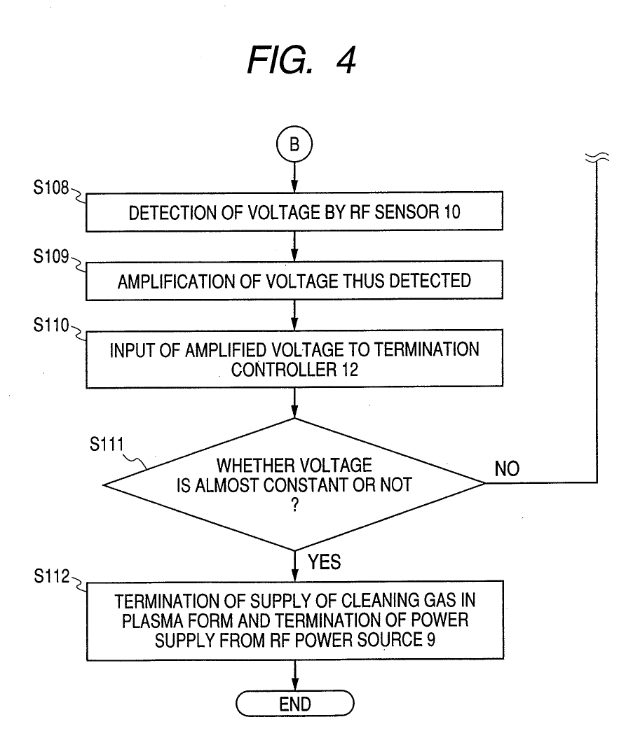

The plasma CVD apparatus 1 of Embodiment 1 has such a constitution as described above. Its operation and effects will next be described referring to FIGS. 1, 3 and 4. FIGS. 3 and 4 are each a flow chart explaining the operations of the plasma CVD apparatus 1 in Embodiment 1.

A gas in the chamber 2 is discharged outside by the pump 3 connected to the bottom surface of the chamber 2, whereby the pressure in the chamber 2 is reduced to a certain vacuum condition (reduced pressure).

The wafer A is then loaded in the plasma CVD apparatus 1 and is disposed on the lower electrode 4 (S101). By an unillustrated driving mechanism, the distance from the upper electrode 5 is adjusted to a predetermined one.

Raw material gases are then fed from the raw material gas feeder 7 to the chamber 2 via the pipe 6 (S102). For example, when a silicon oxide film is formed over the wafer A, monosilane (SiH₄) and oxygen gas (O₂) are introduced into the chamber 2 as raw material gases.

A high frequency voltage (first voltage) is then applied to the lower electrode 4 and upper electrode 5 connected to the radio frequency power source 9. A high frequency electric field then appears between the lower electrode 4 and upper electrode 5 and converts the raw material gases fed from the raw material gas feeder 7 into plasma (S103). By the action of ions or radicals formed by conversion of the raw material gases into plasma, a film is formed over the wafer A disposed on the lower electrode 4 (S104). Simultaneously with the formation of the film over the wafer 1, a film which will be a cause of foreign matters is formed over the interior wall or electrodes in the chamber 2. The output of the radio frequency power source 9 at this time is, for example, about 700 W.

After the wafer A having a film formed thereover is unloaded outside of the chamber 2 (S105), a cleaning gas (for example, NF₃) converted into plasma in the plasma gas generator 8 is introduced into the chamber 2 which is under reduced pressure (S106). Described specifically, when ions or radicals formed by conversion of a cleaning gas into plasma are introduced into the chamber 2, they react with the silicon oxide film or silicon nitride film formed on the interior wall or electrodes of the chamber 2, leading to formation of a gas such as SiF₄. The SiF₄ gas is discharged outside from the chamber 2 by the pump 3. The interior of the chamber 2 can thus be cleaned by gasifying the deposited film and discharging the resulting gas outside.

Upon cleaning in the chamber 2, electricity is supplied to the pair of electrodes from the radio frequency power source 9 and a high frequency voltage (second voltage) is applied between the lower electrode 4 and upper electrode 5. The output of the radio frequency power source 9 is lower than that upon film formation and is, for example, from about 10 to 50 W (S107). This voltage is detected by the RF sensor 10 (S108). The voltage detected by the RF sensor 10 is amplified by the electronic module 11 (S109) and the voltage thus amplified by the electronic module 11 is output to the termination controller 12.

When the amplified voltage is input to the termination controller 12 (S110), it judges whether the voltage becomes constant at a predetermined voltage or greater (S111). When the voltage does not become constant at a predetermined voltage or greater, cleaning in the chamber 2 is continued, so does the supply of electricity to the radio frequency power source 9 (S107). When the voltage becomes constant at a predetermined voltage or greater, on the other hand, supply of electricity to the electrode by the radio frequency power source 9 is stopped. The supply of the plasma cleaning gas to the chamber 2 is also stopped by the termination controller 12 (S112). The supply of the cleaning gas in plasma form to the gas chamber 2 can be stopped by physically inhibiting the supply of the plasma cleaning gas to the gas chamber 2 or stopping the formation of the plasma cleaning gas in the plasma gas generator 8.

The end point of the cleaning can thus be automatically detected so that cleaning in the chamber 2 can be carried out efficiently. This leads to an improvement in throughput. In addition, since the using amount of the expensive gas can be reduced, the cost of the cleaning gas lowers.

Moreover, cleaning even after the removal of the film formed in the chamber 2, so-called over-etching can be suppressed, making it possible to prolong the life of the process kit. Suppression of over-etching is also effective for preventing generation of foreign matters which will otherwise occur by the etching of the process kit (parts).

### EMBODIMENT 2

In Embodiment 2, the present invention is applied, for example, to a fabrication method of a semiconductor integrated circuit device using a plasma CVD apparatus.

FIG. 5 is a top view of the appearance of a plasma CVD apparatus used in Embodiment 2. In FIG. 5, the plasma CVD apparatus used in Embodiment 2 has a buffer chamber 20, a buffer robot 21, process chambers (first film forming chamber) 22a to 22f, a plasma gas generator 23, a storage elevator 24, a cassette chamber 25 and a front robot 26.

The buffer chamber 20 is a chamber for loading a wafer into the process chambers 22a to 22f and it has a buffer robot 21. This buffer robot 21 is able to load the wafer in the process chambers 22a to 22f or unload the wafer from the process chambers 22a to 22f. It is able to move 2 wafers simultaneously.

The process chambers 22a to 22f are chambers for forming a film over the wafer. The plasma CVD apparatus used in Embodiment 2 has three pairs of the process chambers. For example, the process chamber 22a and process chamber 22b form a pair. Similarly, the process chambers 22c and 22d, and the process chambers 22e and 22f, each constitutes a pair.

Each pair of process chambers is equipped with one plasma gas generator 23 to be used upon cleaning for the removal of a film formed inside of the process chambers 22a to 22f. In other words, the plasma gas generator 23 is able to convert a cleaning gas such as NF₃ (mixed with an argon gas as an inert gas) into plasma and generate fluorine radicals and, then introduce the resulting plasma cleaning gas into the process chambers 22a to 22f. In the plasma CVD apparatus to be used in Embodiment 2, the plasma gas generator 23 is disposed outside of the process chambers 22a to 22f. Compared with conversion of the cleaning gas into plasma in the process chambers 22a to 22f, damage on the parts (process kit) in the process chambers 22a to 22f are less when conversion is preformed in the plasma gas generator 23 disposed outside the process chambers 22a to 22f. This leads to prolongation of the life of the process kit.

In the storage elevator 24, wafers before or after film formation in the process chambers 22a to 22f are stored temporarily. For example, 12 wafers can be stored in the storage chamber 24. In the cassette chamber 25, a cassette containing 25 wafers can be placed. The front robot 26 transfers wafers between the cassette 27 in the cassette chamber 25 and storage elevator 24.

In the above-described plasma CVD apparatus, film formation over the wafer and cleaning in the process chambers 22a to 22f are carried out. The cleaning step and the film formation step over the wafer are conducted alternately. In other words, the plasma CVD apparatus is cleaned while the fabrication line of the semiconductor integrated circuit device is in operation.

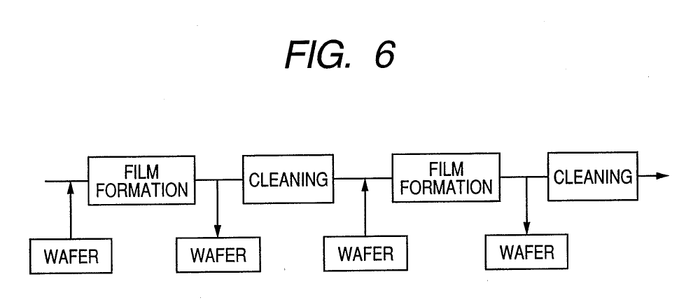

FIG. 6 illustrates a simple sequence for film formation over a wafer and cleaning in the process chambers 22a to 22f in the plasma CVD apparatus of Embodiment 2. As is apparent from FIG. 6, wafers are loaded in the process chambers 22a to 22f of the plasma CVD apparatus, followed by film formation over each wafer in the process chambers 22a to 22f in which the wafers are loaded. After completion of the film formation over the wafer, the wafers are unloaded from the process chambers 22a to 22f, followed by cleaning of the process chambers 22a to 22f. When the cleaning of the process chambers 22a to 22f is completed, new wafers are loaded in the process chambers 22a to 22f and film formation is conducted therein. After completion of the film formation over the wafers, the wafers are unloaded from the process chambers 22a to 22f, followed by cleaning of the process chambers 22a to 22f. Similarly, the film formation over the wafers and cleaning of the process chambers 22a to 22f are conducted alternately. In this manner, the film formation over the wafers and cleaning of the process chambers 22a to 22f can be carried out in the plasma CVD apparatus.

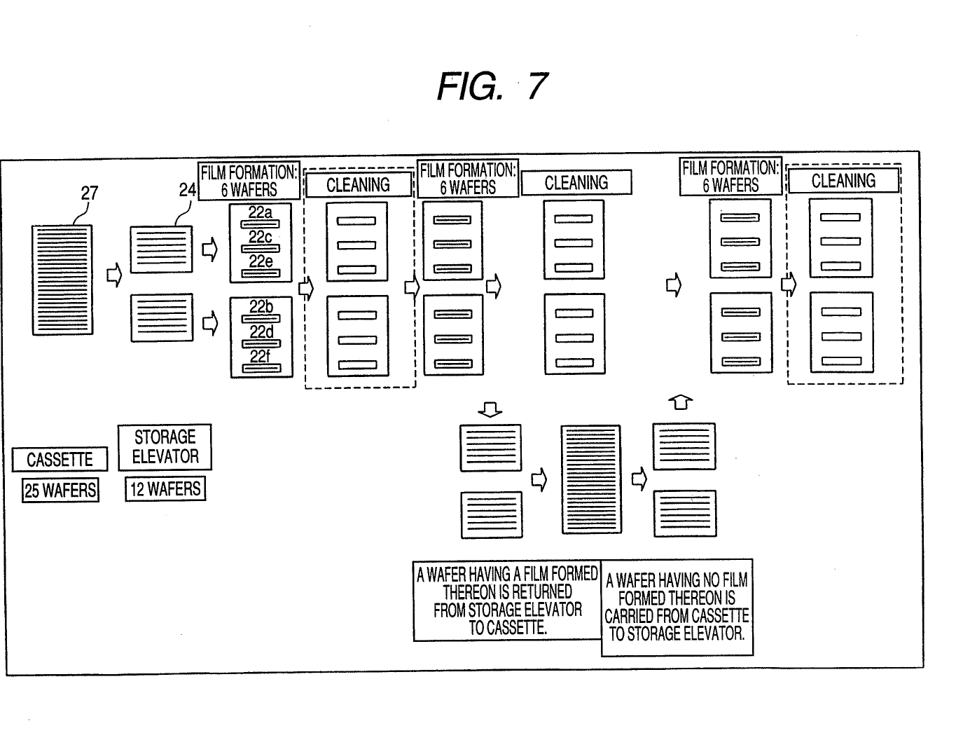

Referring to FIGS. 5 and 7, a sequence for performing film formation over wafers and cleaning of the process chambers 22a to 22f will next be described more specifically. First, the cassette 27 containing twenty five wafers is disposed in the cassette chamber 25 illustrated in FIG. 5. Twelve wafers are taken out from the cassette 27 by means of the front robot 26 and they are stored in the storage elevator 24. From the twelve wafers stored in the storage elevator 24, two wafers are taken out at a time and loaded in the process chambers 22a to 22f by means of the buffer robot 21. One wafer is loaded in each of the process chambers 22a to 22f so that six wafers are loaded in total. In the process chambers 22a to 22f having the wafers loaded therein, a film is formed over the wafer. The six wafers are then taken out from the process chambers 22a to 22f by means of the buffer robot 21 and stored in the storage elevator 24 again. The process chambers 22a to 22f from which the wafers have been unloaded are cleaned. After completion of the cleaning of the process chambers 22a to 22f, six wafers stored in the storage elevator 24 and having no film formed thereover yet are loaded into each of the process chambers 22a to 22f by means of the buffer robot 21. After film formation over the wafer, the resulting wafers are transferred from the process chambers 22a to 22f to the storage elevator 24. At this time, all the twelve wafers stored in the storage elevator 24 have a film formed thereover. By means of the front robot 26, the wafers were returned to the cassette 27 from the storage elevator 24. During this time, the process chambers 22a to 22f are free so that they are cleaned. From the cassette 27, twelve wafers having no film formed thereon yet are taken out and transferred to the storage elevator 24. From the twelve wafers stored in the storage elevator 24, two wafers are taken out at a time and loaded in the process chambers 22a to 22f by means of the buffer robot 21. In the process chambers 22a to 22f having the wafers loaded therein, a film is formed over the wafer. The six wafers are then taken out from the process chambers 22a to 22f by means of the buffer robot 21 and stored in the storage elevator 24 again. The process chambers 22a to 22f from which the wafers have been unloaded are cleaned. Thus, film formation over the wafer and cleaning of the process chambers 22a to 22f can be carried out in the plasma CVD apparatus.

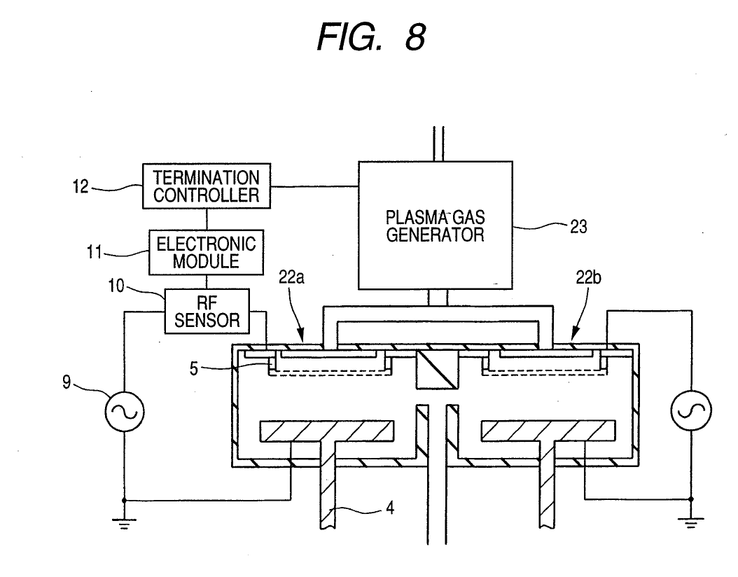

The constitution of each of the process chambers 22a to 22f which carry outs film formation over the wafers and cleaning will next be described referring to FIG. 8. FIG. 8 illustrates the constitution of a pair of process chambers 22a and 22b. In FIG. 8, a plasma gas generator 23 is disposed outside the pair of process chambers 22a and 22b. As described above, the plasma gas generator 23 is constituted so that it can convert the cleaning gas into plasma and generate fluorine radicals and the like.

Inside of each of the process chambers 22a and 22b, a pair of electrodes made of a lower electrode 4 and upper electrode 5 is disposed. A radio frequency power source (oscillator) 9 is electrically connected to this pair of electrodes and is constituted so that it can supply electricity thereto.

In the process chamber 22a, an RF sensor 10 is disposed between the radio frequency power source 9 and the pair of electrodes. This RF sensor 10 is constituted in so that it can detect a voltage generated between the pair of electrodes when electricity is supplied thereto from the radio frequency power source 9.

To the RF sensor 10, an electronic module 11 is connected and to this electronic module 11, a termination controller 12 is electrically connected. The electronic module 11 is constituted so that it can amplify the voltage detected by the RF sensor 10. A termination controller 12 can input therein a voltage detected by the RF sensor via the electronic module 11 and based on a change in the voltage, control the feeding or termination of feeding of the plasma cleaning gas to the process chambers 22a and 22b. The RF sensor 10, electronic module 11 and termination controller 12 are not essential for the process chamber 22b.

The plasma CVD apparatus to be used in Embodiment 2 has the constitution as described above. Its operation for forming a film over the wafer and cleaning the interior of the process chambers 22a and 22b will next be described.

First, the operation for forming a film over the wafer will be described referring to FIG. 8. Wafers are loaded in the chambers 22a and 22b respectively for film formation. The wafer thus loaded is placed on a lower electrode 4. A raw material gas (second gas) for the film will next be introduced in the process chambers 22a and 22b. Electricity (second radio frequency power having second intensity) is supplied from the radio frequency power source 9 to a pair of electrodes made of the lower electrode 4 and upper electrode 5. The electricity supplied from the radio frequency power source 9 is high and for example, 700 W. By the electricity supplied from the radio frequency power source 9, a high voltage appear between the pair of electrodes, and the raw material gas existing between the pair of electrodes is converted into plasma by this high voltage. Owing to a chemical reaction of the raw material gas converted into plasma, a film is formed over the wafer disposed on the lower electrode 4. The film is formed over the wafer in such a manner but, a film (undesired film member) is also formed simultaneously in the interior of the process chambers 22a and 22b other than the wafer. This film formed in the process chambers 22a and 22b will be a cause for foreign matters so that the process chambers 22a and 22b are cleaned. The cleaning of the process chambers 22a and 22b will next be described referring to FIG. 8.

In the plasma gas generator 34 disposed outside the process chambers 22a and 22b, a cleaning gas such as NF₃ (mixed with a dilution gas such as argon gas) is introduced. (The cleaning gas is not limited only to a nitrogen halide when the film to be cleaned is a silicon-based dielectric film, but a fluorocarbon gas such as C₂F₆, C₃F₈ or CF₄ can be used. A nitrogen fluoride gas such as NF₃ or halide gas free of carbon is advantageous because of a low global warming potential. Any substance can be used insofar as it does not generate undesirable damage or contamination and is converted into a volatile substance by generating fluorine radicals and thereby reacting with silicon.) In the plasma gas generator 23, the cleaning gas (first gas) is converted into plasma and fluorine radicals or ions are formed. The cleaning gas converted into plasma in the plasma gas generator 23 is then fed to the process chambers 22a and 22b. This plasma cleaning gas having rich reactivity reacts with the film formed in the process chambers 22a and 22b. The reaction product thus obtained by the reaction is discharged outside of the process chambers. In such a manner, a film formed in the process chambers 22a and 22b can be removed by cleaning.

As described above, Embodiment 2 adopts a so-called remote plasma method which converts the cleaning gas into plasma not inside of the process chambers 22a and 22b, but in the plasma gas generator 23 outside of the process chambers 22a and 22b, and feeding the resulting plasma cleaning gas to the process chambers 22a and 22b.

Cleaning by the remote plasma method is advantageous because since conversion of the cleaning gas into plasma is not carried out in the process chambers 22a and 22b, parts (process kit) such as lower electrode 4 and upper electrode 5 are not damaged upon cleaning. In this remote plasma method, an end point of the cleaning is usually determined in advance by a test or the like and in the actual fabrication line, 1.2 times as much as the cleaning time determined in advance is spent for the cleaning.

Cleaning time for about 1.2 times as much as that determined in advance however lowers a throughput and in addition, deteriorates the parts by over-etching. Moreover, over-etching of the parts may generate foreign matters and heightens the cost owing to an increase in the amount of the cleaning gas.

In Embodiment 2, therefore, automatic end-point detection of cleaning is carried out properly. In the usual cleaning using remote plasma, electricity is not supplied to a pair of electrodes made of the lower electrode 4 and the upper electrode 5 in order to reduce damage of the parts. In this Embodiment, on the other hand, electricity is fed to the pair of electrodes within an extent not damaging the parts. Described specifically, in Embodiment 2, electricity necessary for maintaining the cleaning gas in plasma form is supplied to the pair of electrodes during cleaning of the process chambers 22a and 22b using remote plasma.

Electricity (second electricity) (first high frequency electricity having a first intensity) to be fed to the pair of electrodes is smaller than the electricity (first electricity) fed when a raw material gas is converted into plasma for the formation of a film over the wafer. The smaller electricity is preferred from the viewpoint of preventing damage of the parts. It is therefore desirable to supply the pair of electrodes with the minimum electricity necessary for maintaining the cleaning gas in plasma form. More specifically, from 1 to 10% of the electricity fed to the pair of electrodes for the film formation over the wafer is preferred. The electricity to be fed to the pair of electrodes is not limited to the above-described range. The damage to the parts can be reduced when the electricity is smaller than that fed upon conversion of the raw material gas into plasma for forming a film over the wafer, so that the electricity of from 1 to 50%, or even from 50 to 80% of the electricity fed to the pair of electrodes upon film formation over the wafer can be adopted. In particular, a range of from 0.05% to 40% of the electricity supplied to the pair of electrodes for the film formation over the wafer is desired in view of lessening the damage given to the parts and converting the cleaning gas into plasma (plasma excitation). From the above-described viewpoint, the electricity may be from 0.1 to 30%, moreover from 0.5 to 20%, of the electricity supplied to the pair of electrodes for the formation of a film over the wafer.

When electricity is supplied to the pair of electrodes made of the lower electrode 4 and the upper electrode 5 from the radio frequency power source 9, a voltage (potential difference) appears between the pair of electrodes. This voltage is detected by the RF sensor 10 electrically connected to the electrodes. After the voltage thus detected by the RF sensor 10 is amplified by the electronic module 11, it is input to a termination controller 12. The termination controller 12 automatically detects the end point of the cleaning based on the voltage thus input. In this Embodiment 2, the end point of the cleaning is automatically detected by making use of, as physical or chemical properties of plasma, electrical properties plasma relating to the impedance.

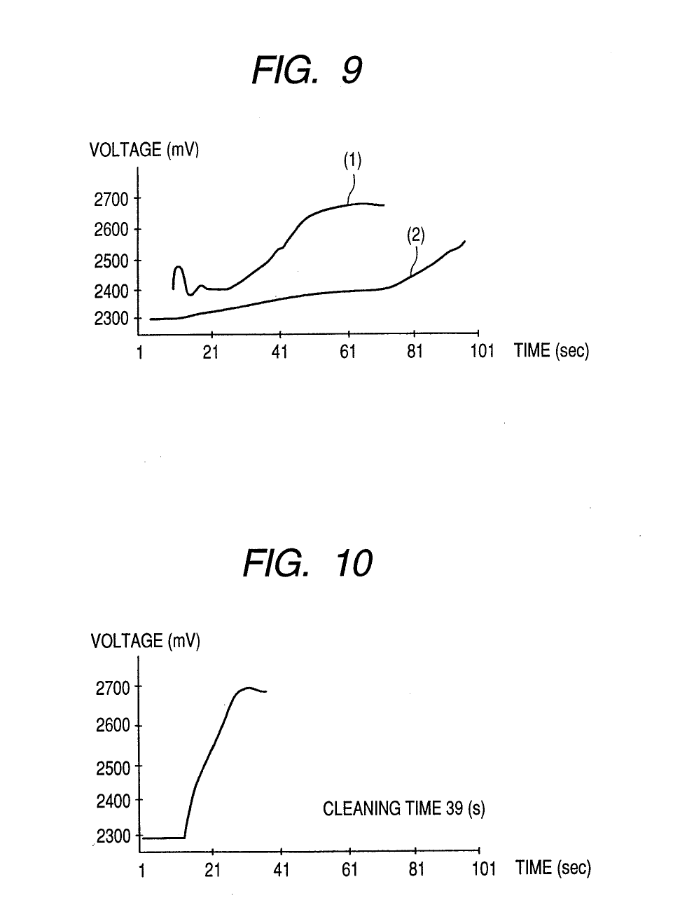

A method of automatically detecting the end point of cleaning in the termination controller 12 will next be described specifically referring to FIG. 9.

FIG. 9 illustrates the relationship between a voltage input to the termination controller 12 and time from initiation of the cleaning. In FIG. 9, the curve (1) shows the relationship between voltage and time when a cleaning gas is normally converted into plasma in the plasma gas generator 23, while the curve (2) shows the relationship between voltage and time when a cleaning gas is converted into plasma by an abnormal voltage lower than the normal voltage.

A description will first be made on the curve (1). In FIG. 9, a voltage (mV) input to the termination controller 12 is plotted along the ordinate, while the time (second) from initiation of the cleaning is plotted along the abscissa. As is apparent from FIG. 9, variations in voltage occur between 2400 mV to 2500 mV soon after initiation of the cleaning. A voltage gradually increases 20 seconds after initiation of the cleaning and after about 60 seconds, it becomes substantially constant. The voltage becomes constant between from 2600 mV to 2700 mV. The time when the voltage becomes substantially constant roughly coincides with the completion time of the cleaning in the process chambers 22a and 22b. As described above, the voltage varies during the cleaning time after initiation of the cleaning and it becomes stable when the cleaning is almost completed. This is presumed to occur because the cleaning gas in plasma form fed from the plasma gas generator 23 to the process chambers 22a and 22b is consumed during cleaning, reacting with a film formed on the interior walls of the process chambers 22a and 22b. Upon completion of the cleaning, on the other hand, the film formed in the process chambers 22a and 22b has been removed and no cleaning gas in plasma form is consumed. When the input voltage becomes substantially constant at a specific value (in this case, for example, 2600 mV) or greater, the termination controller 12 judges that the cleaning in the process chambers 22a and 22b is completed and stops feeding of the plasma cleaning gas from the plasma gas generator 23.

According to Embodiment 2, the finish time of the cleaning in the process chambers 22a and 22b can be automatically detected so that the cleaning in the chamber 2 can be carried out efficiently. This leads to an improvement in the throughput. In addition, owing to a reduction in the using amount of an expensive gas, the cost of the cleaning gas can be decreased.

Moreover, cleaning even after removal of the film formed in the chamber, that is, so-called over-etching can be suppressed so that prolongation of the life of the process kit can be attained. This suppression of over-etching prevents generation of foreign matters which will otherwise occur by the etching of the process kit (parts).

A description will next be made of the curve (2). This curve (2) indicates the relationship between voltage and time when the cleaning gas in plasma form is formed at a voltage lower than the normal voltage owing to abnormal output of the plasma gas generator 23. As is apparent from FIG. 9, the voltage shows a gradual increase after the initiation of the cleaning. Even when about 60 seconds have passed after the initiation of the cleaning, the voltage does not become constant and continues increasing. When the plasma gas generator 23 works normally, the voltage becomes substantially constant 60 seconds after the initiation of the cleaning, from which completion of the cleaning can be judged. When owing to abnormal output, the plasma gas generator 23 works at a voltage lower than that upon normal time, the voltage does not become constant at a specific voltage or greater and the end point of the cleaning cannot be detected. This is presumed to occur because the amount of the cleaning gas in plasma form is less than that upon normal time and therefore, the cleaning is not finished even after 60 seconds have passed after the initiation of the cleaning.

If the voltage does not become constant even after the normal cleaning time has passed, the termination controller generates an alarm (interlock) at the plasma CVD apparatus and terminates its operation, judging that the plasma gas generator 23 of the plasma CVD apparatus has something abnormal. More specifically, when the cleaning time is longer than the normal cleaning time by from 10% to 40%, the termination controller 12 activates an interlock system and terminates the plasma CVD apparatus.

According to Embodiment 2, abnormality of the plasma gas generator 23 can be detected by the termination controller 12. In the conventional method in which cleaning is conducted for a predetermined time, the cleaning is finished within this time irrespective of the abnormality in the plasma gas generator 23 and the subsequent step for the film formation over the wafer follows. Since the film formation over the wafer is conducted even though the cleaning of the process chambers 22a and 22b is not finished owing to the abnormality in the plasma gas generator 23, the film thus formed is not normal owing to insufficient cleaning in the process chambers 22a and 22b, leading to preparation of an inferior wafer. For example, when a film remains over the pair of electrodes owing to insufficient cleaning, the state of the plasma gas changes, which changes the film forming conditions. By this, the film formed over the wafer has sometimes abnormal film quality.

In this Embodiment 2, abnormality of the plasma gas generator 23 can be detected during cleaning so that formation of a film having an abnormal film quality over the wafer can be prevented in advance.

The abnormality in the plasma gas generator 23 can be classified into abnormality of a power source and that resulting from the inside of the plasma gas generator 23. The abnormality of the power source can be detected by the error sign of the power source, but abnormality resulting from the interior of the plasma gas generator 23 cannot be discovered easily. Monitoring of the voltage input to the termination controller 12 as described above, however, facilitates the detection of the abnormality.

Referring to FIGS. 10 to 15, a description will next be made of the relationship between a voltage input to the termination controller 12 and time from initiation of the cleaning upon cleaning of the plasma CVD apparatus when thickness of a film to be formed by the plasma CVD apparatus is changed. In FIGS. 10 to 15, a voltage input to the termination controller 12 is plotted along the coordinate, while the time from initiation of the cleaning is plotted along the abscissa.

FIG. 10 illustrates the cleaning of the process chambers 22a and 22b of the plasma CVD apparatus after formation of an about 200 nm thick film over a wafer in the plasma CVD apparatus. As is apparent from FIG. 10, the voltage becomes constant upon initiation of the cleaning, but it gradually increases with the passage of time and becomes substantially constant about 35 seconds after the cleaning is started. At this film thickness, it takes about 39 seconds to complete the cleaning. The waveform is stable not only upon termination of the cleaning but also upon initiation of the cleaning. Since the termination controller 12 is designed to neglect the waveform for a certain time after the cleaning is started, an appropriate finish time of the cleaning can be detected automatically without causing its malfunction.

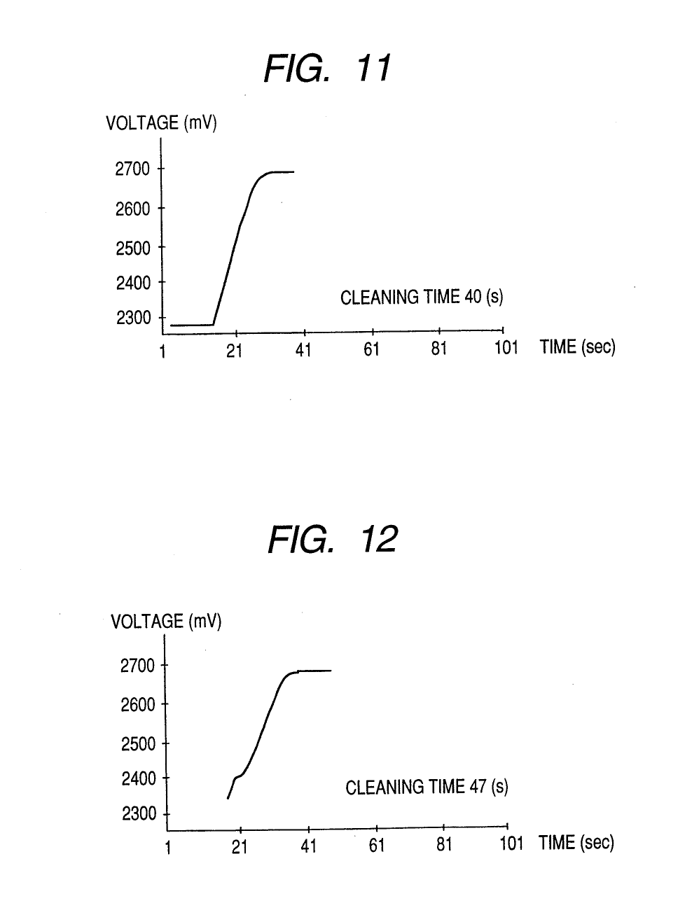

FIG. 11 illustrates the cleaning of the process chambers 22a and 22b after formation of an about 300 nm thick film over a wafer. As is apparent from FIG. 11, the voltage becomes constant for certain time after initiation of the cleaning, but it gradually increases with the passage of time and becomes substantially constant about 36 seconds after cleaning is started. At this film thickness, it takes about 40 seconds to complete the cleaning. Owing to a relatively greater thickness of a film formed over the wafer, cleaning time in FIG. 11 is longer than that in FIG. 10. An increase in the film thickness formed over a wafer causes an increase in the film thickness formed on the interior wall of the process chambers 22a and 22b. This leads to prolongation of cleaning time for the removal of this film.

FIG. 12 illustrates the cleaning of the process chambers 22a and 22b after formation of an about 400 nm thick film over a wafer. As is apparent from FIG. 12, the voltage shows a gradual increase after the cleaning is started and it becomes substantially constant after about 41 seconds. At this film thickness, it takes about 47 seconds to complete the cleaning.

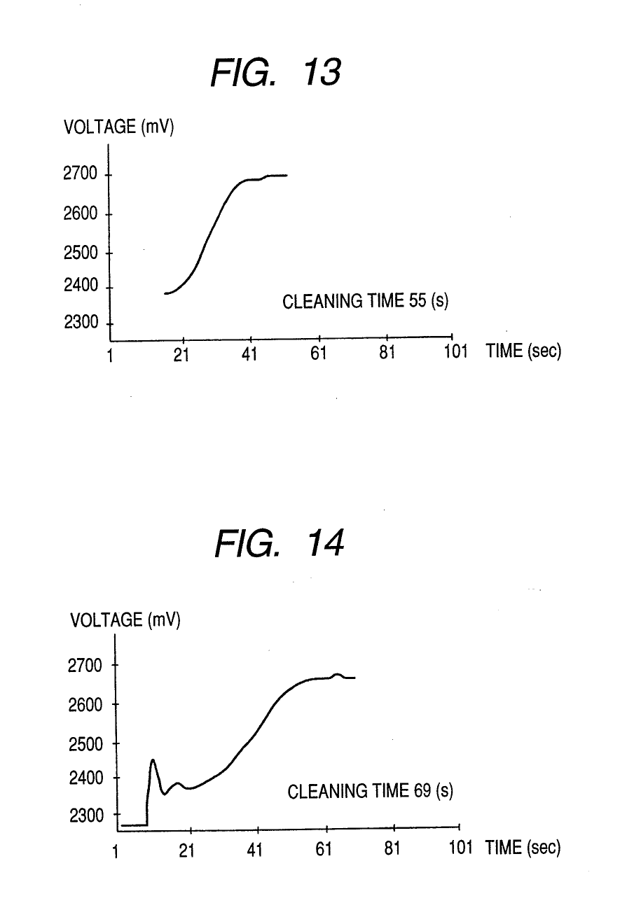

FIG. 13 illustrates the cleaning of the process chambers 22a and 22b after formation of an about 600 nm thick film over a wafer. As is apparent from FIG. 13, the voltage shows a gradual increase after the cleaning is started and it becomes substantially constant after about 50 seconds. At this film thickness, it takes about 55 seconds to complete the cleaning.

FIG. 14 illustrates the cleaning of the process chambers 22a and 22b after formation of an about 800 nm thick film over a wafer. As is apparent from FIG. 14, the voltage is constant for certain time after the initiation of the cleaning. About from 10 to 20 seconds after the initiation of the cleaning, the voltage fluctuates between about 2300 mV and about 2450 mV. It thereafter shows a gradual increase and becomes substantially constant after about 65 seconds. At this thickness, it takes about 69 seconds to complete the cleaning.

FIG. 15 illustrates the cleaning of the process chambers 22a and 22b after formation of an about 1100 nm thick film over a wafer. As is apparent from FIG. 15, the voltage shows a steep rise from about 2300 mV to about 2700 mV just after the initiation of the cleaning and then, continues to decrease until about 20 seconds after the initiation. The voltage gradually increases after 20 seconds and becomes substantially constant after about 71 seconds. At this thickness, it takes about 78 seconds to complete the cleaning.

As illustrated in FIGS. 10 to 15, the waveform of voltage during cleaning differs with the thickness of the film formed over a wafer, but at any film thickness, the voltage becomes constant near the completion of the cleaning. Even if the thickness of a film formed over the wafer by the plasma CVD apparatus is different, the termination controller 12 detects the time point when a voltage becomes substantially constant at a certain voltage or greater, whereby an appropriate end point of the cleaning can be automatically detected.

Examination results on whether or not the use of the automatic detection method of the cleaning end-point as described in Embodiment 2 adversely affects the quality of a film formed by the plasma CVD apparatus will next be shown. In this Embodiment 2, upon cleaning by remote plasma, electricity is supplied from the radio frequency power source 9 to a pair of electrodes made of the lower electrode 4 and the upper electrode 5. Upon conventional cleaning using remote plasma, on the other hand, electricity is not fed to the pair of electrodes. It is therefore examined whether or not the supply of electricity to a pair of electrodes upon cleaning has harmful effects on the film formation over the wafer after cleaning.

As illustrated in FIG. 8, the radio frequency power source 9, RF sensor 10, electronic module 11 and termination controller 12 are connected to the process chamber 22a and automatic end-point detection of the cleaning is conducted according to Embodiment 2. In the process chamber 22b, on the other hand, automatic end-point detection of the cleaning is not performed. Described specifically, upon completion of the cleaning of the process chamber 22a by the automatic end-point detection, the cleaning of the process chamber 22b is also completed. Upon cleaning, electricity is not fed to the pair of electrodes in the process chamber 22b. By comparing the wafer having a film formed thereover in the process chamber 22a and that having a film formed thereover in the process chamber 22b, it is possible to study whether or not the electricity supply to the pair of electrodes upon cleaning adversely affects the film formation over the wafer after cleaning.

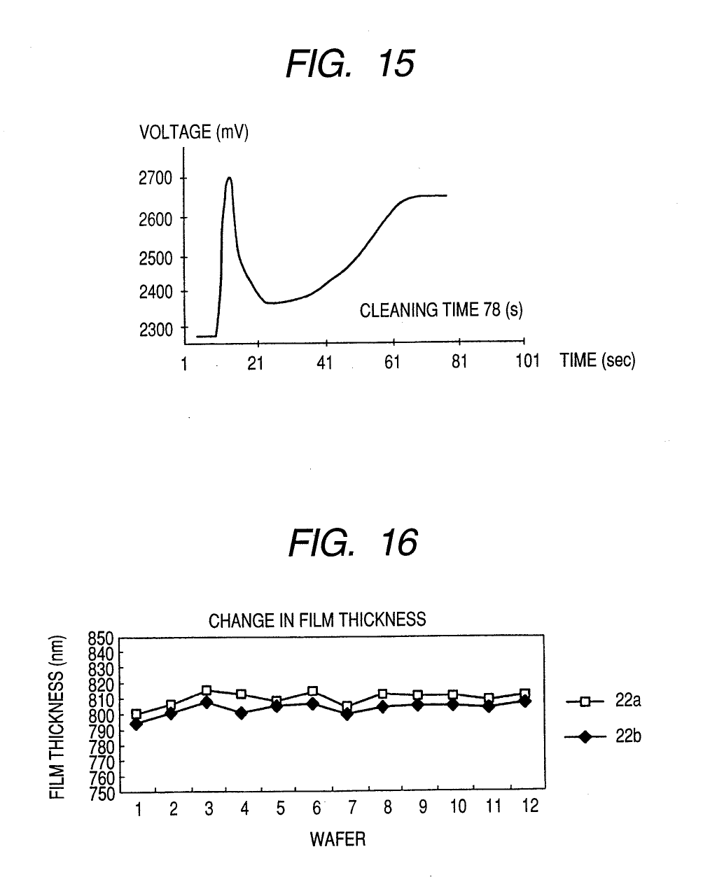

FIG. 16 illustrates the comparison results between the thickness of a film formed over the wafer in the process chamber 22a and that formed in the process chamber 22b. In FIG. 16, film thickness is plotted along the ordinate, while the wafer treated in the n-th order (n stands for positive integer) is plotted along the abscissa. As is apparent from FIG. 16, thickness of the film formed over the wafer in the process chamber 22a ranges from about 800 nm to about 820 nm, while that formed in the process chamber 22b ranges from about 790 nm to about 810 nm. There is accordingly no marked difference in the thickness between the film formed over the wafer in the process chamber 22a and that formed in the process chamber 22b. It has been understood that from the viewpoint of the thickness of the film formed over the wafer, the automatic end-point detection method of the cleaning in Embodiment 2 does not adversely affect the film formation over the wafer after cleaning. The allowable range of film thickness is from about 760 nm to about 840 nm. Judging from this range, film formation in the process chambers 22a and 22b is carried out normally.

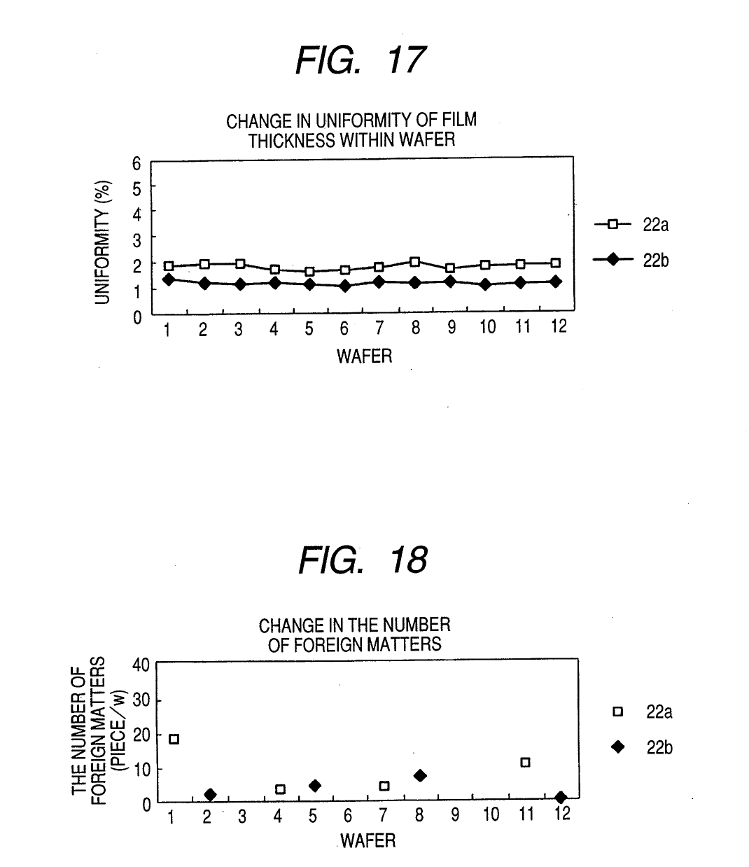

FIG. 17 illustrates the comparison results in the uniformity of film thickness between the film formed over the wafer in the process chamber 22a and that in the process chamber 22b. In FIG. 17, the uniformity of the film thickness is plotted along the ordinate, while the wafer treated in the n-th order (n stands for a positive integer) is plotted along the abscissa. In this diagram, the uniformity is determined by (the maximum thickness in the wafer−the minimum thickness in the wafer)/(the maximum thickness in the wafer+the minimum thickness in the wafer)×100. As is apparent from FIG. 17, the uniformity of the film thickness in the process chamber 22a ranges from 1.5% to 2%, while that in the process chamber 22b ranges from 1% to 1.5%. There is accordingly no marked difference between the process chamber 22a and the process chamber 22b. It has been found that from the viewpoint of the uniformity of the film thickness over the wafer, the automatic detection method of the end-point of cleaning in Embodiment 2 does not adversely affect the film formation conducted after cleaning. The allowable range of the uniformity of the film thickness is 5% or less. Judging from this range, the film formation is carried out normally in the process chambers 22a and 22b.

FIG. 18 illustrates the comparison results in the number of foreign matters on the wafer between the wafer formed in the process chamber 22a and that formed in the process chamber 22b. In FIG. 18, the number of foreign matters per wafer is plotted along the ordinate, while the wafer treated in the n-th order (n stands for a positive integer) is plotted along the abscissa. As is apparent from FIG. 18, the number of the foreign matters on the wafer formed in the process chamber 22a is about 20 or less, while that in the process chamber 22b is about 10 or less. There is accordingly no marked difference between the process chamber 22a and the process chamber 22b. It has been found from the number of foreign matters on the wafer that the automatic detection method of the end-point of cleaning in Embodiment 2 does not adversely affect the film formation on the wafer conducted after cleaning. The allowable range of the number of foreign matters is 30 or less. Judging from this range, the film formation is carried out normally in the process chambers 22a and 22b.

FIG. 19 illustrates the comparison results between the stress of a film formed over the wafer in the process chamber 22a and that formed over the wafer in the process chamber 22b. In FIG. 19, the film stress (Mpa) is plotted along the ordinate, while the wafer treated in the n-th order (n stands for a positive integer) is plotted along the abscissa. The film stress serves as an index for evaluating the film quality such as hardness. As is apparent from FIG. 19, the stress of the film formed over the wafer in the process chamber 22a ranges from −100 (Mpa) to −90 (Mpa), while that formed over the wafer in the process chamber 22b ranges from −110 (MPa) to −100 (MPa). There is accordingly no marked difference between the process chambers 22a and 22b. In other words, there is no marked difference in the quality of the film formed over the wafer. It has been found that from the viewpoint of the film stress, the automatic detection method of the end-point of cleaning in Embodiment 2 does not adversely affect the film formation over the wafer conducted after cleaning. The allowable range of the film stress ranges from −120 (Mpa) to −80 (MPa) so that the film formation is carried out normally both in the process chambers 22a and 22b.

It was examined from the various viewpoints whether or not the automatic detection method of the cleaning end-point in Embodiment 2 adversely affects the film formation over the wafer conducted after cleaning. The above-described results suggest that the automatic detection method has no adverse effects.

A fabrication method of a semiconductor integrated circuit device by using the plasma CVD apparatus which adopts the automatic detection method of the cleaning end-point in Embodiment 2 will next be described.

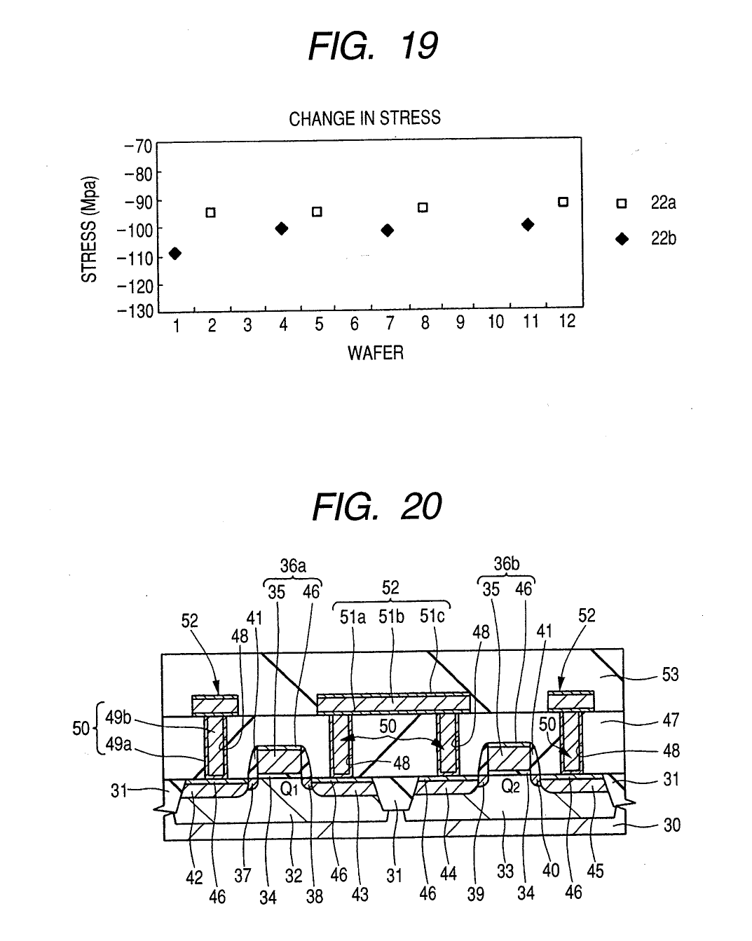

FIG. 20 is a cross-sectional view of MIS transistor Q₁ and MIS transistor Q₂ during the fabrication steps according to Embodiment 2. Referring to FIG. 6, fabrication steps of the MIS transistor Q₁ and MIS transistor Q₂ will next be described.

As illustrated in FIG. 20, a wafer 30 having, for example, a specific resistance of from about 1 to 10 Ωcm is prepared. This wafer 30 is made of p type single crystal silicon and has, over the main surface thereof, element isolation regions 31. These element isolation regions 31 are each made of silicon oxide and formed, for example, by STI (Shallow Trench Isolation) or LOCOS (Local Oxidization of Silicon).

A p well 32 is then formed in an active region separated by the element isolation regions 31 formed over the wafer 30, that is, a region in which an n channel type MIS transistor Q₁ is to be formed. The p well 32 is formed by introducing boron (B) or boron fluoride (BF₂), for example, through ion implantation. Similarly, an n well 33 is formed in a region in which a p channel type MIS transistor Q₂ is to be formed. This n well 33 is formed by introducing phosphorus (P) or arsenic (As), for example, through ion implantation.

Over the wafer 20, a gate insulating film 34 is formed. The gate insulating film 34 is made of, for example, a thin silicon oxide film and can be formed, for example, by thermal oxidation.

Over the gate insulating film 34, gate electrodes 36a and 36b are formed. The gate electrodes 36a and 36b are formed in the following manner. After formation of a polysilicon film 35 over the gate insulating film 34 over the wafer 30, the polysilicon film 35 is patterned by photolithography and etching, whereby the gate electrodes 36a and 36b made of the polysilicon film 35 are formed.

On both sides of the gate electrode 36a, lightly-doped n type impurity diffusion regions 37 and 38 are formed. These lightly-doped n type impurity diffusion regions 37 and 38 are formed by introducing an n type impurity such as phosphorus in the p well 32 by using, for example, ion implantation. Similarly, lightly-doped p type impurity diffusion regions 39 and 40 are formed in regions on both sides of the gate electrode 36b. The lightly-doped p type impurity diffusion regions 39 and 40 are formed by introducing a p type impurity such as boron or boron fluoride in the n well 33 by using, for example, ion implantation.

Over the sidewalls of each of the gate electrodes 36a and 36b, side wall spacers 41 are formed. The side wall spacers 41 can be formed by depositing a silicon oxide film over the wafer 30, for example, by CVD and then anisotropic etching the silicon oxide film thus deposited.

After formation of the side wall spacers 41, heavily doped n type impurity diffusion regions 42 and 43 are formed in regions on both sides of the gate electrode 36a. These heavily doped n type impurity diffusion regions 42 and 43 can be formed by introducing an n type impurity such as phosphorus by using, for example, ion implantation. The heavily doped n type impurity diffusion regions 42 and 43 have an impurity concentration higher than that of the above-described lightly-doped n type impurity diffusion regions 37 and 38. Similarly, heavily doped p type impurity diffusion regions 44 and 45 are formed in regions on both sides of the gate electrode 36b. These heavily doped p type impurity diffusion regions 44 and 45 are formed by introducing a p type impurity such as boron or boron fluoride by making use of, for example, ion implantation. Into these heavily doped p type impurity diffusion regions 44 and 45, a p type impurity has been introduced at a higher concentration than that in the lightly-doped p type impurity diffusion regions 39 and 40.

After exposure of the surface of the heavily doped n type impurity diffusion regions 42 and 43 and heavily doped p type impurity diffusion regions 44 and 45, a cobalt (Co) film is deposited over the wafer 30, for example, by CVD. The wafer is then heat treated to form a cobalt silicide film 46. The gate electrodes 36a and 36b made of the polysilicon film 35 and the cobalt silicide film 46 can thus be formed. The cobalt silicide film 46 can also be formed over the heavily doped n type impurity diffusion regions 42 and 43 and heavily doped p type impurity diffusion regions 44 and 45. This makes it possible to lower the resistance of the gate electrodes 36a and 36b and at the same time, lower the sheet resistance of the heavily doped n type impurity diffusion regions 42 and 43 and heavily doped p type impurity diffusion regions 44 and 45. An unreacted portion of the cobalt film is then removed.

In the above-described manner, the n channel type MIS transistor Q₁ and p channel type MIS transistor Q₂ can be formed.

A description will next be made of a metallization step. Over the wafer, a dielectric film 47 which will be an interlayer dielectric film is deposited, for example, by CVD. By photolithography and etching, a contact hole 48 penetrating through the dielectric film 47 is then formed. At the bottom of the contact hole 48, the cobalt silicide film 46 formed over each of the heavily doped n type impurity diffusion regions 42 and 43 and heavily doped p type impurity diffusion regions 44 and 45 is exposed.

A plug 50 is then formed by embedding a titanium/titanium nitride film 49a and a tungsten film 49b in the contact hole 48. The plug 50 can be formed, for example, in the following manner. Over the dielectric film 47 including the inside of the contact hole 48, the titanium/titanium nitride film 49a is formed, for example, by sputtering, followed by the formation of the tungsten film 49b, for example, by CVD to embed it in the contact hole 48. An unnecessary portion of the titanium/titanium nitride film 49a and tungsten film 49b formed over the dielectric film 47 is then removed by making use of CMP or etchback, whereby the plug 50 is formed.

Over the dielectric film 47 having the plug 50 formed therein, a titanium/titanium nitride film 51a, aluminum film 51b, and titanium/titanium nitride film 51c are formed successively. These films can be formed, for example, by sputtering. The titanium/titanium nitride film 51a, aluminum film 51b, and titanium/titanium nitride film 51c are then patterned by making use of photolithography and etching to form an interconnect 52. A dielectric film 53 is then formed, for example, by CVD over the dielectric film 47 and the interconnect 52. The dielectric film 53 is made of, for example, a silicon oxide film. In such a manner, the wafer 30 having the structure as illustrated in FIG. 20 can be formed.

The wafer 30 having the structure as illustrated in FIG. 20 is then loaded in the plasma CVD apparatus of FIG. 8 used in Embodiment 2. Described specifically, the wafer 30 is transferred into the process chamber 22a of the plasma CVD apparatus and this wafer 30 is disposed on the lower electrode 4. After introduction of TEOS and oxygen gases as raw material gases into the process chamber 22a, electricity is supplied to a pair of electrodes composed of the lower electrode 4 and upper electrode 5 from the radio frequency power source 9. Between the pair of electrodes, a voltage appears and the raw material gases are converted into plasma.

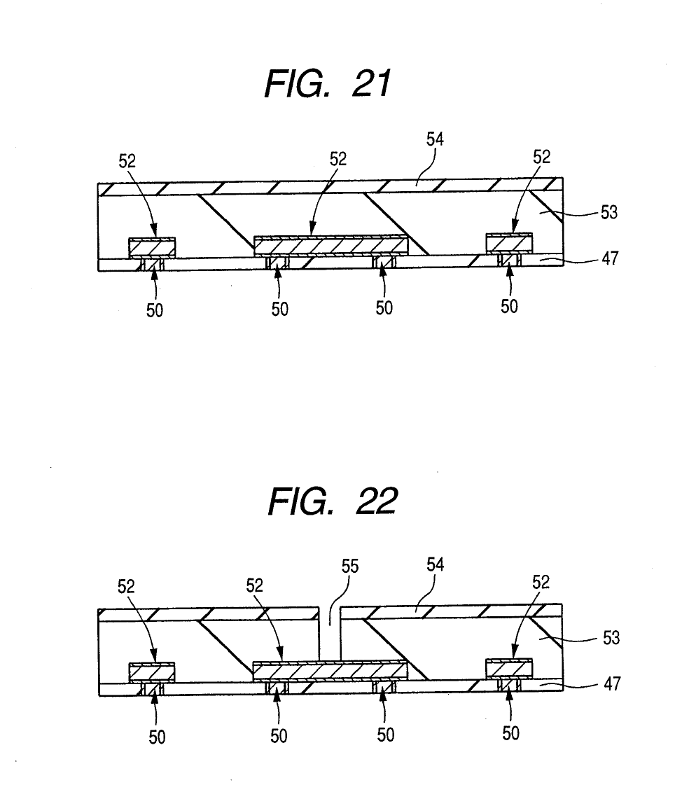

By the chemical reaction of the raw material gases in plasma form, a dielectric film 54 as illustrated in FIG. 21 is then formed (plasma CVD film formation process 2-1). This dielectric film 54 constitutes an interlayer dielectric film and is made of a silicon oxide film. To facilitate understanding, the structure below the dielectric film 47 is omitted from FIG. 21 to FIG. 28

After formation of the dielectric film 54, the wafer 30 is unloaded from the process chamber 22a of FIG. 8. An NF₃ gas (mixed with argon or the like gas) is introduced into the plasma gas generator 23 of FIG. 8. In the plasma gas generator 23, the cleaning gas is converted into plasma and the cleaning gas in plasma form is fed into the process chamber 22a. When the cleaning gas in plasma form is introduced into the process chamber 22a, it reacts with a film formed in the process chamber 22a. By this reaction, the film formed in the process chamber 22a is removed and the reaction product is discharged outside of the process chamber 22a.

During cleaning of the interior of the process chamber 22a by the cleaning gas in plasma form, electricity is supplied to the pair of electrodes from the radio frequency power source 9. The electricity at this time is smaller than that supplied upon conversion of the raw material gases into plasma in the process chamber 22a. In other words, the minimum electricity necessary for maintaining the cleaning gas in plasma form is supplied. A voltage appears between the pair of electrodes and this voltage is detected by the RF sensor 10 of FIG. 8. After amplification in the electronic module 11, this voltage is input to the termination controller 12. The termination controller 12 continues monitoring of the voltage input from the RF sensor 10 during the cleaning in the process chamber 22a. When the voltage becomes substantially constant at a predetermined value or greater, the controller judges that the cleaning in the process chamber 22a is finished, stops feeding of the plasma cleaning gas from the plasma gas generator 23, and terminates cleaning. When the voltage input into the termination controller 12 does not become constant within a predetermined time, the controller detects abnormality of the plasma gas generator 23 and activates an interlock system. In such a manner, the cleaning end-point can be detected properly.

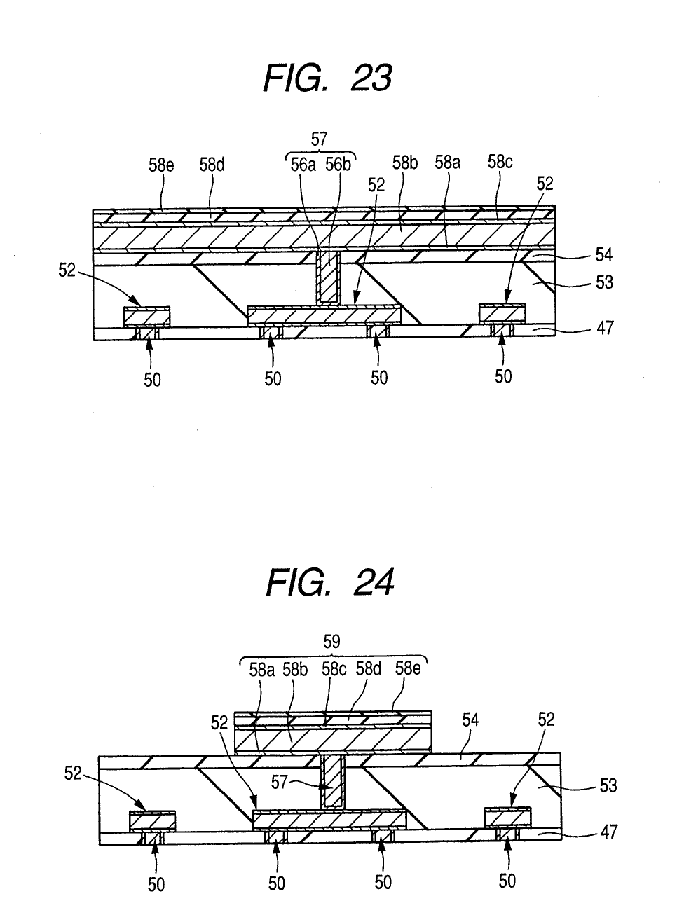

The wafer having the dielectric film 54 formed thereover as illustrated in FIG. 21 in the CVD apparatus of Embodiment 2 is transferred to the subsequent step. As illustrated in FIG. 22, a connecting hole 55 reaching the interconnect 52 is then formed by making use of photolithography and etching. After successive formation of a titanium/titanium nitride film 56a and a tungsten film 56b over the dielectric film 54 including the inside of the connecting hole 55, an unnecessary portion of the titanium/titanium nitride film 56a and tungsten film 56b formed over the dielectric film 54 is removed by CMP (Chemical Mechanical Polishing), whereby a plug 57 having these films embedded in the connecting hole 55 is formed as illustrated in FIG. 23.

Over the dielectric film 54, a titanium/titanium nitride film 58a, an aluminum film 58b, a titanium/titanium nitride film 58c, a dielectric film 58d (plasma CVD film formation process 2-2) and an antireflection film 58e (plasma CVD film formation process 2-3) are formed successively. The titanium/titanium nitride film 58a, aluminum film 58b, and titanium/titanium nitride film 58c can be formed by sputtering. The dielectric film 58d is made of a silicon oxide film and can be formed by plasma CVD using TEOS as a raw material. The antireflection film 58e serves to suppress the influence of a reflection light from the underlying film upon patterning and is made of, for example, a silicon oxynitride film. This antireflection film 58e is formed also by plasma CVD.

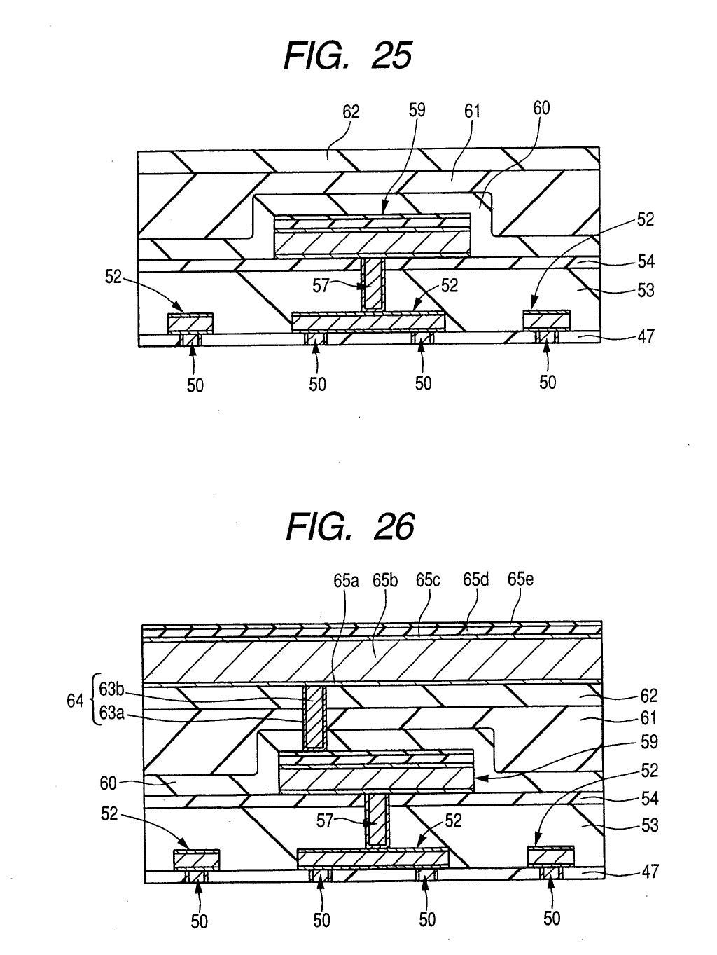

As illustrated in FIG. 24, the films thus deposited successively are patterned by photolithography and etching to form an interconnect 59. A dielectric film 60 is then formed over the interconnect 59 and dielectric film 54 (plasma CVD film formation process 2-4) as illustrated in FIG. 25. The dielectric film 60 is made of, for example, a silicon oxide film and can be formed by plasma CVD using TEOS as a raw material. Over the dielectric film 60, a dielectric film 61 is then formed. The dielectric film 61 is made of, for example, an SOG (Spin On Glass) film. Described specifically, the dielectric film 61 is made of a silicon oxide film formed by spin-coating a solution of silica in a solvent such as alcohol over the main surface of the wafer 30, and then evaporating the solvent by heat treatment.

Over the dielectric film 61, a dielectric film 62 is formed (plasma CVD film formation process 2-5). The dielectric film 62 is made of, for example, a silicon oxide film and is formed by plasma CVD using TEOS as a raw material. Then, the surface of the dielectric film 62 is planarized by CMP.

As illustrated in FIG. 26, after formation of a connecting hole reaching the interconnect 59 by photolithography and etching, a titanium/titanium nitride film 63a and a tungsten film 63b are embedded in this connecting hole to form a plug 64. Over this plug 64 and dielectric film 62, a titanium/titanium nitride film 65a, an aluminum film 65b, a titanium/titanium nitride film 65c, a dielectric film 65d and an antireflection film 65e are formed successively. The titanium/titanium nitride film 65a, aluminum film 65b, and titanium/titanium nitride film 65c can be formed, for example, by sputtering. The dielectric film 65d (plasma CVD film formation process 2-6) is made of a silicon oxide film and can be formed, for example, by plasma CVD using TEOS as a raw material. The antireflection film 65e (plasma CVD film formation process 2-7) is made of, for example, a silicon oxynitride film. This antireflection film 65e is formed also by plasma CVD.

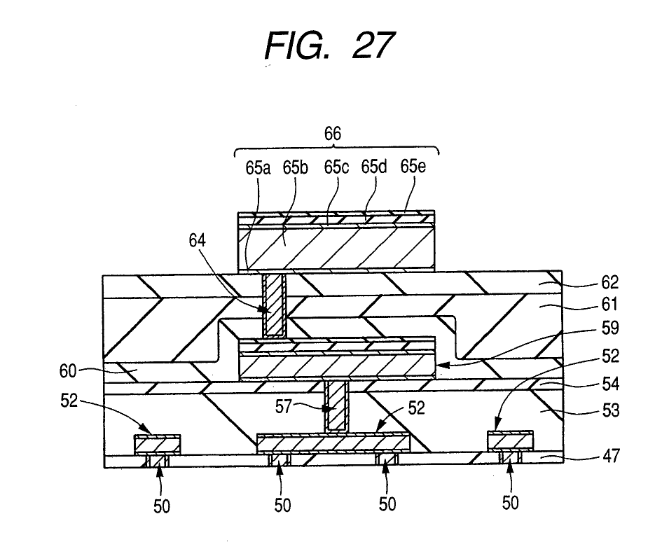

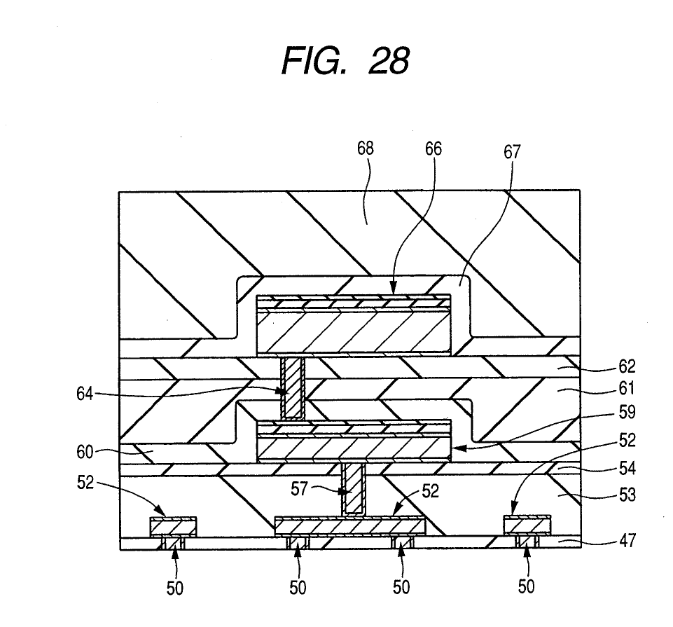

As illustrated in FIG. 27, an interconnect 66 is formed by patterning the film stack by photolithography and etching. As illustrated in FIG. 28, a dielectric film 67 is then formed over this interconnect 66 and dielectric film 62. The dielectric film 67 (plasma CVD film formation process 2-8) is made of a silicon oxide film and can be formed by plasma CVD using TEOS as a raw material.

After annealing with a hydrogen gas, a dielectric film 68 (plasma CVD film formation process 2-9) is formed over the dielectric film 67. The dielectric film 68 is made of a silicon nitride film and can be formed by using plasma CVD. This dielectric film 68 made of a silicon nitride film serves as a passivation film (surface protecting film). It plays a role of protecting the chip from mechanical stress or invasion of impurities. In such a manner, MIS transistors Q₁ and Q₂ and multilevel interconnect can be formed over the wafer 30. After dicing (including laser dicing, which will equally apply hereinafter) of the wafer 30 into each chip, each chip is mounted on a lead frame. The lead frame and chip are electrically connected via wire bonding, followed by sealing with a resin for packaging. In this manner, the semiconductor integrated circuit device can be fabricated.

The plasma CVD apparatus used in Embodiment 2 is used for the formation step of the dielectric film 54. The plasma CVD apparatus employed in Embodiment 2 can be used not only for this step, but also for another step, for example, that for forming the dielectric film 58d, dielectric film 60, dielectric film 62, dielectric film 65d or dielectric film 67 by CVD using TEOS as a raw material. In other words, a plasma CVD apparatus having an automatic detecting function of the cleaning end-point can be used for the step for forming the above-described films. The plasma CVD apparatus employed in Embodiment 2 can also be used even for the step of forming the dielectric film (passivation film) 68 made of a silicon nitride film.

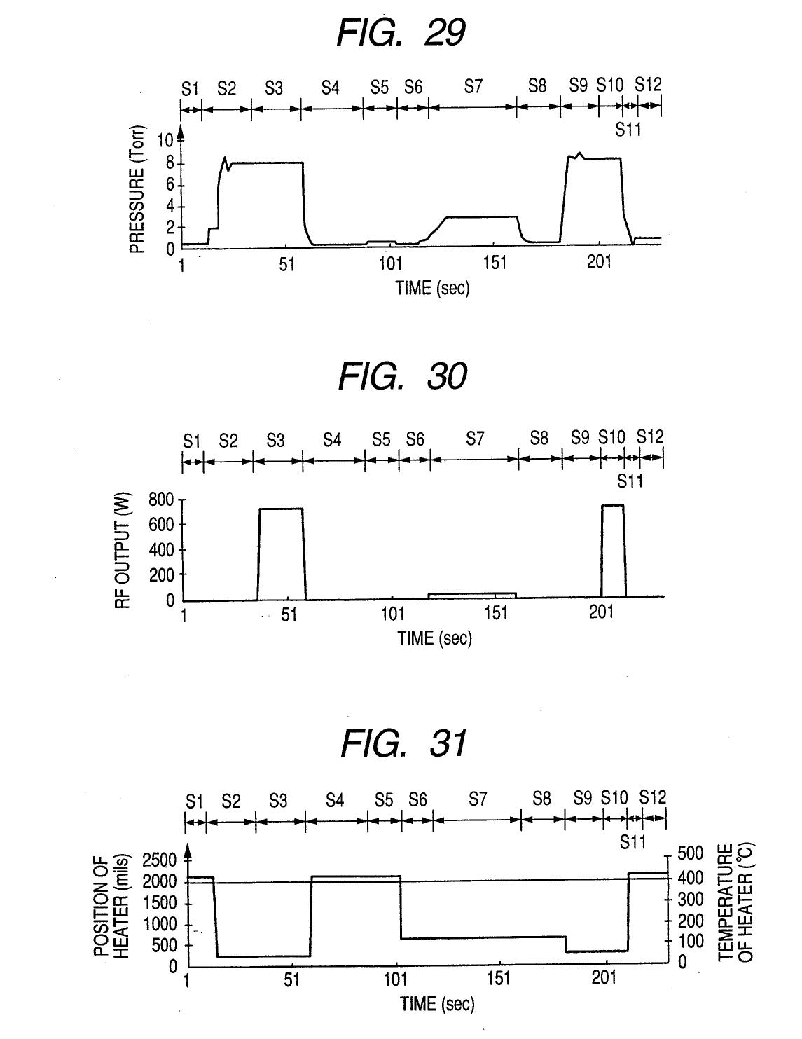

A process sequence of the above-described fabrication method of the semiconductor integrated circuit device in the case where the dielectric film 54 made of a silicon oxide film is formed in the process chamber 22a, followed by cleaning in the process chamber 22a will next be described referring to FIGS. 29 to 37.

FIGS. 29 to 37 illustrates a time-dependent change of each parameter of a plasma CVD apparatus when the interior of the process chamber 22a is cleaned after formation of a silicon oxide film (dielectric film 54) over the wafer 30 by plasma CVD using TEOS as a raw material. Of these diagrams, FIG. 29 illustrates the relationship between pressure (Torr (=133.3 Pa)) in the process chamber 22a and time (second), while FIG. 30 illustrates the relationship between RF output (W) supplied to the pair of electrodes from the radio frequency power source 9 of FIG. 8 and time.

FIG. 31 illustrates the relationship between heater temperature in the lower electrode 4 and time, and heater position (mils (=25.4 μm)) and time. The lower electrode 4 including the heater is vertically movable so that the heater position changes by the step. This heater position means a distance between the lower electrode 4 and the upper electrode 5.

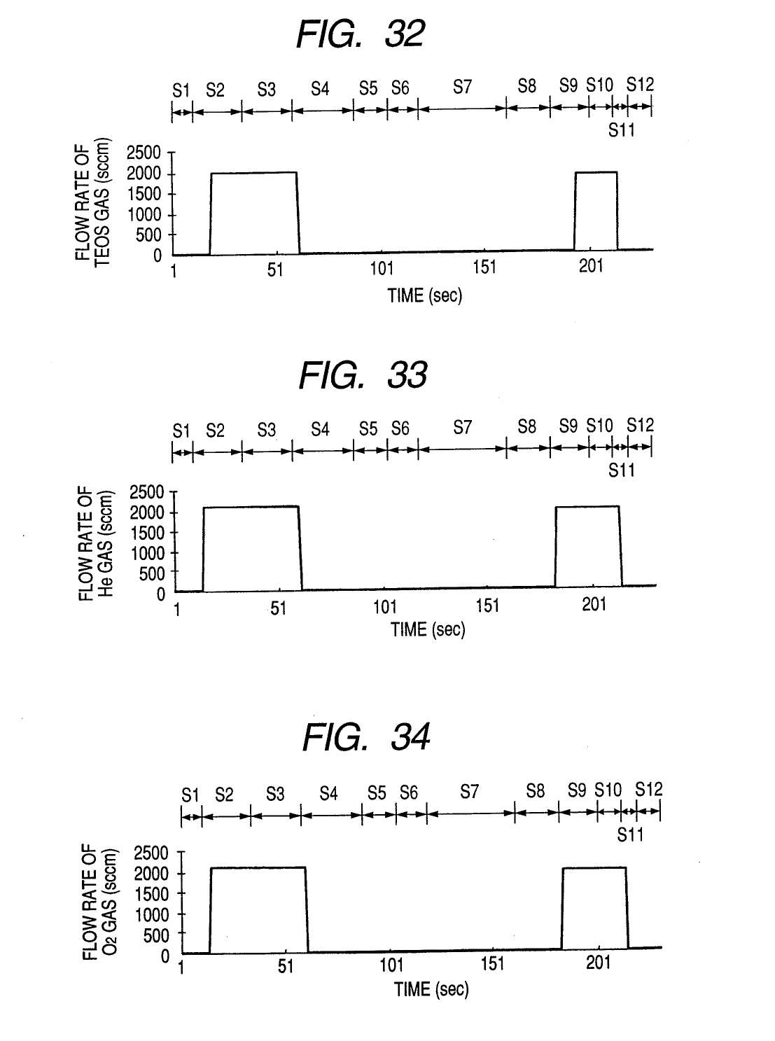

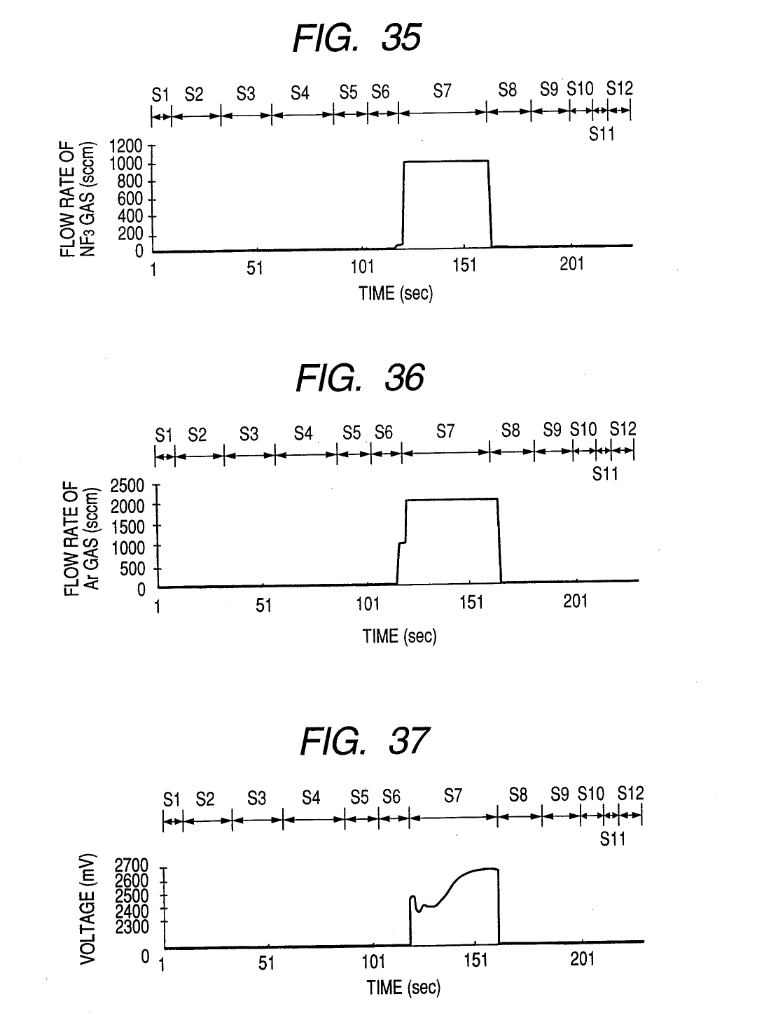

FIG. 32 illustrates the relationship between flow rate (sccm (=1 cc/minute)) of TEOS which is a raw material and time. FIG. 33 illustrates the relationship between flow rate of a helium gas (He) and time. FIG. 34 is the relationship between flow rate of an oxygen gas (O₂) and time. FIG. 35 illustrates the relationship between flow rate of NF₃ which is a cleaning gas and time. FIG. 36 illustrates the relationship between flow rate of an argon gas and time; and FIG. 37 illustrates the relationship between voltage to be input to the termination controller 12 of FIG. 8 and time. In FIGS. 29 to 37, steps S1 to S12 are shown in chronological order.

A description will next be made of the process sequence in the order of steps S1 to S12.

The wafer 30 is loaded in the process chamber 22a of the plasma CVD apparatus (step S1). As illustrated in FIG. 29, the process chamber 22a is highly evacuated. Described specifically, in the loading stage (step S1) of the wafer 30, no gas is introduced into the process chamber 22a as illustrated in FIGS. 32 to 36 so that the high vacuum condition in the process chamber 22a is maintained.

As illustrated in FIG. 31, the temperature of the heater is about 400° C. when the wafer 30 is loaded. The heater position is about 2200 (mils), suggesting that the lower electrode 4 is relatively spaced from the upper electrode 5.

Preparations for forming a silicon oxide film (dielectric film 54) over the wafer 30 are then made (step S2). As illustrated in FIGS. 32 to 34, TEOS, helium gas and oxygen gas are introduced into the process chamber 22a. As illustrated in FIG. 29, the pressure in the process chamber 22a gradually increases and becomes about 8 (Torr). As illustrated in FIG. 31, by elevating the lower electrode 4 including the heater, the heater position is adjusted to about 300 (mils) to relatively narrow the distance between the lower electrode 4 and upper electrode 5. The distance between the lower electrode 4 and upper electrode 5 is shortened in order to convert a gas into plasma between a pair of electrodes. The temperature of the heater is kept at about 400° C.

When the pressure of the gas introduced in the process chamber 22a becomes stable at about 8 (Torr), formation of a silicon oxide film (dielectric film 54) over the wafer is started (Step 3). At this time, TEOS, helium and oxygen gases have been introduced at a flow rate of 2000 sccm as illustrated in FIGS. 32 to 34. As illustrated in FIG. 30, electricity of about 700 (W) is supplied to the pair of electrodes. Supply of electricity to the pair of electrodes causes a difference in potential between the pair of electrodes. This converts the raw material gases such as TEOS existing between the pair of electrodes into plasma form. By the chemical reaction of the plasma raw material gases, the silicon oxide film (dielectric film 54) is formed over the wafer 30.

When the film of a predetermined thickness is formed over the wafer 30, supply of electricity to the pair of electrodes is stopped as illustrated in FIG. 30 and as illustrated in FIGS. 32 to 34, feeding of the TEOS, helium and oxygen gases to the process chamber 22a are also stopped to finish the film formation (Step S4). The gases remaining in the process chamber 22a are discharged outside by a pump. The pressure in the process chamber 22a decreases from about 8 (Torr) into high vacuum condition as illustrated in FIG. 29. As illustrated in FIG. 31, the heater position is changed to about 2200 (mils) to widen the distance between the lower electrode 4 and upper electrode 5.

The wafer having the silicon oxide film (dielectric film 54) formed thereover is unloaded outside the process chamber 22a (step S5). Preparations for cleaning in the process chamber 22a are made (step S6). In other words, introduction of an argon gas or NF₃ gas in plasma form is started. As illustrated in FIG. 31, the heater position is changed to about 600 (mils) to narrow the distance between the lower electrode 4 and upper electrode 5.

Cleaning is then conducted by introducing a cleaning gas in the process chamber 22a (step S7). More specifically, an NF₃ gas in plasma form is introduced at a flow rate of about 1000 (sccm) as illustrated in FIG. 35 and at the same time, an argon gas is introduced at a flow rate of 2000 (sccm) as illustrated in FIG. 36. The pressure in the process chamber 22a rises to about 3 (Torr) as illustrated in FIG. 29. Operation of each of the RF sensor 10, electronic module 11 and termination controller 12 as illustrated in FIG. 8 is started.

The NF₃ gas in plasma rich in reactivity reacts with the silicon oxide film formed in the process chamber 22a so that the silicon oxide film formed in the process chamber 22a is removed. At this time electricity of about 20 W is supplied to the pair of electrodes as illustrated in FIG. 30. This electricity is the minimum electricity necessary for maintaining the plasma state of the NF₃ gas. A voltage is generated in the pair of electrodes supplied with electricity and it is detected by the RF sensor 10. The voltage detected by the RF sensor 10 is amplified by the electronic module 11 and input to the termination controller 12. As illustrated in FIG. 37, the voltage input to the termination controller 12 increases and becomes substantially constant after some variations just after the cleaning is started. When the voltage input to the termination controller 12 becomes substantially constant at a predetermined voltage or greater, the controller judges that the cleaning of the process chamber 22a is completed, and as illustrated in FIGS. 35 and 36, stops feeding of the argon gas and NF₃ gas in plasma form to the process chamber 22a. In addition, the termination controller 12 stops the supply of electricity to the pair of electrodes. In this manner, the end point of cleaning can be detected properly.

The argon gas or NF₃ gas remaining in the process chamber 22a is then discharged outside of the process chamber 22a (step S8). As illustrated in FIG. 29, the pressure in the process chamber 22a is reduced from about 3 (Torr) into a high vacuum condition.

Preparations for seasoning are then made (step S9). The term “seasoning” means treatment for preventing stay of foreign matters (such as silicon oxide film piece), which have been scattered in the air by the cleaning, in the process chamber 22a. Generation of foreign matters is suppressed by carrying out slight film formation to fix them to the interior wall of the process chamber 22a.

For preparations for seasoning, TEOS, helium and oxygen gases are introduced into the process chamber 22a as illustrated in FIGS. 32 to 34. As illustrated in FIG. 29, the pressure in the process chamber 22a increases to about 8 (Torr), the same pressure as that upon above-described film formation. As illustrated in FIG. 31, the heater position is reduced from about 600 (mils) to about 300 (mils), the same as that upon above-described film formation to narrow the distance between the lower electrode 4 and upper electrode 5.

The seasoning is then conducted (step S10). Described specifically, feeding of TEOS, helium and oxygen gases is continued at a flow rate of about 2000 (sccm) as illustrated in FIGS. 32 to 34. By this gas feeding, the pressure in the process chamber 22a is maintained at about 8 (Torr) as illustrated in FIG. 29. At this time, electricity of about 700 (W) is supplied between the pair of electrodes for a period shorter than that for the above-described film formation. Supply of electricity to the pair of electrodes causes a potential difference therebetween. This converts the raw material gases such as TEOS existing between the pair of electrodes into plasma. By the chemical reaction of the raw material gases in the plasma form, a slight silicon oxide film is formed over the interior wall of the process chamber 22a. During this process, foreign matters staying in the space in the process chambers 22a are also fixed to the interior wall of the process chamber 22a.

The seasoning treatment is then finished (step S11). More specifically, electricity supplied to the pair of electrodes is stopped as illustrated in FIG. 30. Feeding of the TEOS, helium and oxygen gases to the process chamber 22a is stopped as illustrated in FIGS. 32 to 34 and at the same time, the TEOS, helium and oxygen gases remaining in the process chamber 22a are discharged outside. The pressure in the process chamber 22a is then reduced from about 8 (Torr) into a high vacuum condition as illustrated in FIG. 29. The heater position is changed from about 300 (mils) to about 2200 (mils) to widen the distance between the lower electrode 4 and upper electrode 5 as illustrated in FIG. 31. Another wafer over which a film is to be formed is then loaded in the process chamber 22a (step S12) and the above-described sequence operations are repeated.

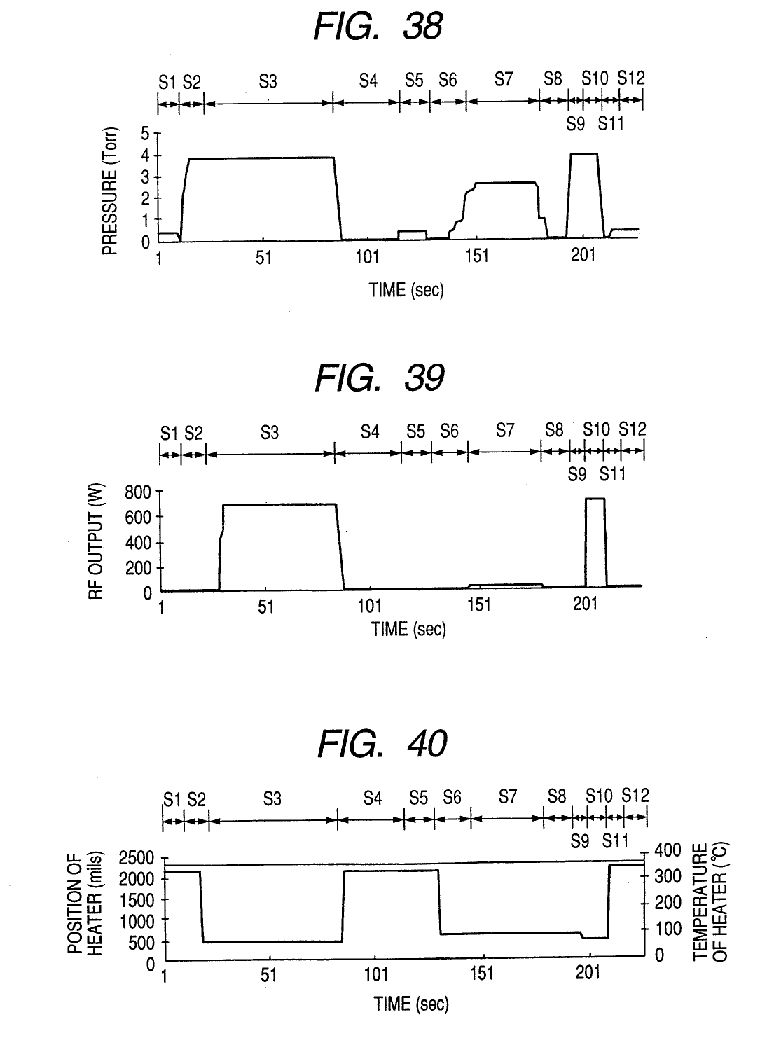

A process sequence of the above-described fabrication method of the semiconductor integrated circuit device comprising formation of a dielectric film 68 made of a silicon nitride film in the process chamber 22a, and cleaning of the process chamber 22a will next be described referring to FIGS. 38 to 46.

FIGS. 38 to 46 each illustrates a time-dependent change of each parameter of a plasma CVD apparatus when cleaning in the process chamber 22a is performed after formation of a silicon nitride film (dielectric film 68) over the wafer 30 by plasma CVD.

FIG. 38 illustrates the relationship between pressure (Torr) in the process chamber 22a and time (second), while FIG. 39 illustrates the relationship between RF output (W) supplied to the pair of electrodes from the radio frequency power source 9 of FIG. 8 and time.

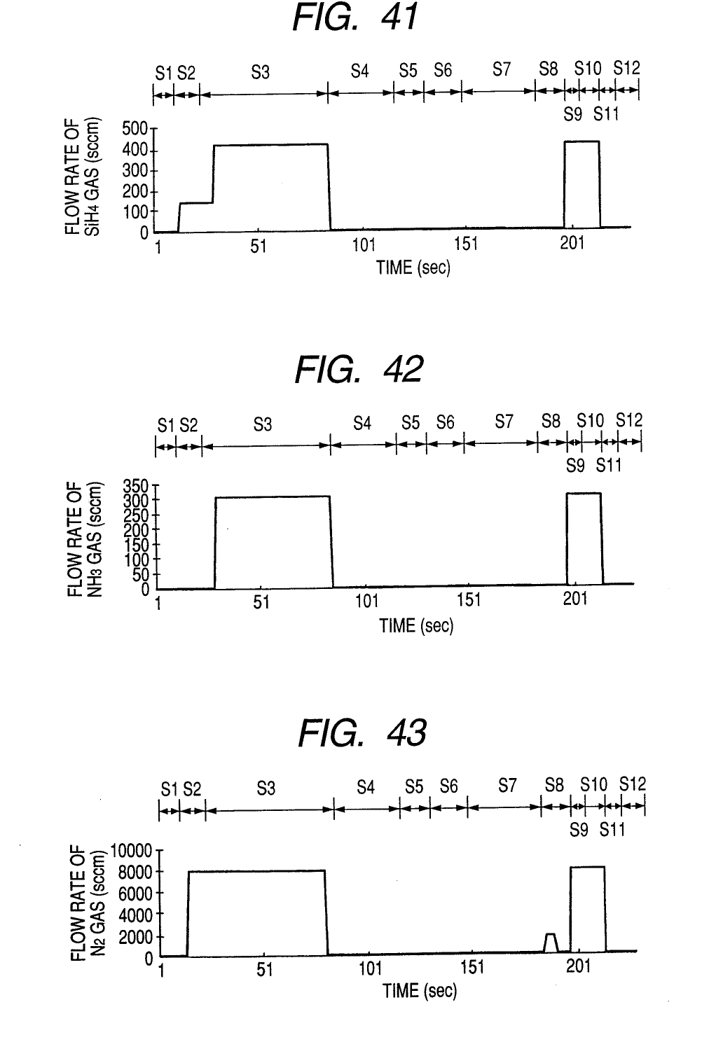

FIG. 40 illustrates the relationship between temperature of a heater in the lower electrode 4 and time, and heater position (mils) and time. FIG. 41 illustrates the relationship between flow rate (sccm) of a silane gas (SiH₄) and time. FIG. 42 illustrates the relationship between flow rate of an ammonia gas (NH₃) and time.

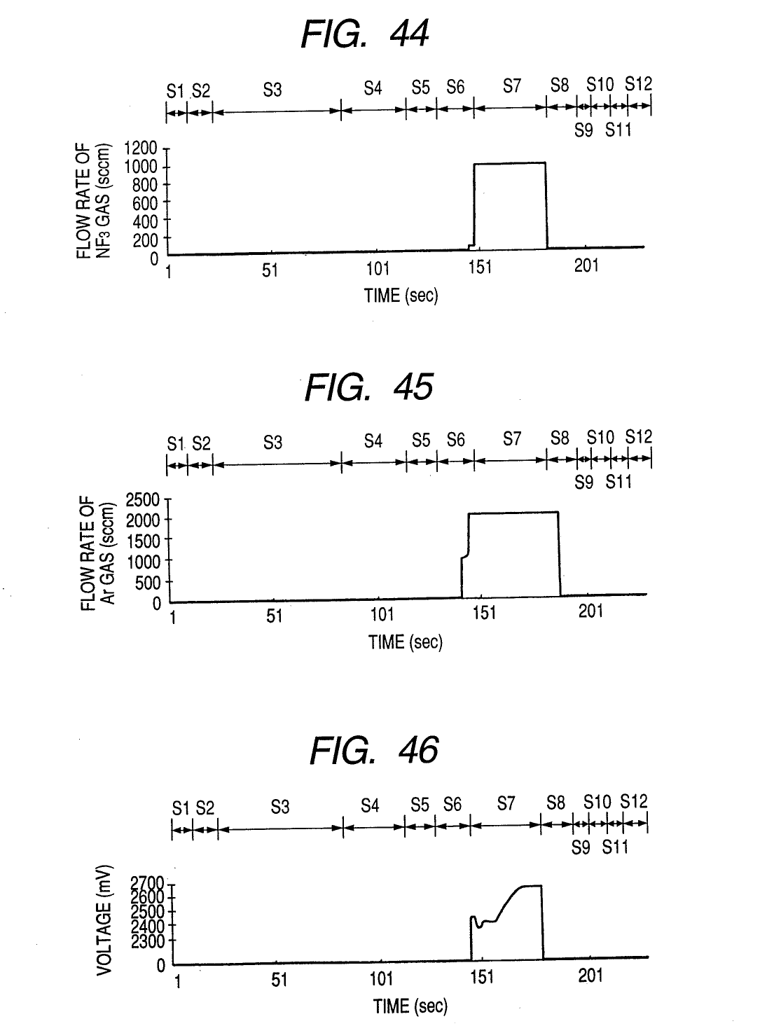

FIG. 43 illustrates the relationship between flow rate of a nitrogen gas (N₂) and time. FIG. 44 illustrates the relationship between flow rate of NF₃ gas as a cleaning gas, and time. FIG. 45 illustrates the relationship between flow rate of an argon gas and time; and FIG. 46 illustrates the relationship between voltage to be input to the termination controller 12 of FIG. 8 and time. In FIGS. 38 to 46, steps S1 to S12 are shown in chronological order.

A description will next be made of the process sequence in the order of the steps S1 to S12.

The wafer 30 is loaded in the process chamber 22a of the plasma CVD apparatus (step S1). As illustrated in FIG. 38, the process chamber 22a is in a vacuum condition as high as about 0.5 Torr.

As illustrated in FIG. 40, the temperature of the heater is about 380° C. when the wafer 30 is loaded. The heater position is about 2200 (mils), suggesting that the lower electrode 4 is relatively spaced from the upper electrode 5.

Preparations for forming a silicon nitride film (dielectric film 68) over the wafer 30 are then made (step S2). As illustrated in FIGS. 41 to 43, silane and nitrogen gases are introduced into the process chamber 22a. More specifically, the silane gas is introduced at a flow rate of about 150 (sccm) and the nitrogen gas is introduced at a flow rate of about 8000 (sccm) into the process chamber 22a. As illustrated in FIG. 38, the pressure in the process chamber 22a gradually increases. As illustrated in FIG. 40, by elevating the lower electrode 4 including the heater, the heater position is adjusted to about 500 (mils) to relatively narrow the distance between the lower electrode 4 and upper electrode 5. The distance between the lower electrode 4 and upper electrode 5 is shortened in order to convert a gas into plasma between the pair of electrodes. The temperature of the heater is kept at about 380° C.

Formation of a silicon nitride film (dielectric film 68) over the wafer 30 is started (Step 3). At this time, silane gas, ammonia gas and nitrogen gas have been introduced into the process chamber 22a at flow rates of 400 (sccm), about 300 (sccm) and about 8000 (sccm) as illustrated in FIGS. 41 to 43. As illustrated in FIG. 39, electricity of about 700 (W) is supplied to the pair of electrodes. Supply of electricity to the pair of electrodes causes a difference in potential between the pair of electrodes. This converts the silane gas and ammonia gas existing between the pair of electrodes into plasma form. By the chemical reaction of the plasma gases, the silicon nitride film (dielectric film 68) is formed over the wafer 30.

When the film of a predetermined thickness is formed over the wafer 30, supply of electricity to the pair of electrodes is stopped as illustrated in FIG. 39, and as illustrated in FIGS. 41 to 43, feeding of the silane, ammonia and nitrogen gases to the process chamber 22a is also stopped to finish the film formation (Step S4). The gases remaining in the process chamber are discharged outside by a pump. The pressure in the process chamber 22a decreases as illustrated in FIG. 38 into high vacuum condition. As illustrated in FIG. 40, the heater position is moved to about 2200 (mils) to widen the distance between the lower electrode 4 and upper electrode 5.

The wafer 30 having the silicon nitride film (dielectric film 68) formed thereover is unloaded outside the process chamber 22a (step S5). Preparations for cleaning in the process chamber 22a are made (step S6). In other words, as illustrated in FIG. 40, the heater position is changed to about 600 (mils) to narrow the distance between the lower electrode 4 and upper electrode 5.

Cleaning is then conducted by introducing a cleaning gas in the process chamber 22a (step S7). More specifically, an NF₃ gas in plasma form is introduced into the process chamber 22a at a flow rate of about 1000 (sccm) as illustrated in FIG. 44 and at the same time, an argon gas is introduced at a flow rate of 2000 (sccm) as illustrated in FIG. 45. The pressure in the process chamber 22a increases to about 3 (Torr) as illustrated in FIG. 38. Operation of each of the RF sensor 10, electronic module 11 and termination controller 12 as illustrated in FIG. 8 is started.

When the plasma NF₃ gas is fed to the process chamber 22a, it reacts with the silicon nitride film formed in the process chamber 22a so that the silicon nitride film formed in the process chamber 22a is removed. At this time a slight electricity of about 20 W is supplied to the pair of electrodes as illustrated in FIG. 39. This electricity is the minimum electricity necessary for maintaining the plasma state of the NF₃ gas. A voltage is generated in the pair of electrodes supplied with the electricity and it is detected by the RF sensor 10. The voltage detected by the RF sensor 10 is amplified by the electronic module 11 and input to the termination controller 12. As illustrated in FIG. 46, the voltage input to the termination controller 12 increases and becomes substantially constant after some variations at an initial stage. When the voltage input to the termination controller 12 becomes substantially constant at a predetermined voltage or greater, the controller judges that the cleaning of the process chamber 22a is completed, and as illustrated in FIGS. 44 and 45, stops feeding of the argon gas and plasma NF₃ gas to the process chamber 22a. In addition, the termination controller 12 stops the supply of electricity to the pair of electrodes as illustrated in FIG. 39. In this manner, the end point of cleaning can be detected properly.

The argon gas or NF₃ gas remaining in the process chamber 22a is discharged outside thereof (step S8). As illustrated in FIG. 38, the pressure in the process chamber 22a is reduced from about 3 (Torr) into a high vacuum condition.

Preparations for seasoning are then made (step S9). As illustrated in FIGS. 41 to 43, silane, ammonia and nitrogen gases are introduced into the process chamber 22a. As illustrated in FIG. 38, the pressure in the process chamber 22a increases to about 4 (Torr), the same pressure as that upon above-described film formation. As illustrated in FIG. 40, the heater position is reduced from about 600 (mils) to about 500 (mils), the same as that upon above-described film formation to narrow the distance between the lower electrode 4 and upper electrode 5.

The seasoning is then conducted (step S10). Described specifically, feeding of silane, ammonia and nitrogen gases is continued at flow rates of about 400 (sccm), about 300 (sccm) and about 8000 (sccm), respectively as illustrated in FIGS. 41 to 43. By this gas feeding, the pressure in the process chamber 22a is maintained at about 4 (Torr) as illustrated in FIG. 38. At this time, electricity of about 700 (W) is supplied between the pair of electrodes for a period shorter than that for the above-described film formation. This converts the raw material gases such as silane gas existing between the pair of electrodes into plasma. By the chemical reaction of the raw material gases converted into plasma, a slight silicon oxide film is formed over the interior wall of the process chamber 22a. By this procedure, foreign matters staying in the space in the process chambers 22a are fixed to the interior wall of the process chamber 22a.

The seasoning treatment is then finished (step S11). More specifically, electricity supplied to the pair of electrodes is stopped as illustrated in FIG. 39. Feeding of the silane, ammonia and nitrogen gases to the process chamber 22a is also stopped as illustrated in FIGS. 41 to 43 and at the same time, the silane, ammonia and nitrogen gases remaining in the process chamber 22a are discharged outside. The pressure in the process chamber 22a is then reduced from about 4 (Torr) into a high vacuum condition as illustrated in FIG. 38. The heater position is changed from about 500 (mils) to about 2200 (mils) to widen the distance between the lower electrode 4 and upper electrode 5 as illustrated in FIG. 40. Another wafer over which a film is to be formed is then loaded in the process chamber 22a (step S12) and then the above-described sequence operations are repeated.

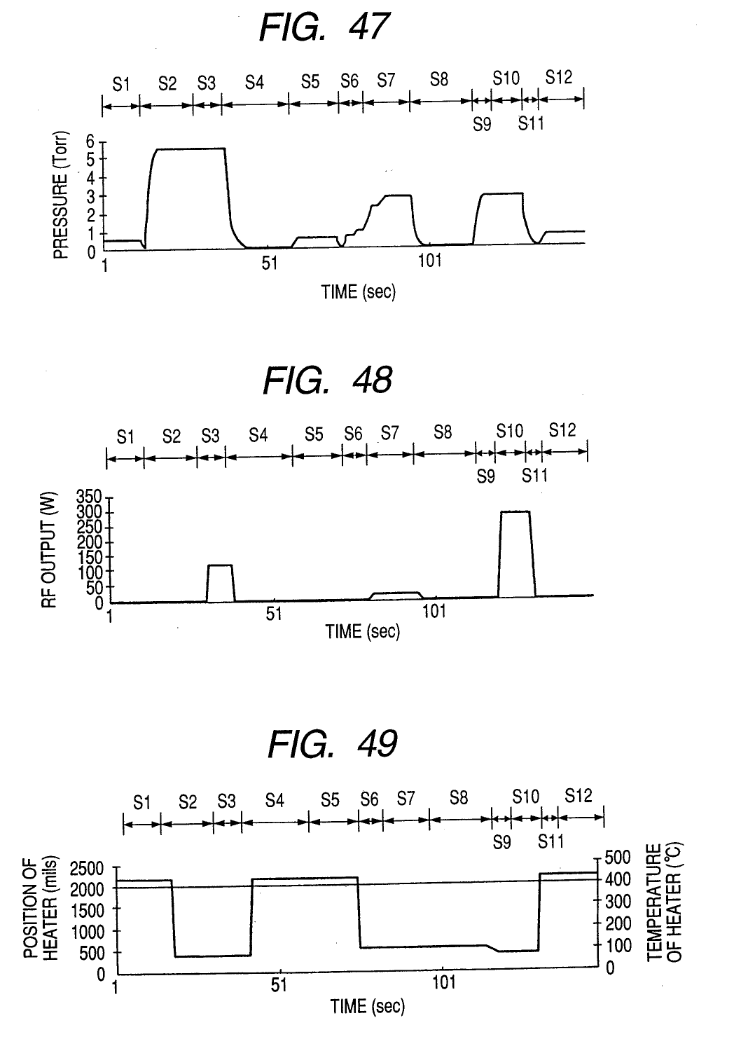

A process sequence of the above-described fabrication method of the semiconductor integrated circuit device comprising formation of an antireflection film 58e made of a silicon oxynitride film in the process chamber 22a, and cleaning of the process chamber 22a will next be described referring to FIGS. 47 to 55.

FIGS. 47 to 55 illustrate a time-dependent change of each parameter of a plasma CVD apparatus when cleaning in the process chamber 22a is performed after formation of a silicon oxynitride film (antireflection film 58e) over the wafer 30 by plasma CVD.

FIG. 47 illustrates the relationship between pressure (Torr) in the process chamber 22a and time (second), while FIG. 48 illustrates the relationship between RF output (W) supplied to the pair of electrodes from the radio frequency power source 9 of FIG. 8 and time.

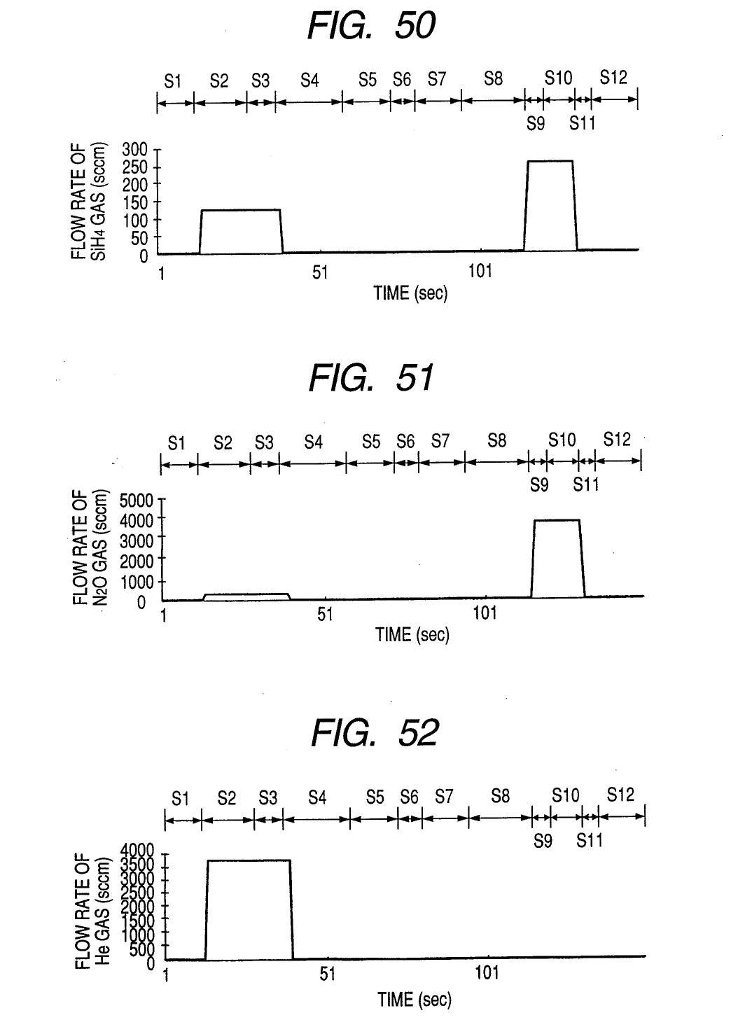

FIG. 49 illustrates the relationship between temperature of a heater in the lower electrode 4 and time, and heater position (mils) and time. FIG. 50 illustrates the relationship between flow rate (sccm) of a silane gas (SiH₄) and time. FIG. 51 illustrates the relationship between flow rate of an N₂O gas and time.

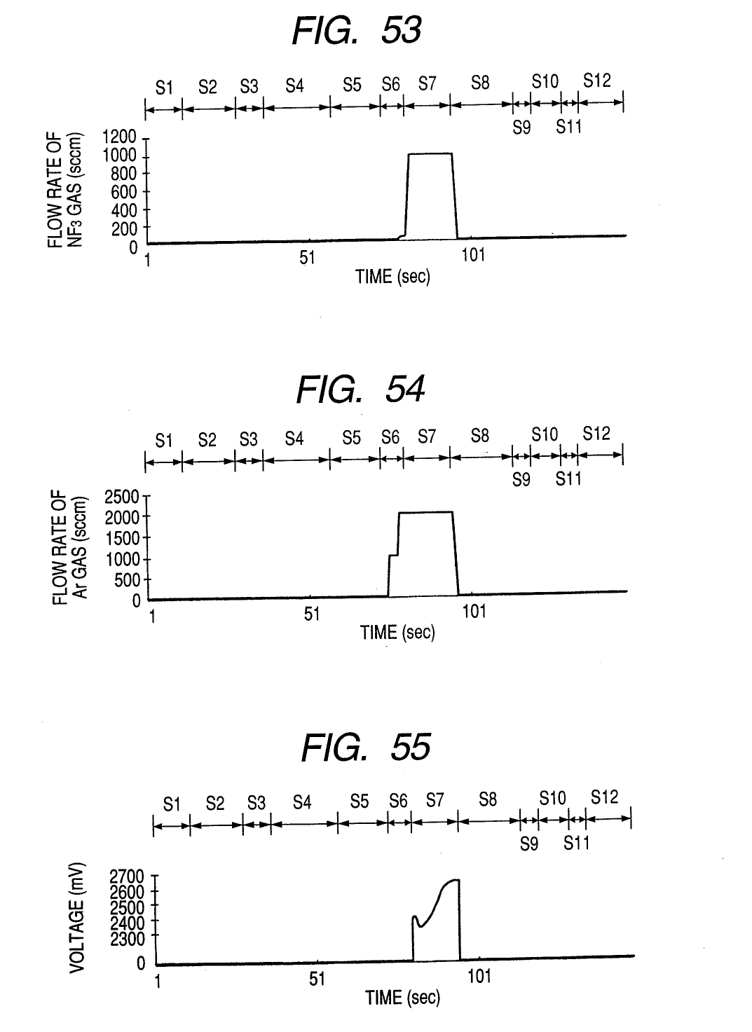

FIG. 52 illustrates the relationship between flow rate of a helium gas (He) and time. FIG. 53 is the relationship between flow rate of NF₃ gas which is a cleaning gas, and time. FIG. 54 illustrates the relationship between flow rate of an argon gas and time; and FIG. 55 illustrates the relationship between voltage to be input to the termination controller 12 of FIG. 8 and time. In FIGS. 47 to 55, steps S1 to S12 are shown in chronological order.

A description will next be made of the process sequence in the order of the steps S1 to S12.

The wafer 30 is loaded in the process chamber 22a of the plasma CVD apparatus (step S1). As illustrated in FIG. 47, the process chamber 22a is in a vacuum condition as high as about 0.5 Torr.

As illustrated in FIG. 49, the temperature of the heater is about 400° C. when the wafer 30 is loaded. The heater position is about 2200 (mils), suggesting that the lower electrode 4 is relatively spaced from the upper electrode 5.

Preparations for forming a silicon oxynitride film (antireflection film 58e) over the wafer 30 are then made (step S2). As illustrated in FIGS. 50 to 52, silane, N₂O and helium gases are introduced into the process chamber 22a. More specifically, the silane gas, N₂O gas and helium gas are introduced into the process chamber 22a at flow rates of about 130 (sccm), about 300 (sccm) and about 4000 (sccm), respectively. As illustrated in FIG. 47, the pressure in the process chamber 22a gradually increases to about 5.5 (Torr). As illustrated in FIG. 49, by elevating the lower electrode 4 including the heater, the heater position is adjusted to about 500 (mils) to relatively narrow the distance between the lower electrode 4 and upper electrode 5. The distance between the lower electrode 4 and upper electrode 5 is shortened in order to convert a gas into plasma between a pair of electrodes. The temperature of the heater is kept at about 400° C.

Formation of a silicon oxynitride film (antireflection film 58e) over the wafer 30 is started (Step 3). As illustrated in FIG. 48, electricity of about 130 (W) is supplied to the pair of electrodes. Supply of electricity to the pair of electrodes causes a difference in potential between the pair of electrodes. This converts the silane gas and N₂O gas existing between the pair of electrodes into plasma form. By the chemical reaction of the raw material gases converted into plasma, the silicon oxynitride film (antireflection film 58e) is formed over the wafer 30.

When the film of a predetermined thickness is formed over the wafer 30, supply of electricity to the pair of electrodes is stopped as illustrated in FIG. 48, and as illustrated in FIGS. 50 to 52, feeding of the silane, N₂O and helium gases to the process chamber 22a is also stopped to finish the film formation (Step S4). The gases remaining in the process chamber are discharged outside by a pump. The pressure in the process chamber 22a decreases as illustrated in FIG. 47 into high vacuum condition. As illustrated in FIG. 49, the heater position is changed to about 2200 (mils) to widen the distance between the lower electrode 4 and upper electrode 5.

The wafer having the silicon oxynitride film (antireflection film 58e) formed thereover is unloaded outside the process chamber 22a (step S5). Preparations for cleaning in the process chamber 22a are made (step S6). In other words, as illustrated in FIG. 54, introduction of an argon gas into the process chamber 22a is started. As illustrated in FIG. 49, the heater position is changed to about 600 (mils) to narrow the distance between the lower electrode 4 and upper electrode 5.

Cleaning is then conducted by introducing a cleaning gas in the process chamber 22a (step S7). More specifically, an NF₃ gas in plasma form is introduced into the process chamber 22a at a flow rate of about 1000 (sccm) as illustrated in FIG. 53 and at the same time, an argon gas is introduced at a flow rate of 2000 (sccm) as illustrated in FIG. 54. The pressure in the process chamber 22a increases to about 3 (Torr) as illustrated in FIG. 38. Operation of each of the RF sensor 10, electronic module 11 and termination controller 12 as illustrated in FIG. 8 is started.

When the NF₃ gas in plasma form is fed to the process chamber 22a, it reacts with the silicon oxynitride film formed in the process chamber 22a so that the silicon oxynitride film formed in the process chamber 22a is removed. At this time a slight electricity of about 20 W is supplied to the pair of electrodes as illustrated in FIG. 48. This electricity is the minimum electricity necessary for maintaining the plasma state of the NF₃ gas. A voltage is generated in the pair of electrodes supplied with the electricity and it is detected by the RF sensor 10. The voltage detected by the RF sensor 10 is amplified by the electronic module 11 and input to the termination controller 12. As illustrated in FIG. 55, the voltage input to the termination controller 12 increases and becomes substantially constant after some variations at the initial stage. When the voltage input to the termination controller 12 becomes substantially constant at a predetermined voltage or greater, the controller judges that the cleaning of the process chamber 22a is completed, and as illustrated in FIGS. 53 and 54, stops feeding of the argon gas and plasma NF₃ gas to the process chamber 22a. In addition, the termination controller 12 stops the supply of electricity to the pair of electrodes as illustrated in FIG. 48. In this manner, the end point of cleaning can be detected properly.

The argon gas or NF₃ gas remaining in the process chamber 22a is discharged outside of the process chamber 22a (step S8). As illustrated in FIG. 38, the pressure in the process chamber 22a is reduced from about 3 (Torr) into a high vacuum condition.

Preparations for seasoning are then made (step S9). As illustrated in FIGS. 50 to 51, silane and N₂O gases are introduced into the process chamber 22a. As illustrated in FIG. 47, the pressure in the process chamber 22a increases to about 3 (Torr). As illustrated in FIG. 49, the heater position is reduced from about 600 (mils) to about 500 (mils), the same as that upon the above-described film formation to narrow the distance between the lower electrode 4 and upper electrode 5.

The seasoning is then conducted (step S10). Described specifically, silane and N₂O gases are fed at flow rates of about 250 (sccm) and about 4000 (sccm), respectively as illustrated in FIGS. 50 to 51. By this gas feeding, the pressure in the process chamber 22a is maintained at about 3 (Torr) as illustrated in FIG. 47. At this time, electricity of about 700 (W) is supplied between the pair of electrodes for a period shorter than that for the above-described film formation. This converts the raw material gases such as silane gas existing between the pair of electrodes into plasma. By the chemical reaction of raw material gases in plasma form, a slight silicon oxynitride film is formed over the interior wall of the process chamber 22a. During this procedure, foreign matters staying in the space in the process chambers 22a are also fixed to the interior wall of the process chamber 22a.

The seasoning treatment is then finished (step S1). More specifically, electricity supplied to the pair of electrodes is stopped as illustrated in FIG. 48. Feeding of the silane and N₂O gases to the process chamber 22a is stopped as illustrated in FIGS. 50 to 51, and at the same time, the silane and N₂O gases remaining in the process chamber 22a are discharged outside. The pressure in the process chamber 22a is then reduced from about 3 (Torr) into a high vacuum condition as illustrated in FIG. 47. The heater position is changed from about 500 (mils) to about 2200 (mils) as illustrated in FIG. 49 to widen the distance between the lower electrode 4 and upper electrode 5. Another wafer over which a film is to be formed is then loaded in the process chamber 22a (step S12) and the above-described sequence operations are repeated.

### EMBODIMENT 3

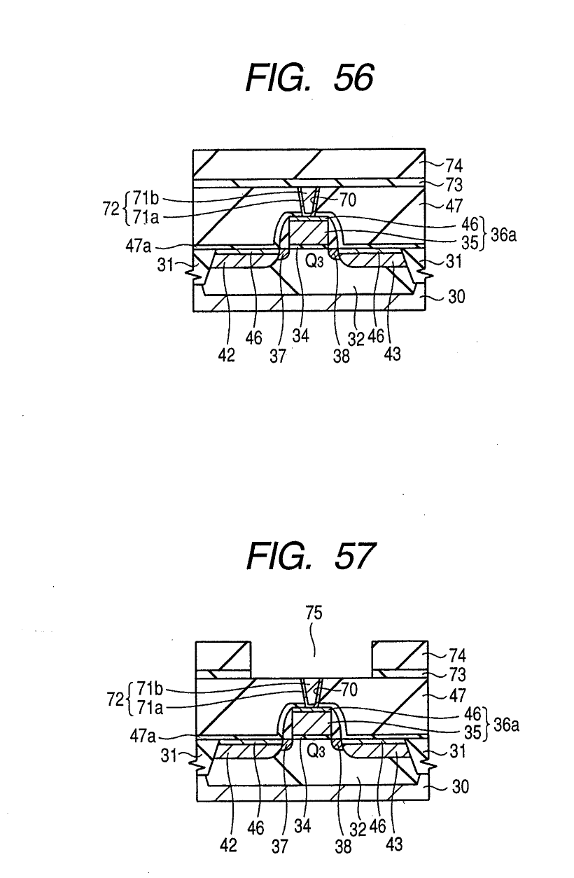

In Embodiment 2, an application example of the present invention to a fabrication method of a semiconductor integrated circuit device having aluminum interconnects (an interconnection structure having mutual connection having aluminum as a main component) was described. In Embodiment 3, an application example of the present invention to a fabrication method of a semiconductor integrated circuit device having a copper interconnect (an interconnection structure having mutual connection having copper as a main component) formed using the damascene or dual damascene method will be described referring to FIGS. 56 to 62.

In FIG. 56, an MIS transistor Q3 is formed over the wafer 30. This MIS transistor Q3 can be formed by carrying out similar steps to those of the MIS transistor Q₁ described in Embodiment 2.

Over the main surface of the wafer 30 having the MIS transistor Q3, a dielectric film 47a is formed using, for example, CVD. This dielectric film 47a is made of a silicon nitride film. Over the dielectric film 47a, a dielectric film 47 is formed. This dielectric film 47 is made of a silicon oxide film. A connecting hole 70 is then formed in these dielectric films 47 and 47a by photolithography and etching.

After formation of a titanium/titanium nitride film 71a and a tungsten film 71b over the main surface of the wafer including the inside of the connecting hole 70, an unnecessary portion of the titanium/titanium nitride film 71a and a tungsten film 71b formed over the dielectric film 47 outside the connecting hole 70 is removed by CMP, whereby a plug 72 is formed.

Over the dielectric film 47 having the plug 72 formed therein, a dielectric film 73 is formed. This dielectric film (silicon-containing insulating diffusion-barrier film) 73 is made of a silicon carbide film (SiC, SiCN or the like) or a silicon nitride film (SiN) and can be formed by using, for example, CVD. The wafer 30 having the dielectric film 73 formed thereover is loaded in the process chamber 22a of the plasma CVD apparatus as illustrated in FIG. 8 and disposed over the lower electrode 4. After introduction of TEOS and oxygen gases in the process chamber 22a as raw material gases, electricity is supplied to a pair of electrodes made of the lower electrode 4 and upper electrode 5 from the radio frequency power source 9. A voltage is then generated between the pair of electrodes and the raw material gases are converted into plasma. By the chemical reaction of the raw material gases in plasma form, a dielectric film 74 (plasma CVD film formation process 3-1) made of a silicon oxide film is formed over the dielectric film 73.

After unloading of the wafer 30 having the dielectric film 74 formed thereover from the process chamber 22a, the interior of the process chamber 22a is cleaned in a similar manner to that described in Embodiment 2. More specifically, a plasma cleaning gas formed in the plasma gas generator 23 as illustrated in FIG. 8 is introduced into the process chamber 22a. When the plasma cleaning gas is introduced into the process chamber 22a, it reacts with a film formed in the process chamber 22a, whereby the unnecessary film formed in the process chamber 22a is removed.

During cleaning in the process chamber 22a by the plasma cleaning gas, electricity is supplied to the pair of electrodes from the radio frequency power source 9. At this time, a voltage appears between the pair of electrodes and this voltage is detected by the RF sensor 10 as illustrated in FIG. 8. After amplification in the electronic module 11, this voltage is input to the termination controller 12. The termination controller 12 continues monitoring of the voltage input from the RF sensor 10 during the cleaning in the process chamber 22a. When the voltage becomes constant at a predetermined voltage or greater, the controller judges that the cleaning in the process chamber 22a is finished, stops feeding of the plasma cleaning gas from the plasma gas generator 23, and terminates cleaning. When the voltage input into the termination controller 12 does not become constant within a predetermined time, the controller judges that an abnormality happens in the plasma gas generator 23 and activates an interlock system. In such a manner, the end-point of cleaning can be detected properly.

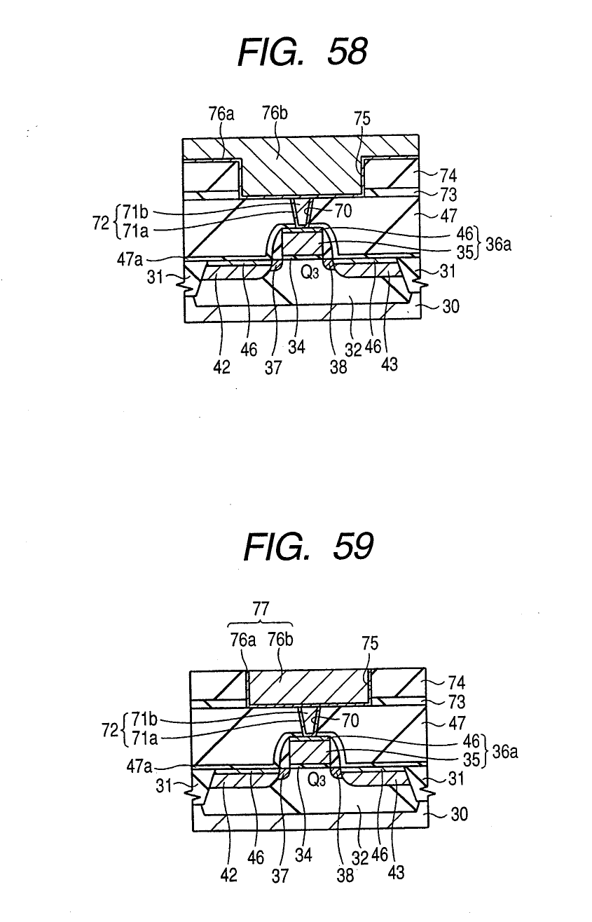

As illustrated in FIG. 57, by photolithography and etching of the wafer 30 having the dielectric film 74 formed thereover, an interconnect trench 75 is formed in the dielectric film 74 and dielectric film 73 formed therebelow. From the bottom of this interconnect trench 75, a plug 72 is exposed. As illustrated in FIG. 58, a titanium/titanium nitride film 76a made of a film stack of a titanium film and a titanium nitride film is formed over the main surface of the wafer 30. Over the interior wall of this interconnect trench 75, a titanium/titanium nitride film 76a is formed. This titanium/titanium nitride film 76a can be formed, for example, by sputtering. This titanium/titanium nitride film 76a has a function as a conductive barrier film. In other words, it has a function of preventing diffusion, into silicon, of copper to be embedded in the interconnect trench 75 which will be described later. Instead of the titanium film or titanium nitride film, a tantalum film, a tungsten film, a refractory metal nitride film such as tantalum nitride film or tungsten nitride film, a titanium silicide nitride film or tungsten silicide nitride film may be used as such a conductive barrier film. A film using an alloy thereof as a main material may be used. The above-described films may be used not only as a single substance film but also a film stack.

A relatively thin seed film made of a copper (Cu) film is formed over the titanium/titanium nitride film 76a. The seed film can be formed, for example, by sputtering. This seed film is formed in order to improve adhesion between the copper film 76b, a main conductor film which will be described later, and the titanium/titanium nitride film 76a. The seed film also serves as an electrode upon electroplating which will be described later.

Over the whole surface of the wafer 30, a copper film 76b thicker than the seed film is formed to embed it in the interconnect trench 75. The copper film 76b is formed, for example, by plating such as electroplating or electroless plating. It can also be formed by forming a copper film 76b over the titanium/titanium nitride film 76a by direct sputtering and then planarizing the surface by reflow; or by depositing a copper film 76b by CVD.

An interconnect 77 as illustrated in FIG. 59 is then formed by removing an unnecessary portion of the titanium/titanium nitride film 76a and copper film 76b formed over the insulating film 74 while leaving the titanium/titanium nitride film 76a and copper film 76b buried in the interconnect trench 75. CMP, for example, can be employed for the removal of the unnecessary portion of the titanium/titanium nitride film 76a and copper film 76b.

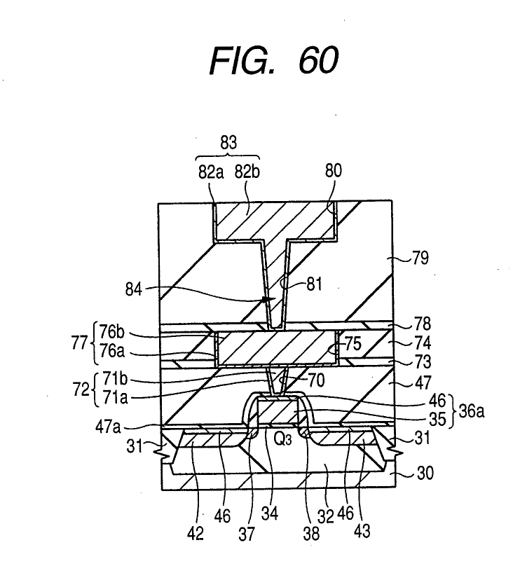

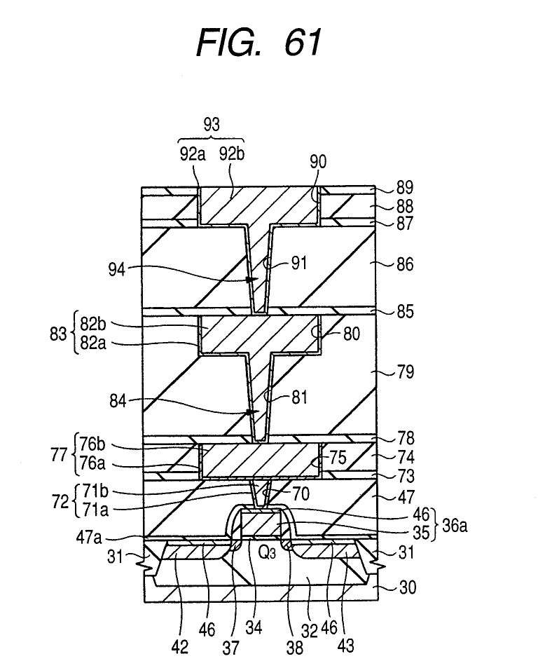

As illustrated in FIG. 60, a dielectric film 78 (plasma CVD film formation process 3-2) is then formed over the dielectric film 74 having the interconnect 74 formed therein, followed by the formation of a dielectric film 79 (plasma CVD film formation process 3-3) over the dielectric film 78. The dielectric film 78 is made of a silicon carbonitride film, while the dielectric film 79 is made of a silicon oxide film formed by the plasma CVD using TEOS as a raw material.

An interconnect trench 80 and connecting hole 81 are formed in the dielectric films 78 and 79 by photolithography and etching. From the bottom of the connecting hole 81, the interconnect 77 is exposed. Over the main surface of the wafer 30 including the interior walls of the interconnect trench 80 and connecting hole 81, a titanium/titanium nitride film 82a is formed.

Over the wafer 30 having the titanium/titanium nitride film 82a formed thereover, a relatively thin seed film made of a copper film is formed, for example, by sputtering. A copper film 82b thicker than the seed film is then formed to embed the interconnect trench 80 and connecting hole 81.

An interconnect 83 and a plug 84 are formed by removing an unnecessary portion of the titanium/titanium nitride film 82a and copper film 82b formed over the dielectric film 79 while leaving the titanium/titanium nitride film 82a and copper film 82b embedded in the interconnect 80 and connecting hole 81. For the removal of the unnecessary portion of the titanium/titanium nitride film 82a and copper film 82b, CMP can be employed for example.

As illustrated in FIG. 61, dielectric films 85 to 89 are formed successively over the dielectric film 79 having the interconnect 80 and plug 81 formed therein. The dielectric film 85 (plasma CVD film formation process 3-4) is a silicon carbonitride film; the dielectric film 87 is a silicon nitride film; the dielectric film 86 (plasma CVD film formation process 3-5) and the dielectric film 88 (plasma CVD film formation process 3-6) are each a silicon oxide film formed by plasma CVD using TEOS as a raw material; and the dielectric film 89 (plasma CVD film formation process 3-7) is an antireflection film.

An interconnect trench 90 and a connecting hole 91 are formed in the dielectric films 85 to 89 by photolithography and etching. From the bottom of the connecting hole 91, the interconnect 83 is exposed. Over the main surface of the wafer 30 including the interior wall of the interconnect trench 90 and connecting hole 91, a titanium/titanium nitride film 92a is formed.

Over the wafer 30 having the titanium/titanium nitride film 92a formed thereover, a relatively thin seed film made of a copper film is formed, for example, by sputtering. A copper film 92b thicker than the seed film is then formed to embed the interconnect trench 90 and connecting hole 91.

An interconnect 93 and a plug 94 are the formed by removing an unnecessary portion of the titanium/titanium nitride film 92a and copper film 92b formed over the dielectric film 89 while leaving the titanium/titanium nitride film 92a and copper film 92b embedded in the interconnect trench 90 and the connecting hole 91. For the removal of the unnecessary portion of the titanium/titanium nitride film 92a and copper film 92b, CMP, for example, can be employed.

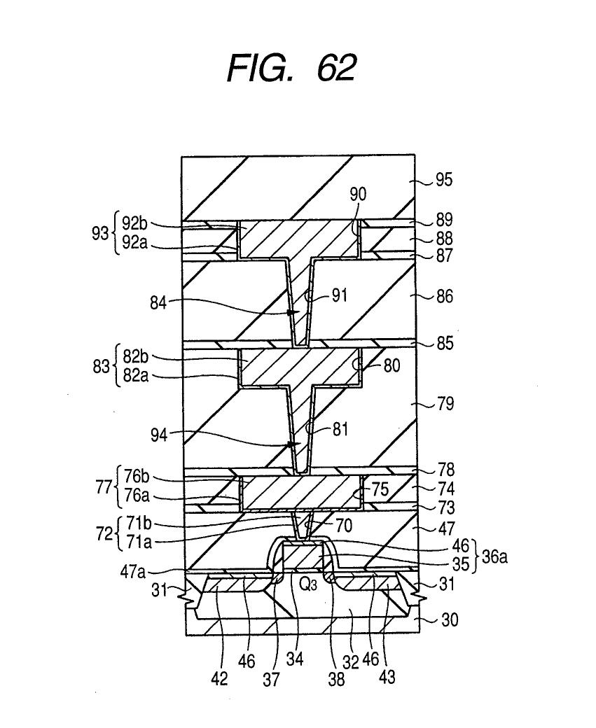

As illustrated in FIG. 62, a dielectric film 95 is then formed over the dielectric film 89 having the interconnect 93 therein. This dielectric film 95 (plasma CVD film formation process 3-8 functions as a surface protective film (passivation film) and is formed of a silicon nitride film formed, for example, by plasma CVD. As descried above, the present invention can be applied to the fabrication method of a semiconductor integrated circuit device having a copper interconnect. In other words, a semiconductor integrated circuit device having a copper interconnect can be fabricated using a plasma CVD apparatus equipped with an automatic detection function of cleaning end-point.

An application example of the plasma CVD apparatus used in Embodiment 3 to a formation step of the dielectric film 74 was described. Not only for it but also for a step of forming the dielectric film 79, 86 or 88 by CVD using TEOS as a raw material, the plasma CVD apparatus used in Embodiment 3 can be used. In other words, a plasma CVD apparatus having automatic detection function of the cleaning end-point can be used for the above-described film formation steps. It is also possible to apply the plasma CVD apparatus used in Embodiment 3 to the step of forming the dielectric film 89 made of a silicon oxynitride film or the dielectric film 95 made of a silicon nitride film.

### EMBODIMENT 4

In the plasma CVD apparatus used in Embodiment 2, cleaning of the interior of the process chambers 22a and 22b is conducted whenever a wafer is treated in the process chambers 22a and 22b. In Embodiment 4, an example of cleaning in the process chambers 22a and 22b whenever two wafers are treated in the process chambers 22a and 22b will be described. The plasma CVD apparatus to be used in Embodiment 4 has a similar constitution to that described in FIGS. 5 and 8.

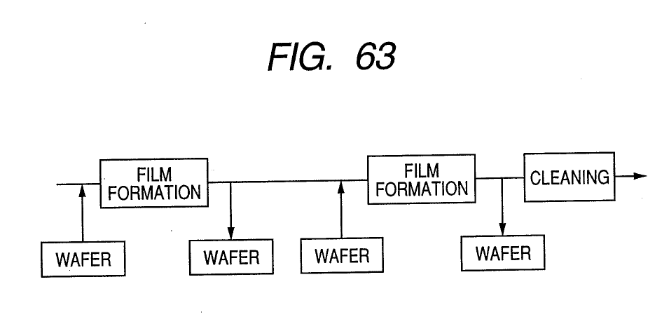

In FIG. 63, a simplified sequence for carrying out film formation over wafer by the plasma CVD to be used in Embodiment 4 and cleaning in the process chambers 22a to 22f will be described. As is apparent from FIG. 63, the first wafer is loaded in each of the process chambers 22a to 22f of the plasma CVD apparatus. In the process chambers 22a to 22f having wafers loaded therein, a film is formed over the wafer. After completion of the film formation, the resulting wafer is unloaded from the process chambers 22a to 22f. A second wafer is loaded in each of the process chambers 22a to 22f and a film is formed over the wafer. After completion of the film formation over the second wafer, it is unloaded, followed by cleaning in the process chambers 22a to 22f. Similarly, a series of operations composed of film formation over the wafer twice and cleaning in the process chambers 22a to 22f is thereafter repeated. The 25-th wafer is similarly treated together with a wafer of the next wafer cassette (wafer transfer container). In general, a plurality of wafer cassettes (two, four or the like) can be set and by doing so, it is possible to improve the throughput in the plasma CVD apparatus used in Embodiment 4.

In Embodiment 2, completion of the film formation over a first wafer is followed by cleaning and the operation is conducted in accordance with the sequence as shown in FIG. 7. Described specifically, as illustrated in FIG. 7, twelve wafers are taken out from the cassette 27 containing twenty five wafers and they are disposed in the storage elevator 24. Film formation of a first wafer is carried out in six process chambers 22a to 22f. Here, six wafers in total are treated. When the treatment of the first wafer is finished in the process chambers 22a to 22f, cleaning thereof is started. At this time, six untreated wafers remain in the storage elevator 24. These untreated wafers are waiting until the completion of the cleaning. In other words, in the cleaning encompassed by a broken line in FIG. 7, untreated wafers are waiting for the treatment in the storage elevator 24. This cause a loss time and lowers a throughput. In Embodiment 2, the chambers are cleaned whenever one wafer is treated. This is advantageous because film formation over the wafer can always be started in the cleaned process chambers 22a to 22f, but a throughput lowers in this method.

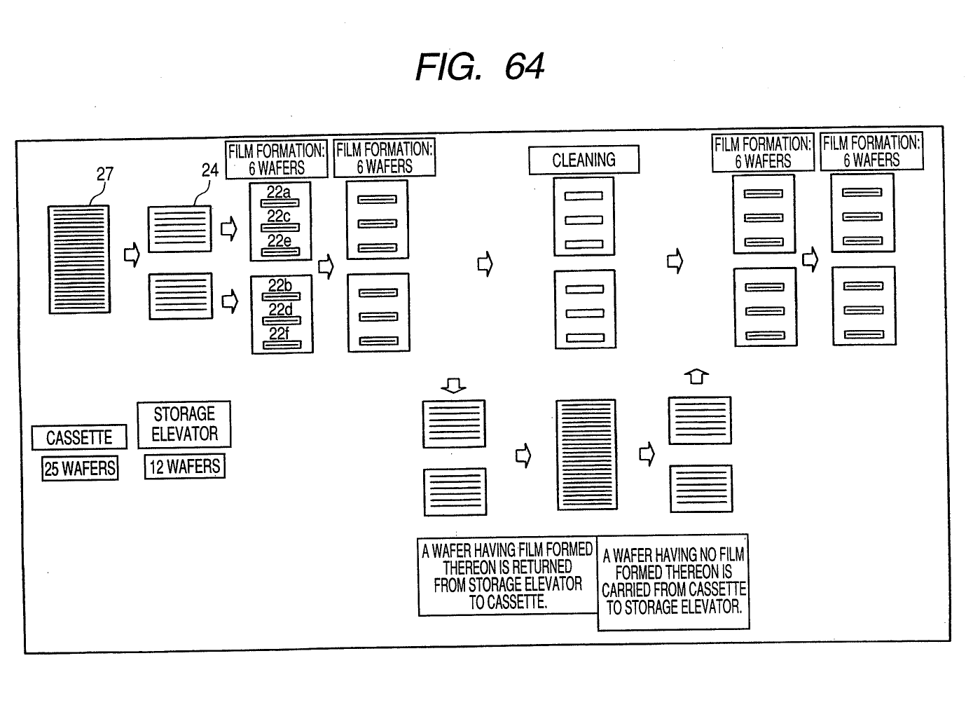

In Embodiment 4, operations are conducted in accordance with the sequence shown in FIG. 64. In FIG. 64, twelve wafers are taken out from a cassette 27 containing twenty five wafers and these twelve wafers are placed in a storage elevator 24. A film is then formed over a first wafer in six process chambers 22a to 22f. The six wafers having a film formed thereover are returned to the storage elevator 24 and simultaneously, all the untreated (six) wafers are loaded in the process chambers 22a to 22f. In the process chambers 22a to 22f, film formation over a second wafer is performed. The wafers after film formation are returned in the storage elevator 24 from the process chambers 22a to 22f. Film formation over all the twelve wafers in the storage elevator 24 is therefore finished. Twelve wafers having a film formed thereover are returned from the storage elevator 24 to the cassette 27 and fresh untreated wafers are loaded in the storage elevator 24 from the cassette 27. When loading and unloading of the wafers are conducted between the storage elevator 24 and cassette 27, no operation is conducted in the process chambers 22a to 22f. Cleaning is therefore conducted by making use of this free time. In this Embodiment 4, process chambers 22a to 22f are cleaned only in a free time thereof, which heightens efficiency and improves a throughput. In other words, in this Embodiment 4, cleaning of the process chambers 22a to 22f is performed without keeping the wafers waiting, but by making use of the transfer time of wafers between the storage elevator 24 and cassette 27 so that a throughput can be improved. According to this Embodiment 4, throughput can be improved not only by decreasing the cleaning frequency compared with that of Embodiment 2 but also by eliminating the waiting time of wafers. When a hermetically sealed type wafer transfer container (hermetically sealed but is connected to outside via an air filter) called “foup” usually adopted in a wafer process of 300 Φ or greater is used, each batch is small, for example, consists of 12 wafers so that cleaning during the transfer term of a wafer (term from unloading of the wafer from the chamber to loading of a new wafer to the chamber, or a term from unloading of the wafer from the chamber to loading of a new wafer taken out from a new transfer container to the chamber) between the transfer container and chamber improves a throughput efficiently.

As described above, according to Embodiment 4, supposing that the number of wafers which can be treated similarly by the apparatus is P and the number of wafers which can wait in the apparatus is W, cleaning can be performed whenever W pieces of wafers are treated by the whole apparatus and wafers which have already been waiting can be treated smoothly without further waiting.

In the case of a small batch as described above, rapid treatment can be attained even if the apparatus has not waiting mechanism when 2P=B wherein B represents the batch size. If cleaning is performed whenever one wafer is treated, rapid progress of each bath can be attained in a wafer line at P=B.

The constitution and operations of the cleaning end-point detecting performance in Embodiment 4 are similar to those in Embodiment 2. The process sequence of Embodiment 4 is composed of the steps from S1 to S5 twice and subsequent steps from S6 to S12 which were described above referring to FIGS. 29 to 55 concerning the process sequence of Embodiment 2.

### EMBODIMENT 5

In Embodiment 2, cleaning in the process chambers 22a to 22f is conducted whenever one wafer is treated in the process chambers 22a to 22f. In this Embodiment 5, an example of cleaning of the interior of the process chambers 22a to 22f after a film is formed over the n (stands for an integer of 3 or greater) pieces of wafers in the process chambers 22a to 22f will be described. The constitution of a plasma CVD apparatus employed in Embodiment 5 is similar to that illustrated in FIG. 5 and FIG. 8.

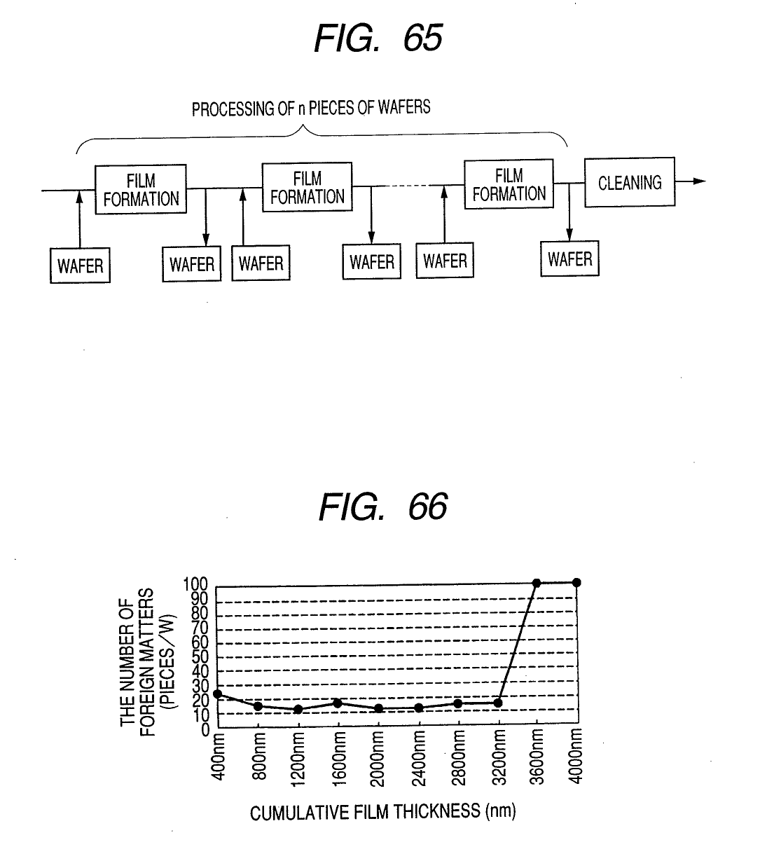

FIG. 65 illustrates a simplified process sequence for carrying out film formation over a wafer in the plasma CVD apparatus to be used in Embodiment 5 and cleaning in the process chambers 22a to 22f. As is apparent from FIG. 65, a wafer is loaded in the process chambers 22a to 22f of the plasma CVD apparatus, in which a film is formed over the wafer. After completion of the film formation over the wafer, the wafer is unloaded from the process chambers 22a to 22f. This operation is repeated for n (n stands for an integer of 3 or greater) pieces of wafers in each of the process chambers 22a to 22f, followed by cleaning therein. A series of operations composed of n times of similar film formation treatment over wafer and cleaning in the process chambers 22a to 22f is repeated. This makes it possible to improve the throughput of the plasma CVD apparatus used in Embodiment 5. Particularly, when Embodiment 4 is taken into consideration, wait time of the wafer during cleaning can be eliminated when the n stands for an even number so that further improvement in the throughput can be attained.

From the viewpoint of the throughput, an increase in the number n is desired, but an increase in the number n means a reduction in the cleaning frequency in the process chambers 22a to 22f. When the cleaning frequency in the process chambers 22a to 22f decreases, foreign matters are apt to appear upon film formation, leading to the formation of inferior wafers and lowering in the yield of the product. In order to prevent generation of foreign matters in the process chambers 22a to 22f, it is necessary to suppress the upper limit of the number n. When cleaning is conducted during the film-formation-free time (returning time of wafers to the transfer container and transfer time of the wafers from the transfer container to the film formation chamber), the number n is preferably 4 or less. Even when cleaning cannot be conducted in the film-formation-free time, on the other hand, the number n is preferably 10 or less.

FIG. 66 illustrates the relationship between the cumulative film thickness (nm) in the plasma CVD apparatus and the number of foreign matters. In FIG. 66, the number of foreign matters per wafer is plotted along the ordinate, while the cumulative film thickness (nm) in the plasma CVD apparatus is plotted along the abscissa. This cumulative film thickness means the film thickness formed by continuing film formation without cleaning. The thickness of 1600 nm on the abscissa means that four wafers are treated without cleaning supposing a 400-nm thick film is formed on one wafer, or means that eight wafers are treated supposing a 200-nm thick film is formed on one wafer.

As is apparent from FIG. 66, the number of foreign matters falls within a range of from 10 to 20 per wafer when the cumulative film thickness is from 400 nm to 3200 nm. When the cumulative film thickness becomes 3600 nm, exceeding 3200 nm, the number of foreign matters shows a drastic increase and it becomes 100 per wafer. It is therefore preferred to select the number n so that the cumulative film thickness does not exceed 3200 nm (the film of FIG. 66 is an ordinarily employed silicon oxide film formed by plasma TEOS, but this also applies to silicon-oxide-based dielectric films such as SiOC and non-oxide-based silicon-containing dielectric films such as silicon nitride-based films). By selecting the number n so as to suppress the cumulative film thickness to 3200 nm or less, the throughput of the step and also the yield of the product can be improved.

The constitution and operations of the cleaning end-point detecting performance in Embodiment 5 are similar to those in Embodiment 2. The process sequence of Embodiment 5 is composed of the steps from S1 to S5 repeated n times and subsequent steps from S6 to S12, which were described above referring to FIGS. 29 to 55 concerning the process sequence of Embodiment 2.

### EMBODIMENT 6

In Embodiment 2, an example of automatically detecting the end point of cleaning by using the RF sensor 10 in the cleaning of the process chambers 22a to 22f was described. In Embodiment 6, an example of automatically detecting the end point of cleaning by using a photoelectric sensor (such as photo diode, photoelectric cell, image sensor, photoelectron multiplier, streak tube, microchannel plate or semiconductor photosensor) will be described.

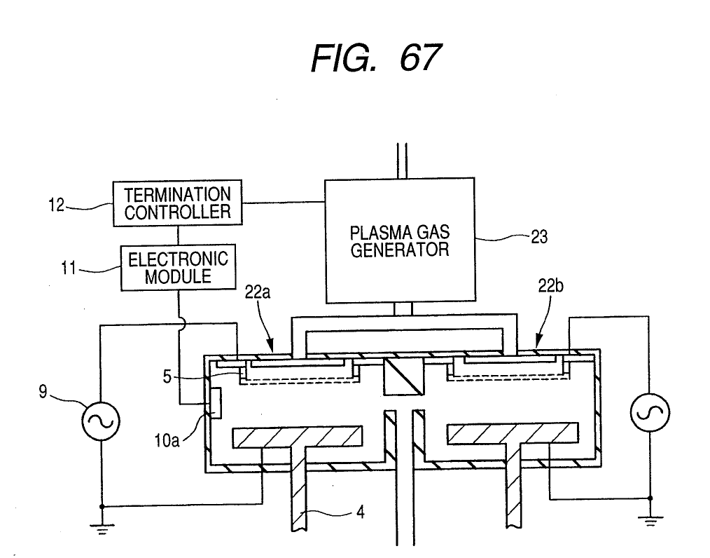

The constitution of a plasma CVD apparatus to be used in Embodiment 6 is similar to that described referring to FIG. 5. FIG. 67 illustrates the constitution of the process chambers 22a and 22b in which film formation over wafer and cleaning are carried out. FIG. 67 is almost similar to FIG. 8 in which the process chambers 22a and 22b of Embodiment 2 are illustrated so that only the different portions will be described next.

A difference between FIG. 8 and FIG. 67 is that a voltage generated between a pair of electrodes made of the lower electrode 4 and upper electrode 5 is detected by the RF sensor 10 in FIG. 8, while light emission of a plasma cleaning gas between a pair of electrodes is detected by a photoelectric sensor 10a in FIG. 67. Also in this manner, the cleaning end-point can be automatically detected by detecting light emission of the plasma cleaning gas through the photoelectric sensor 10a. In Embodiment 6, optical properties of plasma are utilized as physical or chemical properties of plasma.

Actual cleaning operation in Embodiment 6 will next be described referring to FIG. 67. After film formation over wafer in the process chambers 22a and 22b, the wafer having a film formed thereover is unloaded from the process chambers 22a and 22b. An NF₃ gas (mixed with an argon gas) is introduced into the plasma gas generator 23. The cleaning gas thus introduced is converted into plasma in the plasma gas generator 23 and the cleaning gas in plasma form is introduced into the process chambers 22a and 22b. The plasma cleaning gas rich in reactivity causes a chemical reaction with the film formed inside of the process chambers 22a and 22b and forms a reaction product. By this, the film formed inside of the process chambers 22a and 22b is removed and cleaning thereof is completed. The reaction product is discharged outside of the process chambers 22a and 22b.

During cleaning with the plasma cleaning gas, electricity is supplied to the pair of electrodes from the radio frequency power source 9 and the cleaning gas existing between the pair of electrodes is maintained in plasma form. The electricity supplied to the pair of electrodes is much smaller than that supplied upon film formation. The minimum electricity necessary for maintaining the plasma form of the cleaning gas is supplied. This makes it possible to reduce a plasma-induced deterioration of parts.

The cleaning gas in plasma form contains fluorine radicals. For example, fluorine radicals are under excited state, and upon transition of electrons from the excited state to the normal state, a light is emitted. This light emission is detected by the photoelectric sensor 10a and converted into a voltage by photoelectric conversion. The voltage obtained by photoelectric conversion is input to the termination controller 12 after amplification by the electronic module. When the voltage thus input becomes substantially constant at a predetermined voltage or greater, the termination controller 12, based on judgment that the cleaning is finished, stops feeding of the plasma cleaning gas from the plasma gas generator 23 to the process chambers 22a and 22b and terminates cleaning. In such a manner, the end point of the cleaning in the process chambers 22a and 22b can be detected properly.

During cleaning in the process chambers 22a and 22b, the plasma cleaning gas is used for the reaction with the film formed in the process chamber 22a. As the plasma cleaning gas containing fluorine radicals is consumed, light emission by fluorine radicals relatively decreases. With a progress in the removal of the film formed in the process chambers 22a and 22b, the consumption amount of the plasma cleaning gas lowers and an amount of fluorine radicals in the process chambers 22a and 22b becomes constant. The light emission amount from the fluorine radicals also becomes constant. The voltage also becomes constant in proportion to the light emission amount. It is therefore possible to judge the cleaning end-point properly.

In Embodiment 6, the photoelectric sensor 10a is employed. There is a possibility of the surface of the photoelectric sensor 10 being clouded by the plasma cleaning gas, which may disturb detection. In Embodiment 6, however, the minimum electricity necessary for conversion of the cleaning gas into plasma is supplied to a pair of electrodes so that conversion into plasma occurs vigorously in a relatively narrow region between the pair of electrodes. The influence of the plasma cleaning gas is presumed to be small in the photoelectric sensor 10a which is away from the pair of electrodes. In this Embodiment, a description was made mainly on optical emission spectrometry, but in some cases, absorption spectrometry is effective. The absorption spectrometry is conducted, for example, by introducing a light having a predetermined band width into the film forming chamber and observing the spectrum of a light transmitting from the opposite side.

In Embodiment 6, the process chambers 22a and 22b may be cleaned whenever a first wafer is treated in the process chambers 22a and 22b as described in Embodiment 2 or whenever first and second wafers are treated in the process chambers 22a and 22b as described in Embodiment 4. Alternatively, cleaning may be conducted after treatment of n (n stands for an integer of 3 or greater) pieces of wafers in the process chambers 22a and 22b as described in Embodiment 5.

### (Mutual Relation Between Examples and the Other Important Points)

The present invention made by the present inventors have described specifically based on some embodiments. It should however be borne in mind that the present invention is not limited to them. It is needless to say that it can be modified within an extent not departing from the scope of the present invention.

The present invention may be applied to a thermal CVD apparatus which adopts the remote plasma method for the cleaning in the chambers and conducts film formation by decomposing raw material gases by heating. In this case, automatic detection of cleaning end-point can be effected by installing, to this apparatus, a radio frequency power source of about 100 W and any one of the constitutions described in the above-described embodiments.

It is needless to say that the integrated circuit fabrication wafer process, such as fabrication process as disclosed in Embodiment 2, particularly aluminum interconnection process (from a step of forming a tungsten plug to the final step of forming a protective film), and fabrication process as disclosed in Embodiment 3, particularly copper interconnection process (from a step of forming a tungsten plug to a final step of forming a protective film) can be applied to Embodiments 1 to 6. On the contrary, it is needless to say that the end-point detection and wafer treatment technique in CVD disclosed in Embodiments 1, 2, 4, 5 and 6 can be applied to the integrated circuit fabrication wafer process of Embodiment 2 or 3.

The silicon oxide based dielectric film materials for ILD and processes relating thereto as disclosed in this application can be applied to the plasma CVD film formation processes 2-1, 2, 4, 5, 6 and 8 and 3-1, 3, and 6.

The silicon oxide film based dielectric film materials (such as SiON) for antireflection film and processes relating thereto as disclosed by the present application can be applied to the plasma CVD film formation processes 2-3 and 2-7 and 3-7.

The non-silicon oxide film based dielectric film materials (such as SiN, SIC and SICN) and processes as disclosed by the present application can be applied to the plasma CVD film formation processes 2-9 and 3-2, 4, 5 and 8.

The fabrication method of the semiconductor integrated circuit device according to the present invention can be applied widely for electronic devices including semiconductor integrated circuit devices, liquid-crystal display devices, plasma displays, the other integrated circuit devices and semiconductor devices.

What is claimed is:

1. A fabrication method of a semiconductor integrated circuit device comprising the steps of:
(a) etching an undesired film member deposited over an interior wall or electrodes of a first film forming chamber of a plasma CVD apparatus not containing therein a wafer to be treated, while introducing, in the first film forming chamber, a first-radical-containing first gas generated outside the film forming chamber;
(b) during the step (a), subjecting the first gas in the first film forming chamber to plasma excitation at a first radio frequency power of a first intensity and detecting an end point of the etching by observing the physical or chemical properties of the excited plasma;
(c) terminating the etching based on the results of the step (b);
(d) discharging the first gas from the first film forming chamber;
(e) after the steps (c) and (d), storing, in the first film forming chamber, a first wafer to be treated;
(f) subjecting a second gas, while being introduced into the first film forming chamber containing the first wafer, to plasma excitation by second radio frequency power of a second intensity greater than the first intensity, thereby forming a first film member on or over a first main surface of the first wafer; and
(g) after the step (f), taking out the first wafer from the first film forming chamber,
wherein impedances are detected by an RF sensor electrically connected to the electrodes.

2. A fabrication method of a semiconductor integrated circuit device according to claim 1, wherein the physical or chemical properties of plasma are optical properties of the plasma.

3. A fabrication method of a semiconductor integrated circuit device comprising the steps of:
(a) etching an undesired film member deposited over an interior wall or electrodes of a first film forming chamber of a CVD apparatus not containing therein a wafer to be treated, while introducing, in the first film forming chamber, a first-radical-containing first gas formed outside the first film forming chamber;
(b) during the step (a), subjecting the first gas, which is in the first film forming chamber, to plasma excitation by a first radio frequency power of a first intensity and detecting an end point of the etching by observing physical or chemical properties of the excited plasma;
(c) terminating the etching based on the results of the step (b);
(d) discharging the first gas from the first film forming chamber;
(e) after the steps (c) and (d), placing a first wafer to be treated in the first film forming chamber;
(f) forming a first film member on or over a first main surface of the first wafer to be treated without causing plasma excitation by radio frequency power higher than the first radio frequency power, while introducing a second gas in the first film forming chamber containing the first wafer therein; and
(g) after the step (f), taking out the first wafer from the first film forming chamber,
wherein impedances are detected by an RF sensor electrically connected to the electrodes.

4. A fabrication method of a semiconductor integrated circuit device according to claim 3, wherein the physical or chemical properties of the plasma are optical properties of the plasma.

5. A fabrication method of a semiconductor integrated circuit device according to claim 3, wherein the first film member is formed by thermal CVD.

6. A fabrication method of a semiconductor integrated circuit device comprising the steps of:
(a) etching an undesired film member deposited over an interior wall or electrodes of a first film forming chamber of a plasma CVD apparatus not containing a wafer to be treated, while introducing, in the first film forming chamber, a first-radical-containing first gas formed outside the first film forming chamber;
(b) during the step (a), subjecting the first gas in the first film forming chamber to plasma excitation at a first radio frequency power of a first intensity and detecting an end point of the etching;
(c) based on the results of the step (b), terminating the etching;
(d) discharging the first gas from the first film forming chamber;
(e) after the steps (c) and (d), storing a first wafer to be treated in the first film forming chamber;
(f) forming, while introducing a second gas in the first film forming chamber containing the first wafer to be treated, a first film member on or over a first main surface of the first wafer by subjecting the second gas to plasma excitation;
(g) after the step (f), taking out the first wafer from the first film forming chamber;
(h) after the step (g), storing a second wafer to be treated in the first film forming chamber without etching an undesired film member deposited in the first film forming chamber during the step (f);
(i) forming, while introducing the second gas in the first film forming chamber containing the second wafer, the first film member on or over a first main surface of the second wafer by subjecting the second gas to plasma excitation; and
(j) after the step (i), taking out the second wafer from the first film forming chamber,
wherein impedances are detected by an RF sensor electrically connected to the electrodes.

7. A fabrication method of a semiconductor integrated circuit device according to claim 6, wherein the end point of etching is detected by measuring optical properties of the first gas plasma-excited in the first film forming chamber.

8. A fabrication method of a semiconductor integrated circuit device according to claim 1, wherein said etching is a cleaning of said at least one of said interior walls and said electrodes.

9. A fabrication method of a semiconductor integrated circuit device according to claim 3, wherein said etching is a cleaning of said at least one of said interior walls and said electrodes.

10. A fabrication method of a semiconductor integrated circuit device according to claim 6, wherein said etching is a cleaning of said at least one of said interior walls and said electrodes.
